(19) United States
(12) Patent Application Publication
(10) Pub. No.: US 2025/0301778 A1
(43) Pub. Date: Sep. 25, 2025

(54) SEMICONDUCTOR DEVICES IN INTEGRATED CIRCUIT HAVING DIFFERENT THRESHOLD VOLTAGES

(71) Applicant: TEXAS INSTRUMENTS INCORPORATED, Dallas, TX (US)

(72) Inventors: Zhikai Tang, Sunnyvale, CA (US); Ujwal Radhakrishna, San Jose, CA (US); Jungwoo Joh, Allen, TX (US); Timothy Bryan Merkin, Princeton, TX (US); Yoganand Saripalli, Allen, TX (US)

(21) Appl. No.: 18/610,219

(22) Filed: Mar. 19, 2024

(51) Int. Cl. H01L 27/088; H01L 27/06; H01L 29/20; H01L 29/66; H01L 29/778

(52) U.S. Cl. CPC H10D 84/84; H10D 30/015; H10D 30/475; H10D 62/8503; H10D 84/811

(57) ABSTRACT

The present disclosure generally relates to semiconductor devices in an integrated circuit (IC) that have different threshold voltages. In an example, an IC includes a semiconductor substrate, a channel layer, a barrier layer, a first semiconductor device, and a second semiconductor device. The channel layer is on the semiconductor substrate, and the channel layer includes a gallium nitride (GaN) material. The barrier layer is on the channel layer. The first semiconductor device is on the semiconductor substrate. The first semiconductor device includes a first terminal over the barrier layer, and the first semiconductor device has a first threshold voltage. The second semiconductor device is on the semiconductor substrate. The second semiconductor device includes a second terminal over the barrier layer, and the second semiconductor device has a second threshold voltage different from the first threshold voltage. The first and second threshold voltages are both positive or negative voltages.

### BACKGROUND

A type of semiconductor device is a high electron mobility transistor (HEMT). A HEMT typically employs different semiconductor materials to form a heterojunction, where a channel may be formed near the heterojunction and between a source region and a drain region. A HEMT may have a high speed operation, which makes HEMTs attractive for high frequency applications, among others.

### SUMMARY

This Summary is provided to introduce a brief selection of disclosed concepts in a simplified form that are further described below in the Detailed Description including the drawings provided. Various disclosed devices and methods may be beneficially applied to semiconductor devices in an integrated circuit (IC) that have different threshold voltages. While such embodiments may be expected to achieve improved performance for a target application, no particular result is a requirement unless explicitly recited in a particular claim.

An example described herein is an IC. The IC includes a semiconductor substrate, a channel layer, a barrier layer, a first semiconductor device, and a second semiconductor device. The channel layer is on the semiconductor substrate, and the channel layer includes a gallium nitride (GaN) material. The barrier layer is on the channel layer. The first semiconductor device is on the semiconductor substrate. The first semiconductor device includes a first terminal over the barrier layer, and the first semiconductor device has a first threshold voltage. The second semiconductor device is on the semiconductor substrate. The second semiconductor device includes a second terminal over the barrier layer, and the second semiconductor device has a second threshold voltage different from the first threshold voltage. The first and second threshold voltages are both positive or negative voltages.

Another example described herein is an IC. The IC includes a semiconductor substrate, a first high electron mobility transistor (HEMT), a second HEMT, and a diode. The first HEMT is on the semiconductor substrate. The first HEMT is coupled between a power terminal and a switching terminal. The second HEMT is on the semiconductor substrate. The second HEMT is coupled between the switching terminal and a ground terminal. The diode is on the semiconductor substrate. The diode is coupled between the switching terminal and the ground terminal. The diode has a different threshold voltage from at least one of the first HEMT and the second HEMT.

A further example described herein is an IC. The IC includes a semiconductor substrate, a first depletion mode HEMT, an enhancement mode HEMT, and a comparator. The first depletion mode HEMT is on the semiconductor substrate. The first depletion mode HEMT is coupled between a power terminal and a clamp terminal. The first depletion mode HEMT has a first threshold voltage. The enhancement mode HEMT is on the semiconductor substrate. The enhancement mode HEMT is coupled between the clamp terminal and a ground terminal. The enhancement mode HEMT has a gate terminal. The comparator has a first comparator input, a second comparator input, and a comparator output. The first comparator input is electrically coupled to the clamp terminal. The second comparator input is electrically coupled to a reference terminal. The comparator output is electrically coupled to the gate terminal. The comparator includes a second depletion mode HEMT on the semiconductor substrate. The second depletion mode HEMT has a second threshold voltage different from the first threshold voltage.

An example is a method. A channel layer is formed on a semiconductor substrate. The channel layer includes a gallium nitride (GaN) material. A barrier layer is formed on the channel layer. A first semiconductor device is formed on the semiconductor substrate. The first semiconductor device includes a first terminal over the barrier layer, and the first semiconductor device has a first threshold voltage. A second semiconductor device is formed on the semiconductor substrate. The second semiconductor device includes a second terminal over the barrier layer, and the second semiconductor device has a second threshold voltage different from the first threshold voltage. The first and second threshold voltages are both positive or negative voltages.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

FIG. 1A is a schematic of a circuit that includes semiconductor devices having different threshold voltages according to some examples.

FIG. 1B is a schematic of a circuit that includes semiconductor devices having different threshold voltages according to some examples.

FIGS. 2, 3, 4, 5, 6, 7, 8, and 9 are schematics illustrating cross-sectional views of respective integrated circuits (ICs) according to some examples.

FIG. 10 is a flowchart of a method of manufacturing the IC of FIG. 2 according to some examples.

FIGS. 11, 12, 13, 14, 15, 16, 17, 18, 19, 20, and 21 are schematics illustrating cross-sectional views of the IC of FIG. 2 at various stages of manufacturing according to some examples.

FIG. 22 is a flowchart of a method of manufacturing the IC of FIG. 4 according to some examples.

FIGS. 23, 24, 25, and 26 are schematics illustrating cross-sectional views of the IC of FIG. 4 at various stages of manufacturing according to some examples.

FIG. 27 is a flowchart of a method of manufacturing the IC of FIG. 6 according to some examples.

FIGS. 28, 29, 30, 31, and 32 are schematics illustrating cross-sectional views of the IC of FIG. 6 at various stages of manufacturing according to some examples.

FIG. 33 is a flowchart of a method of manufacturing the IC of FIG. 7 according to some examples.

FIGS. 34, 35, 36, and 37 are schematics illustrating cross-sectional views of the IC of FIG. 7 at various stages of manufacturing according to some examples.

FIG. 38 is a flowchart of a method of manufacturing an IC in which gate layers have different doping concentrations according to some examples.

FIGS. 39, 40, 41, and 42 are schematics illustrating cross-sectional views of an IC at various stages of manufacturing according to some examples.

FIG. 43 is a flowchart of a method of manufacturing an IC in which gate layers have different doping concentrations according to some examples.

FIGS. 44 and 45 are schematics illustrating cross-sectional views of an IC at various stages of manufacturing according to some examples.

FIG. 46 is a flowchart of a method of manufacturing an IC in which gate layers have different doping concentrations according to some examples.

FIGS. 47, 48, and 49 are schematics illustrating cross-sectional views of an IC at various stages of manufacturing according to some examples.

FIG. 50 is a flowchart of a method of manufacturing an IC using a gate first process according to some examples.

FIGS. 51, 52, 53, 54, and 55 are schematics illustrating cross-sectional views of an IC at various stages of manufacturing according to some examples.

FIG. 56 is a flowchart of a method of manufacturing an IC using a gate first process according to some examples.

FIG. 57 is a schematic illustrating a cross-sectional view of an IC at a stage of manufacturing according to some examples.

FIG. 58 is a flowchart of a method of manufacturing an IC using a gate first process according to some examples.

FIGS. 59, 60, 61, and 62 are schematics illustrating cross-sectional views of an IC at various stages of manufacturing according to some examples.

FIG. 63 is a chart illustrating threshold voltage of a semiconductor device as a function of gate layer thickness according to some examples.

FIG. 64 is a chart illustrating threshold voltage of a semiconductor device as a function of gate layer dopant concentration according to some examples.

FIG. 65 is a chart illustrating threshold voltage of a semiconductor device as a function of barrier layer thickness according to some examples.

FIG. 66 is a chart illustrating threshold voltage of semiconductor devices as a function of gate length according to some examples.

FIG. 67 is a chart illustrating threshold voltage of semiconductor devices as a function of contact offset length according to some examples.

FIGS. 68, 69, 70, 71, and 72 are schematics illustrating cross-sectional views of respective semiconductor devices illustrating different isolation mechanisms according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates to semiconductor devices in an integrated circuit (IC) that have different threshold voltages. In some examples described herein, the semiconductor devices may be or include a high electron mobility transistor (HEMT), a HEMT-based device, a diode, etc. An example HEMT-based device may include a diode-connected HEMT. In some examples, an IC includes two or more semiconductor devices that are a same type and that have different threshold voltages. The IC may include one or more other semiconductor devices that are a same or different type and that have a same threshold voltage or different threshold voltages. For example, an IC may include two or more enhancement mode (Emode) HEMTs that have different threshold voltages, and may further include one or more depletion mode (Dmode) HEMTs. In another example, an IC may include two or more Dmode HEMTs that have different threshold voltages, and may further include one or more Emode HEMTs. In some examples, an IC in which the semiconductor devices are formed may include a gallium nitride (GaN) platform, such as an indium aluminum gallium nitride (InᵢAlⱼGa₁₋ᵢ₋ⱼN, where 0≤i≤1, 0≤j≤1, and 0≤i+j≤1) platform.

According to some examples, an IC includes a semiconductor substrate, a channel layer on the semiconductor substrate, and a barrier layer on the channel layer. A first semiconductor device (e.g., a HEMT) is on the semiconductor substrate and has a first threshold voltage. A second semiconductor device (e.g., a HEMT) is on the semiconductor substrate and has a second threshold voltage different from the first threshold voltage. The first and second threshold voltages may both be respective positive voltages or respective negative voltages. The first and second semiconductor devices may both be a same Emode type or Dmode type. Further examples include a method of manufacturing such an IC. Such a method includes forming the channel layer on the semiconductor substrate, forming the barrier layer on the channel layer, forming the first semiconductor device, and forming the second semiconductor device.

Different threshold voltages in semiconductor devices may be achieved by one or more techniques. Any number of those techniques may be implemented in any semiconductor device to achieve a target threshold voltage.

A first technique includes implementing different thicknesses of respective gate layers of the semiconductor devices, such as for Emode HEMTs. As detailed below, a semiconductor device, such as an Emode HEMT, may include a gate layer that is, for example, a p-doped semiconductor layer, which may further have a gate metal contact that forms a Schottky or ohmic junction with the gate layer. Thickness of the gate layer may affect a gate metal contact to gate layer Schottky capacitance and hole depletion. Thus, a positive gate voltage applied to the gate layer may be needed before the gate layer starts to modulate the channel. A thinner gate layer may result in a semiconductor device having a larger Schottky capacitance and a lower threshold voltage than a semiconductor device with a thicker gate layer. To form such gate layers with different thicknesses, the gate layer may be patterned and subsequently, the patterned gate layers may be selectively reduced (e.g., by etching while masking non-selected gate layers).

Another technique includes implementing different thicknesses of a barrier layer for the semiconductor devices, such as for Emode HEMTs. In some examples, the barrier layer may be aluminum gallium nitride (AlGaN). The more aluminum (Al) content in the barrier layer at the channel, the lower the threshold voltage becomes (e.g., a positive threshold voltage may be reduced towards zero, and a negative threshold voltage may be reduced to a more negative voltage). Aluminum content may be varied by different concentrations and/or by different thicknesses. A larger thickness may result in a larger aluminum content, and a reduced thickness may result in a reduced aluminum content. A thicker barrier layer may also result in larger channel electron density that is more difficult to deplete by the gate layer, which results in a lower threshold voltage. Barrier thickness may increase polarization charge and hence may also reduce the threshold voltage. Hence, in some examples, the barrier layer at the channel of a semiconductor device is thinner than the barrier layer at the channel of another semiconductor device. To form a barrier layer with different thicknesses, in some examples, the barrier layer may be deposited (e.g., epitaxially grown), and a recess may be etched at a channel for a semiconductor device that is to have a thinner barrier layer. To form a barrier layer with different thicknesses, in some examples, the barrier layer may include a first barrier sub-layer that is deposited (e.g., epitaxially grown) and through which an opening is etched at a channel for a semiconductor device that is to have a thinner barrier layer. The barrier layer may further include a second barrier sub-layer that is deposited (e.g., epitaxially grown) on the first barrier sub-layer and in the opening.

Another technique includes implementing different thicknesses of a channel layer for the semiconductor devices, such as for Emode HEMTs. In some examples, a channel layer may be on one or more transition layers, which may include one or more doped buffer layers. By having different thicknesses of a channel layer, the distance from the doped buffer layer(s) may be varied, which may result in differing threshold voltages. The thinner the channel layer is, and closer the channel in the channel layer is to the doped buffer layer, the larger the threshold voltage is. A closer proximity to the doped buffer layer may result in lower electron density and resulting increased depletion of the channel, which may result in increased threshold voltage. To form a channel layer with different thicknesses, in some examples, the channel layer may be deposited (e.g., epitaxially grown), and a recess may be etched at a channel for a semiconductor device that is to have a thinner channel layer.

Another technique includes implementing different gate lengths of gate layers of the semiconductor devices (e.g., Emode HEMTs), where the gate length is a length of the gate layer along an axis between the source and the drain. For some range of gate length, threshold voltage decreases with increasing gate length, and for another range of gate length, threshold voltage increases with increasing gate length. Due to the longer gate length, a longer depletion region may result in the channel region under the gate layer between the source and the drain. Accordingly, a larger gate voltage may be needed to generate sufficient charge to replenish the depleted charge and form the channel, which results in a higher threshold voltage. To form gate layers with different gate lengths, in some examples, a mask used for patterning a gate layer may be modified to achieve the gate lengths.

Another technique includes implementing different gate contact offset lengths between gate metal contacts and gate layers of the semiconductor devices, such as for Emode HEMTs. The gate contact offset length may be a distance between a sidewall of a gate metal contact (where the gate metal contact contacts the gate layer) and a corresponding sidewall of the gate layer. Increasing a gate contact offset length within some range increases the threshold voltage. Due to the gate contact offset, the gate metal is closer to the channel (e.g., directly on the gate layer), and the metal over the gate contact offset length has both passivation and gate layer underneath it. Accordingly, the channel region directly below the gate metal has a lower threshold voltage to enable the formation of channel, whereas the channel region within the gate contact offset length has a higher threshold voltage to enable the formation of channel. Increasing the gate contact offset length can reduce the dimension of the gate contact directly above the channel region and increase the threshold voltage. To form different gate contact offset lengths, in some examples, a mask used for forming a contact opening (e.g., through one or more dielectric layers) to a gate layer may be modified to achieve the gate contact offset length.

Another technique includes implementing different concentrations of dopants, including different uniform concentrations or different gradients of concentrations, of respective gate layers of the semiconductor devices, such as for Emode HEMTs. As detailed below, a semiconductor device, such as an Emode HEMT, may include a gate layer that is, for example, a p-doped semiconductor layer. Having different concentrations of p-type dopants in p-doped semiconductor gate layers may result in differing numbers of acceptors from the p-type dopants, which can cause the different threshold voltages. A lower number of acceptors in a gate layer may result in less depletion in a channel of the semiconductor device, which may reduce the threshold voltage of the semiconductor device. Conversely, a larger number of acceptors in a gate layer may result in greater depletion in a channel of the semiconductor device, which may increase the threshold voltage of the semiconductor device. Hence, a gate layer with a lower dopant concentration may result in a semiconductor device having a lower threshold voltage than a semiconductor device with a gate layer having a higher threshold voltage. To form such gate layers with different dopant concentrations, in some examples, different gate sub-layers maybe deposited (e.g., epitaxially grown) with different in situ doping, where the gate layers are patterned from the different gate sub-layers. To form such gate layers with different dopant concentrations, in other examples, a gate layer maybe deposited (e.g., epitaxially grown) with in situ doping, and some areas that are to have a higher dopant concentration are implanted with dopants. To form such gate layers with different dopant concentrations, in still other examples, a gate layer maybe deposited (e.g., epitaxially grown), and different areas are implanted with dopants at different concentrations.

Another technique includes implementing different metal-barrier work functions in the semiconductor devices, such as for Emode HEMTs. Different metals may be implemented in as gate metal contacts for different semiconductor devices to implement different metal-barrier work functions. To form different gate contact metals, in some examples, multiple processes each including a metal deposition, and metal patterning may be used for forming the different gate metal contacts.

Another technique includes implementing different effective gate-to-channel capacitances of the semiconductor devices, such as for Dmode HEMTs. The semiconductor devices may be Dmode metal-insulator-semiconductor HEMTs (MIS-HEMTs). The effective gate-to-channel capacitance is a function of a thickness of a dielectric material and the dielectric constant of the dielectric material. Hence, various examples include modifying the thickness and/or dielectric constant of the dielectric materials implemented in the semiconductor devices. As an example, to implement the different effective gate-to-channel capacitances, two dielectric layers may be formed, where the second dielectric layer is formed on the first dielectric layer. The second dielectric layer may be a different material from the first dielectric layer, such that the two dielectric layers have different dielectric constants. The second dielectric layer may be removed from a semiconductor device, such that the first and second dielectric layers remain as a gate dielectric layer for at least one semiconductor device, and the first dielectric layer remains as a gate dielectric layer for at least one other semiconductor device. Other methods of forming gate dielectric layers with different thicknesses and/or dielectric constants may be implemented.

Implementing semiconductor devices with different threshold voltages in an IC may provide IC with improved performance. Incorporating the semiconductor devices in an IC (e.g., in a single die or chip), such as a System-on-Chip (SoC), may save power, reduce size, reduce costs, and reduce parasitics, among other things. Other benefits and advantages may be achieved.

Various examples are described herein. Although the specific examples may illustrate various aspects of the above generally described features, examples may incorporate any combination of the above generally described features (which are described in more detail in examples below). Methods according to various examples may implement various operations and/or processing to achieve various aspects.

Examples described herein may enable a platform for integrating different semiconductor devices on an IC. Such a platform may permit inclusion of Emode HEMTs (which may include Schottky junctions to gate layers), Dmode HEMTs (e.g., Dmode MIS-HEMTs), and a field effect rectifier and/or diode. In such monolithic integration, multiple threshold voltages may be achieved, such as including low threshold voltages for Emode HEMTs for driver circuits, for a freewheeling diode, for HEMTs for a startup circuit, fine-tuning clamp voltage of high resolution clamp diodes stack, etc., and including high threshold voltages for low and high voltage power HEMTs to avoid false turn-on during fast switching. Other components and devices may be included in the monolithic integration, such as resistors, capacitors, inductors, etc. Such a monolithic integration may be implemented for high-efficiency power conversion and other applications, for example.

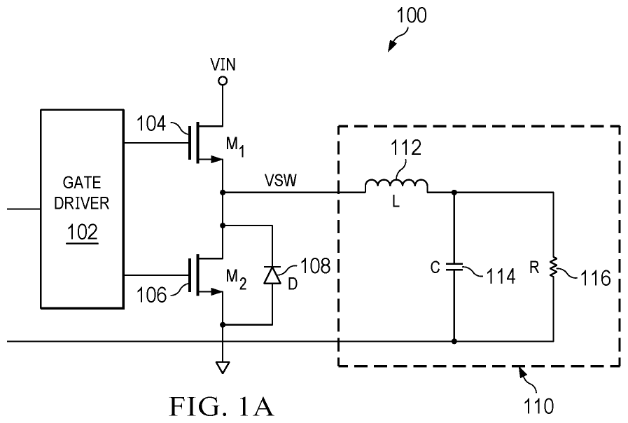

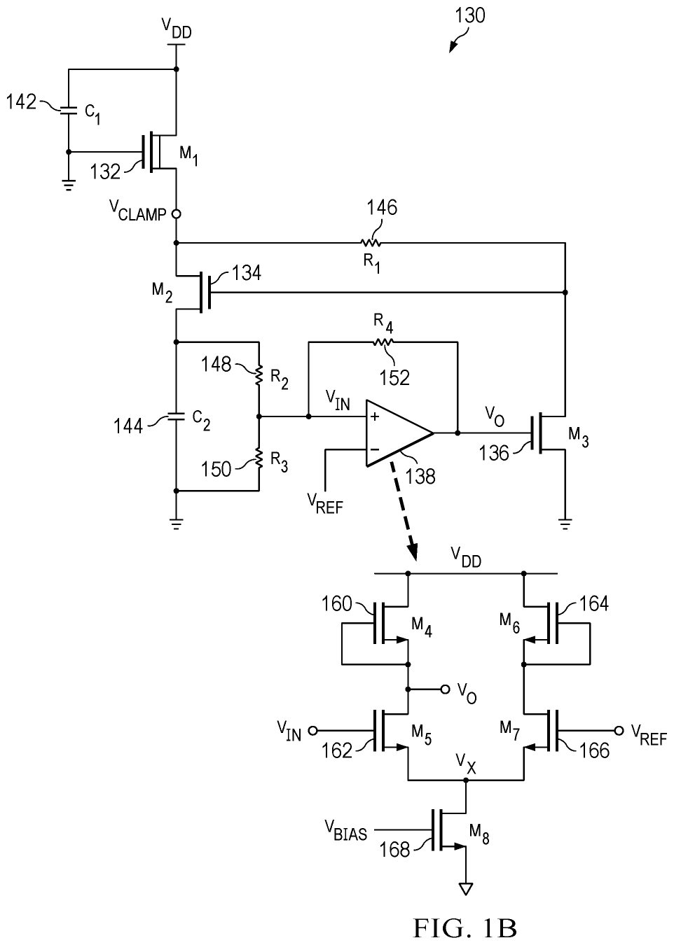

FIG. 1A is a circuit schematic of a circuit 100 that includes semiconductor devices according to some examples. The circuit 100 is an example buck converter circuit. The circuit 100 may be implemented as an IC on a single die or chip and may further be included on an SoC. The circuit 100 includes a gate driver circuit 102, a first HEMT 104, a second HEMT 106, a diode 108, and a load circuit 110. The load circuit 110 includes an inductor 112, a capacitor 114, and a resistor 116. The first HEMT 104 and second HEMT 106 may be Emode HEMTs and may have a same or similar threshold voltage. A threshold voltage of the diode 108 (e.g., a diode-connected HEMT) may be different from (e.g., less than) a threshold voltage of at least one of the first HEMT 104 or second HEMT 106. For example, a lower threshold voltage of the diode 108 may minimize power loss during deadtime. In some examples, diode 108 is integrated with first HEMT 104 and/or second HEMT 106 (e.g., implemented on the same semiconductor die), to reduce parasitics and overall size of circuit 100.

The first HEMT 104 is electrically coupled between a power terminal (VIN) and a switching terminal (VSW). More specifically, a drain terminal of the first HEMT 104 is electrically coupled to an input terminal (VIN), and source terminal of the first HEMT 104 is electrically coupled to the switching terminal (VSW). The second HEMT 106 and the diode 108 are electrically coupled between the switching terminal (VSW) and a ground terminal. More specifically, a drain terminal of the second HEMT 106 and a cathode of the diode 108 are electrically coupled to the switching terminal (VSW), and a source terminal of the second HEMT 106 and an anode of the diode 108 are electrically coupled to the ground terminal. The gate terminals of the first HEMT 104 and second HEMT 106 are electrically coupled to respective control terminals of the gate driver circuit 102.

A first terminal of the inductor 112 is electrically coupled to the switching terminal (VSW). A second terminal of the inductor 112 is electrically coupled to respective first terminals of the capacitor 114 and resistor 116. Respective second terminals of the capacitor 114 and resistor 116 are electrically coupled to the ground terminal. The capacitor 114 and resistor 116 are electrically coupled in parallel.

FIG. 1B is a circuit schematic of a circuit 130 that includes semiconductor devices according to some examples. The circuit 130 is an example start-up circuit. The circuit 130 may be implemented as an IC on a single die or chip and may further be included on a SoC. The circuit 130 includes a first HEMT 132, a second HEMT 134, a third HEMT 136, and a comparator 138. The circuit 130 further includes a first capacitor 142, a second capacitor 144, a first resistor 146, a second resistor 148, a third resistor 150, and a fourth resistor 152. The first HEMT 132 and a HEMT in the comparator 138 may be Dmode HEMTs and may have different threshold voltages. For example, a magnitude of the threshold voltage (e.g., a negative voltage) of the first HEMT 132 may be greater than a magnitude of the threshold voltage (e.g., a negative voltage) of the HEMT in the comparator 138. The second HEMT 134 and third HEMT 136 may be Emode HEMTs. By having these devices integrated on a single die/chip, parasitic can be reduced, and the overall size of the circuit 130 can be reduced as well.

The first HEMT 132 is electrically coupled between a power terminal (V_{DD}) and a clamp terminal (V_{CLAMP}). More specifically, a source terminal of the first HEMT 132 is electrically coupled to the power terminal (V_{DD}), and a drain terminal of the first HEMT 132 is electrically coupled to the clamp terminal (V_{CLAMP}). Further, a first terminal of the first capacitor 142 is electrically coupled to the power terminal (V_{DD}), and a second terminal of the first capacitor 142 and a gate terminal of the first HEMT 132 are electrically coupled to a ground terminal.

A first terminal of the first resistor 146 and a source terminal of the second HEMT 134 are electrically coupled to the clamp terminal (V_{CLAMP}). A second terminal of the first resistor 146 and a gate terminal of the second HEMT 134 are electrically coupled to a drain terminal of the third HEMT 136. A source terminal of the third HEMT 136 is electrically coupled to a ground terminal.

A drain terminal of the second HEMT 134 is electrically coupled to respective first terminals of the second capacitor 144 and second resistor 148. A second terminal of the second resistor 148 is electrically coupled to a positive (+) input terminal of the comparator 138 (as an input terminal (V_{IN})) and respective first terminals of the third resistor 150 and fourth resistor 152. Respective second terminals of the second capacitor 144 and third resistor 150 are electrically coupled to a ground terminal. A second terminal of the fourth resistor 152 is electrically coupled to an output terminal (V_{O}) of the comparator 138 and a gate terminal of the third HEMT 136. A negative (−) input terminal of the comparator 138 is a reference voltage (V_{REF}) terminal.

The comparator 138 includes a fourth HEMT 160, a fifth HEMT 162, a sixth HEMT 164, a seventh HEMT 166, and an eighth HEMT 168. The HEMTs 160-168 in the comparator 138 may be Dmode HEMTs and may have different threshold voltages from the first HEMT 132. A source terminal of the fourth HEMT 160 is electrically coupled to the power terminal (V_{DD}), and a gate terminal and a drain terminal of the fourth HEMT 160 are electrically coupled to the output terminal (V_{O}). A source terminal of the fifth HEMT 162 is electrically coupled to the output terminal (V_{O}), and a drain terminal of the fifth HEMT 162 is electrically coupled to an internal node (V_{X}). A gate terminal of the fifth HEMT 162 is electrically coupled to the input node (V_{N}). A source terminal of the sixth HEMT 164 is electrically coupled to the power terminal (V_{DD}), and a gate terminal and a drain terminal of the sixth HEMT 164 are electrically coupled to a source terminal of the seventh HEMT 166. A drain terminal of the seventh HEMT 166 is electrically coupled to the internal node (V_{X}), and a gate terminal of the seventh HEMT 166 is electrically coupled to the reference voltage terminal (V_{REF}).

Various examples contemplate circuits implemented on a single die or chip (e.g., on a same semiconductor substrate) that include semiconductor devices of a same Emode or Dmode type that have different threshold voltages. The above-described circuits 100, 130 are merely example circuits that may be implemented on a single die or chip in which semiconductor devices (e.g., HEMTs) of a same type (e.g., Emode or Dmode) have different threshold voltages. Further, one or more semiconductor devices of a different type (e.g., Emode or Dmode) may be included in the circuit. Other circuits may be implemented according to different examples.

Examples of various semiconductor devices are provided in the following description of various figures. Some semiconductor devices may be described as being rated for high or low voltage applications. A high or low voltage rating of a semiconductor device does not indicate a high or low threshold voltage for that semiconductor device. A semiconductor device rated for a high voltage application may have a magnitude of the threshold voltage that is low. Conversely, a semiconductor device rated for a low voltage application may have a magnitude of the threshold voltage that is high. Any combination of high or low voltage rating may be implemented with a high or low threshold voltage.

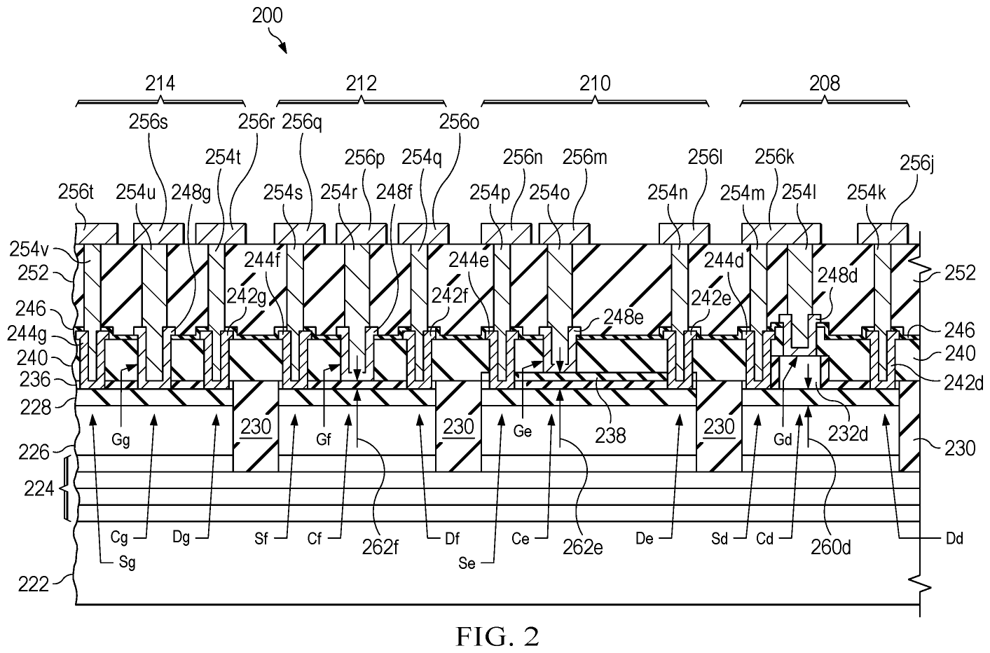

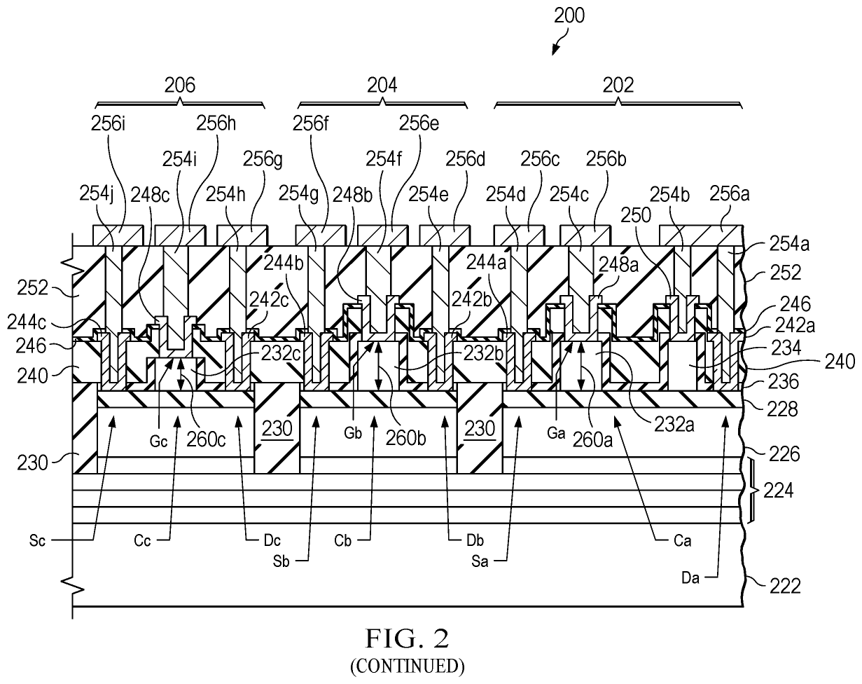

FIGS. 2, 3, 4, 5, 6, 7, 8, and 9 illustrate cross-sectional views of respective ICs. Components described with respect to a figure may be common with other figures. Such components are indicated by like reference numbers in the figures, and description of such components in subsequent figures may be omitted for brevity. Further, a change between components of different figures may result in some change to a component common between those figures. Description of such change may, in some instances, be omitted for brevity; however, such change may be apparent from the figures and may not change the general nature of the that component.

FIG. 2 illustrates a cross-sectional view of an IC 200 according to some examples. The IC 200, in this example, includes a first semiconductor device 202, a second semiconductor device 204, a third semiconductor device 206, a fourth semiconductor device 208, a fifth semiconductor device 210, a sixth semiconductor device 212, and a seventh semiconductor device 214. In the illustrated example, the first semiconductor device 202, second semiconductor device 204, and third semiconductor device 206 are each an Emode HEMT. The fourth semiconductor device 208 is a diode-connected Emode HEMT. The fifth semiconductor device 210, sixth semiconductor device 212, and seventh semiconductor device 214 are each a Dmode HEMT. More particularly, in some examples, the first semiconductor device 202 may be an Emode HEMT that is rated for a high voltage application (e.g., due to in part the large lateral distance between a drain and a gate). The second semiconductor device 204 may be an Emode HEMT that is rated for a low voltage application (e.g., due to in part the smaller lateral distance between a drain and a gate). The low voltage rating is less than the high voltage rating. The third semiconductor device 206 may be an Emode HEMT that is rated for a low voltage application and may be an analog HEMT. The fourth semiconductor device 208 may be an Emode HEMT connected in a diode-connected configuration. The fifth semiconductor device 210 may be a Dmode MIS-HEMT rated for a high voltage application. The sixth semiconductor device 212 may be a Dmode MIS-HEMT rated for a low voltage application. The seventh semiconductor device 214 may be a Dmode HEMT. Other semiconductor devices may be included in addition to the illustrated devices or instead of the illustrated devices. Some examples contemplate that some subset of the illustrated devices may be included in an IC. The illustrated devices are shown for ease to describe various aspects.

In some examples, respective magnitudes of threshold voltages of the first semiconductor device 202 and second semiconductor device 204 are greater than each of the magnitudes of the respective threshold voltages of the third semiconductor device 206 and fourth semiconductor device 208. As described subsequently, the differing threshold voltages may be achieved by different thicknesses of gate layers of the respective semiconductor devices.

In some examples, a magnitude of a threshold voltage of the fifth semiconductor device 210 is less than the magnitude of the threshold voltage of the sixth semiconductor device 212. As described subsequently, the differing threshold voltages may be achieved by differing thicknesses and/or dielectric constants of gate insulator layer(s) between a respective gate terminal and channel region.

FIG. 2 shows a semiconductor substrate 222 and one or more transition layers 224 over and on the semiconductor substrate 222. A channel layer 226 is over and on the uppermost transition layer 224. A barrier layer 228 is over and on the channel layer 226. In some examples, the semiconductor substrate 222, transition layer(s) 224, channel layer 226, and barrier layer 228 may together be considered a semiconductor substrate.

The semiconductor substrate 222 may be a bulk semiconductor substrate, a semiconductor-on-insulator (SOI) substrate, or any other appropriate substrate. For example, the semiconductor substrate 222 may be or include a bulk silicon wafer. The transition layer(s) 224 may include any number of layers of any materials that are configured to accommodate lattice mismatch between the semiconductor substrate 222 and the channel layer 226 (e.g., to reduce or minimize lattice defect generation and/or propagation in the channel layer 226). For example, the transition layer(s) 224 may have a gradient concentration of one or more elements in a direction normal to the upper surface of the semiconductor substrate 222. Further, a layer of the transition layer(s) 224 may be a doped buffer layer.

The channel layer 226 is configured, possibly in conjunction with the barrier layer 228, to conduct and confine charge carriers (such as electrons) within two dimensions. In some examples, the channel layer 226 is configured to include a two-dimensional electron gas (2DEG) in various examples. The 2DEG may be formed by energy band bending resulting from the barrier layer 228 being over and on the channel layer 226. In some examples, the channel layer 226 may be a portion of a semiconductor substrate (e.g., without transition layer(s)), and/or the semiconductor substrate 222 with the transition layer(s) 224 and the channel layer 226 may be considered a semiconductor substrate. In some examples, the channel layer 226 includes a gallium nitride (GaN) layer and, in such examples, may be referred to as a GaN channel layer. In some examples, the material of the channel layer 226 is or includes an unintentionally doped material, such as a material doped by diffusion of dopants from another layer, or is or includes an intrinsic material. The barrier layer 228, in some examples, may be or include an aluminum gallium nitride (AlGaN) layer and, in such examples, may be referred to as an AlGaN barrier layer. In some examples, the channel layer 226 may be or include indium aluminum gallium nitride (InᵢAlⱼGa₁₋ᵢ₋ⱼN) (where 0≤i≤1, 0≤j≤1, and 0≤i+j≤1), and the barrier layer 228 may be or include indium aluminum gallium nitride (InₖAlₗGa₁₋ₖ₋ₗN) (where 0≤k≤1, 0≤l≤1, and 0≤k+l≤1). Other materials may be implemented for the channel layer 226 and/or the barrier layer 228.

Isolation structures 230 are through the barrier layer 228 and channel layer 226 and into the transition layer(s) 224. The isolation structures 230 may be or include shallow trench isolations (STIs), deep trench isolations (DTIs), doped regions, implanted regions (e.g., undoped to amorphize), or other isolation structures. The isolation structures 230 are laterally between neighboring semiconductor devices 204-214 and may provide electrical isolation between the semiconductor devices 204-214. Other isolation techniques that may be implemented are described subsequently.

Gate layers 232a, 232b, 232c, 232d are over and on an upper surface of the barrier layer 228. In some examples, the gate layers 232a, 232b, 232c, 232d are or include a semiconductor layer of a semiconductor material. Further, in some examples, the gate layers 232a-232d are doped with a dopant. In some examples, the gate layers 232a-232d are doped with a p-type dopant. In some examples, the gate layers 232a-232d may be or include a gallium nitride (GaN) layer, such as indium aluminum gallium nitride (InₘAlₙGa₁₋ₘ₋ₙN) (where 0≤m<1, 0≤n<1, and 0≤m+n≤1), and the dopant with which the gate layers 232a-232d are doped is a p-type dopant, which may be or include magnesium (Mg), carbon (C), zinc (Zn), the like, or a combination thereof. In examples in which the gate layers 232a-232d are gallium nitride (GaN) doped with a p-type dopant, the gate layer 232 may be referred to as a p-doped GaN (pGaN) layer. Further, in examples in which the gate layers 232a-232d are gallium nitride (GaN) doped with a magnesium, the gate layers 232a-232d may be referred to as a magnesium doped gallium nitride (GaN:Mg) layer. In some examples, a concentration of the dopant in the gate layers 232a-232d, which is electrically activated, is equal to or greater than 1×10¹⁷ cm⁻³. In some examples, the concentration is equal to or greater than 1×10¹⁸ cm⁻³. In some examples, the dopant in the gate layers 232a-232d may have a uniform concentration, which may be equal or different between the gate layers 232a-232d. In some examples, the dopant in the gate layers 232a-232d may have a gradient concentration, which may be a same or different gradient concentration between the gate layers 232a-232d. Other materials, dopants, and/or concentrations may be implemented in other examples.

An injection layer 234 is over and on the upper surface of the barrier layer 228. The injection layer 234 may be or include a same material as the gate layers 232a-232d, including being doped like one or more of the gate layers 232a-232d.

A first dielectric layer 236 is over and on the upper surface of the barrier layer 228, on and along sidewalls of the gate layers 232a-232b, and over and on upper surfaces of the gate layers 232a, 232b and injection layer 234. In some examples, the first dielectric layer 236 may be or include silicon oxide, silicon nitride, or the like. A second dielectric layer 238 is over and on the first dielectric layer 236 within a region of the fifth semiconductor device 210. A material of the second dielectric layer 238 is different from a material of the first dielectric layer 236. The dielectric constant of the second dielectric layer 238 may be different from the dielectric constant of the first dielectric layer 236. In some examples, the second dielectric layer 238 may be or include silicon nitride or the like.

A third dielectric layer 240, which may be a pre-metal dielectric layer (PMD), is over and on the first dielectric layer 236 and second dielectric layer 238. In some examples, the third dielectric layer 240 is or includes silicon nitride (SiN), silicon oxide (SiO₂), silicon oxynitride (SiON), or aluminum oxide (Al₂O₃), although in other examples, the third dielectric layer 240 may be or include another one or more other dielectric materials.

Drain metal contacts 242a, 242b, 242c, 242d, 242e, 242f, 242g and source metal contacts 244a, 244b, 244c, 244d, 244e, 244f, 244g are through the third dielectric layer 240 and the first dielectric layer 236 and contact the barrier layer 228. In some examples, the metal contacts 242a-242g, 244a-244g may extend into the barrier layer 228, and still further examples, the metal contacts 242a-242g, 244a-244g may be through the barrier layer 228 and contact the channel layer 226. The metal contacts 242a-242g, 244a-244g may be or include metal, such as titanium nitride (TiN), tantalum nitride (TaN), titanium (Ti), aluminum (Al), copper (Cu), tungsten (W), the like, or a combination thereof.

A fourth dielectric layer 246 is over and on the third dielectric layer 240 and the metal contacts 242a-242g, 244a-244g. In some examples, the fourth dielectric layer 246 is or includes a nitride, such as silicon nitride (SiN), although in other examples, the fourth dielectric layer 246 may be or include another one or more other dielectric materials.

Gate metal contacts 248a, 248b, 248c, 248d, 248e, 248f, 248g and injection metal contact 250 are through the fourth dielectric layer 246 and third dielectric layer 240. The gate metal contact 248a is also through the first dielectric layer 236 and contacts the gate layer 232a. The injection metal contact 250 is also through the first dielectric layer 236 and contacts the injection layer 234. The gate metal contact 248b is also through the first dielectric layer 236 and contacts the gate layer 232b. The gate metal contact 248c contacts the gate layer 232c. The gate metal contact 248d contacts the gate layer 232d. The gate metal contact 248e contacts the second dielectric layer 238. The gate metal contact 248f contacts the first dielectric layer 236. The gate metal contact 248g is also through the first dielectric layer 236 and contacts the barrier layer 228. As illustrated, the metal contacts 248a-248g, 250 may be layers conformally along surfaces that define respective openings in which the metal contacts 248a-248g, 250 are formed. In other examples, the metal contacts 248a-248g, 250 may fill openings in which the metal contacts 248a-248g, 250 are formed.

The metal contacts 248a-248g, 250 may include or be any appropriate metal. In some semiconductor devices, a gate metal contact may form a Schottky junction with the gate layer. As examples, when the gate layer is magnesium doped gallium nitride (GaN:Mg), metal that may form a Schottky junction with the gate layer may be or include titanium (Ti), titanium tungsten (TiW), titanium nitride (TiN), nickel (Ni), platinum (Pt), tantalum nitride (TaN), copper (Cu), tungsten (W), or alloys thereof. As examples, when the gate layer is magnesium doped gallium nitride (GaN:Mg), metal that may form an ohmic junction with the gate layer may be or include gold (Au), aluminum (Al), or alloys thereof, which alloys may include titanium tungsten aluminum (TiWAl) and titanium aluminum nitride (TiAlN).

A fifth dielectric layer 252, which may be an inter-layer dielectric layer (ILD), is over and on the fourth dielectric layer 246 and metal contacts 248a-248g, 250. The fifth dielectric layer 252 may be a single dielectric layer or may include multiple dielectric layers of a same dielectric material or different dielectric materials. For example, the fifth dielectric layer 252 may include a silicon nitride, a silicon oxide-based material (such as a phosphosilicate glass (PSG) or a tetraethyl orthosilicate (TEOS) oxide), polytetrafluoroethylene, or the like.

Metal vias 254a through 254v are through the fifth dielectric layer 252. Metal via 254a is also through the fourth dielectric layer 246 and contacts the drain metal contact 242a. Metal via 254b contacts the injection metal contact 250. Metal via 254c contacts the gate metal contact 248a. Metal via 254d is also through the fourth dielectric layer 246 and contacts the source metal contact 244a. Metal via 254e is also through the fourth dielectric layer 246 and contacts the drain metal contact 242b. Metal via 254f contacts the gate metal contact 248b. Metal via 254g is also through the fourth dielectric layer 246 and contacts the source metal contact 244b. Metal via 254h is also through the fourth dielectric layer 246 and contacts the drain metal contact 242c. Metal via 254i contacts the gate metal contact 248c. Metal via 254j is also through the fourth dielectric layer 246 and contacts the source metal contact 244c. Metal via 254k is also through the fourth dielectric layer 246 and contacts the drain metal contact 242d. Metal via 254l contacts the gate metal contact 248d. Metal via 254m is also through the fourth dielectric layer 246 and contacts the source metal contact 244d. Metal via 254n is also through the fourth dielectric layer 246 and contacts the drain metal contact 242e. Metal via 254o contacts the gate metal contact 248e. Metal via 254p is also through the fourth dielectric layer 246 and contacts the source metal contact 244e. Metal via 254q is also through the fourth dielectric layer 246 and contacts the drain metal contact 242f. Metal via 254r contacts the gate metal contact 248f. Metal via 254s is also through the fourth dielectric layer 246 and contacts the source metal contact 244f. Metal via 254t is also through the fourth dielectric layer 246 and contacts the drain metal contact 242g. Metal via 254u contacts the gate metal contact 248g. Metal via 254v is also through the fourth dielectric layer 246 and contacts the source metal contact 244g.

Metal lines 256a through 256t are over and on the fifth dielectric layer 252. Metal line 256a is further over and on (and electrically couples) the metal vias 254a, 254b. Metal lines 256b-256j are further over and on (and electrically couple) the metal vias 254c-254k, respectively. Metal line 256k is further over and on (and electrically couples) the metal vias 2541, 254m. Metal lines 2561-256t are further over and on (and electrically couple) the metal vias 254n-254v, respectively. The metal vias 254a-254v may each include (i) one or more metal-barrier and/or adhesion layers (e.g., titanium nitride (TiN), tantalum nitride (TaN), the like, or a combination thereof) conformally in a respective opening through the fifth dielectric layer 252 and, where applicable, the fourth dielectric layer 246, and (ii) a fill metal (e.g., aluminum (Al), copper (Cu), tungsten (W), the like, or a combination thereof) over and/or on the metal-barrier and/or adhesion layer(s). The metal lines 256a-256t may each include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof) over and/or on the metal-barrier and/or adhesion layer(s). In some examples, some of the metal lines 256a-256t may implement or include respective field plates for the semiconductor devices for electric field management.

The first semiconductor device 202 includes a first source terminal Sa, a first channel region Ca, a first drain terminal Da, and a first gate terminal Ga. The first gate terminal Ga is or includes the gate layer 232a. The first channel region Ca is in the channel layer 226 underlying the first gate terminal Ga. The first channel region Ca is laterally between the first drain terminal Da and the first source terminal Sa, which are also in the channel layer 226. The drain metal contact 242a is electrically coupled to the first drain terminal Da, and the source metal contact 244a is electrically coupled to the first source terminal Sa. The gate metal contact 248a is electrically coupled to the first gate terminal Ga (e.g., the gate layer 232a). The first gate terminal Ga and gate metal contact 248a are laterally between the drain metal contact 242a and the source metal contact 244a. Further, the injection layer 234 is laterally between the gate layer 232a and the drain metal contact 242a. The injection layer 234 is electrically coupled with the drain metal contact 242a through the injection metal contact 250, metal vias 254a, 254b, and metal line 256a. The injection layer 234 electrically coupled with the drain metal contact 242a forms a hybrid drain.

The second semiconductor device 204 includes a second source terminal Sb, a second channel region Cb, a second drain terminal Db, and a second gate terminal Gb. The second gate terminal Gb is or includes the gate layer 232b. The second channel region Cb is in the channel layer 226 underlying the second gate terminal Gb. The second channel region Cb is laterally between the second drain terminal Db and the second source terminal Sb, which are also in the channel layer 226. The drain metal contact 242b is electrically coupled to the second drain terminal Db, and the source metal contact 244b is electrically coupled to the second source terminal Sb. The gate metal contact 248b is electrically coupled to the second gate terminal Gb (e.g., the gate layer 232b). The second gate terminal Gb and gate metal contact 248b are laterally between the drain metal contact 242b and the source metal contact 244b.

The third semiconductor device 206 includes a third source terminal Sc, a third channel region Cc, a third drain terminal Dc, and a third gate terminal Gc. The third gate terminal Gc is or includes the gate layer 232c. The third channel region Cc is in the channel layer 226 underlying the third gate terminal Gc. The third channel region Cc is laterally between the third drain terminal Dc and the third source terminal Sc, which are also in the channel layer 226. The drain metal contact 242c is electrically coupled to the third drain terminal Dc, and the source metal contact 244c is electrically coupled to the third source terminal Sc. The gate metal contact 248c is electrically coupled to the third gate terminal Gc (e.g., the gate layer 232c). The third gate terminal Gc and gate metal contact 248c are laterally between the drain metal contact 242c and the source metal contact 244c.

The fourth semiconductor device 208 includes a fourth source terminal Sd, a fourth channel region Cd, a fourth drain terminal Dd, and a fourth gate terminal Gd. The fourth gate terminal Gd is or includes the gate layer 232d. The fourth channel region Cd is in the channel layer 226 underlying the fourth gate terminal Gd. The fourth channel region Cd is laterally between the fourth drain terminal Dd and the fourth source terminal Sd, which are also in the channel layer 226. The drain metal contact 242d is electrically coupled to the fourth drain terminal Dd, and the source metal contact 244d is electrically coupled to the fourth source terminal Sd. The gate metal contact 248d is electrically coupled to the fourth gate terminal Gd (e.g., the gate layer 232d). The fourth gate terminal Gd and gate metal contact 248d are laterally between the drain metal contact 242d and the source metal contact 244d. The fourth gate terminal Gd is electrically coupled to the fourth source terminal Sd through the gate metal contact 248d, metal vias 2541, 254m, metal line 256k, and source metal contact 244d. Hence, the fourth semiconductor device 208 is electrically connected in a diode-connected configuration.

The fifth semiconductor device 210 includes a fifth source terminal Se, a fifth channel region Ce, a fifth drain terminal De, and a fifth gate terminal Ge. The fifth gate terminal Ge is or includes the gate metal contact 248e. The fifth channel region Ce is in the channel layer 226 underlying the fifth gate terminal Ge. A gate insulator or gate dielectric layer (e.g., the first dielectric layer 236 and second dielectric layer 238) is vertically between the fifth gate terminal Ge (e.g., the gate metal contact 248e) and the fifth channel region Ce, and more particularly, between the gate metal contact 248e and the barrier layer 228. The fifth channel region Ce is laterally between the fifth drain terminal De and the fifth source terminal Se, which are also in the channel layer 226. The drain metal contact 242e is electrically coupled to the fifth drain terminal De, and the source metal contact 244e is electrically coupled to the fifth source terminal Se. The fifth gate terminal Ge (e.g., gate metal contact 248e) is laterally between the drain metal contact 242e and the source metal contact 244e.

The sixth semiconductor device 212 includes a sixth source terminal Sf, a sixth channel region Cf, a sixth drain terminal Df, and a sixth gate terminal Gf. The sixth gate terminal Gf is or includes the gate metal contact 248f. The sixth channel region Cf is in the channel layer 226 underlying the sixth gate terminal Gf. A gate insulator or gate dielectric layer (e.g., the first dielectric layer 236) is vertically between the sixth gate terminal Gf (e.g., the gate metal contact 248f) and the sixth channel region Cf, and more particularly, between the gate metal contact 248f and the barrier layer 228. The sixth channel region Cf is laterally between the sixth drain terminal Df and the sixth source terminal Sf, which are also in the channel layer 226. The drain metal contact 242f is electrically coupled to the sixth drain terminal Df, and the source metal contact 244f is electrically coupled to the sixth source terminal Sf. The sixth gate terminal Gf (e.g., gate metal contact 248f) is laterally between the drain metal contact 242f and the source metal contact 244f.

The seventh semiconductor device 214 includes a seventh source terminal Sg, a seventh channel region Cg, a seventh drain terminal Dg, and a seventh gate terminal Gg. The seventh gate terminal Gg is or includes the gate metal contact 248g. The seventh channel region Cg is in the channel layer 226 underlying the seventh gate terminal Gg. The seventh channel region Cg is laterally between the seventh drain terminal Dg and the seventh source terminal Sg, which are also in the channel layer 226. The drain metal contact 242g is electrically coupled to the seventh drain terminal Dg, and the source metal contact 244g is electrically coupled to the seventh source terminal Sg. The seventh gate terminal Gg (e.g., gate metal contact 248g) is laterally between the drain metal contact 242g and the source metal contact 244g.

The gate layer 232a of the first semiconductor device 202 has a thickness/height 260a (e.g., in a direction perpendicular to the upper surface of the barrier layer 228, and between the upper surface of the barrier layer 228 and metal contact 248a). The gate layer 232b of the second semiconductor device 204 has a thickness 260b (e.g., between the upper surface of the barrier layer 228 and metal contact 248b). The thickness 260b may be equal to the thickness 260a. The gate layer 232c of the third semiconductor device 206 has a thickness 260c (e.g., between the upper surface of the barrier layer 228 and metal contact 248c). The gate layer 232d of the fourth semiconductor device 208 has a thickness 260d. The thickness 260d may be equal to the thickness 260c. The thickness 260a and thickness 260b are each greater than each of the thickness 260c and thickness 260d.

The differences in thicknesses results in the magnitude of the threshold voltage of the first semiconductor device 202 being different from (e.g., greater than) each of the respective magnitudes of the threshold voltages of the third semiconductor device 206 and fourth semiconductor device 208. The differences in thicknesses/heights results in the magnitude of the threshold voltage of the second semiconductor device 204 being greater than each of the respective magnitudes of the threshold voltages of the third semiconductor device 206 and fourth semiconductor device 208. The threshold voltages of the first semiconductor device 202 and the second semiconductor device 204 may be equal, and the threshold voltages of the third semiconductor device 206 and the fourth semiconductor device 208 may be equal. The threshold voltages of the semiconductor devices 202-208 may be positive voltages.

The gate insulator or gate dielectric layer (e.g., the first dielectric layer 236 and second dielectric layer 238) of the fifth semiconductor device 210 has a thickness/height 262e (e.g., in a direction perpendicular to the upper surface of the barrier layer 228, and between the upper surface of the barrier layer 228 and metal contact 248e). The gate insulator (e.g., the first dielectric layer 236) of the sixth semiconductor device 212 has a thickness 262f (e.g., between the upper surface of the barrier layer 228 and metal contact 248f). The thickness 262f is less than the thickness 262e. The seventh semiconductor device 214 does not include a gate insulator or gate dielectric layer between the seventh gate terminal Gg and the seventh channel region Cg.

The differences in effective gate-to-channel capacitances result in the magnitude of the threshold voltage of the fifth semiconductor device 210 being greater than each of the respective magnitudes of the threshold voltages of the sixth semiconductor device 212 and seventh semiconductor device 214. The difference in effective gate-to-channel capacitances results in the magnitude of the threshold voltage of the sixth semiconductor device 212 being greater than the magnitude of the threshold voltage of the seventh semiconductor device 214. A difference in effective gate-to-channel capacitances may be achieved by differences in thicknesses and/or absence of a gate insulator or gate dielectric layer and/or differences in effective dielectric constants of a gate insulator or gate dielectric layer. The threshold voltages of the semiconductor devices 210-214 may be negative voltages.

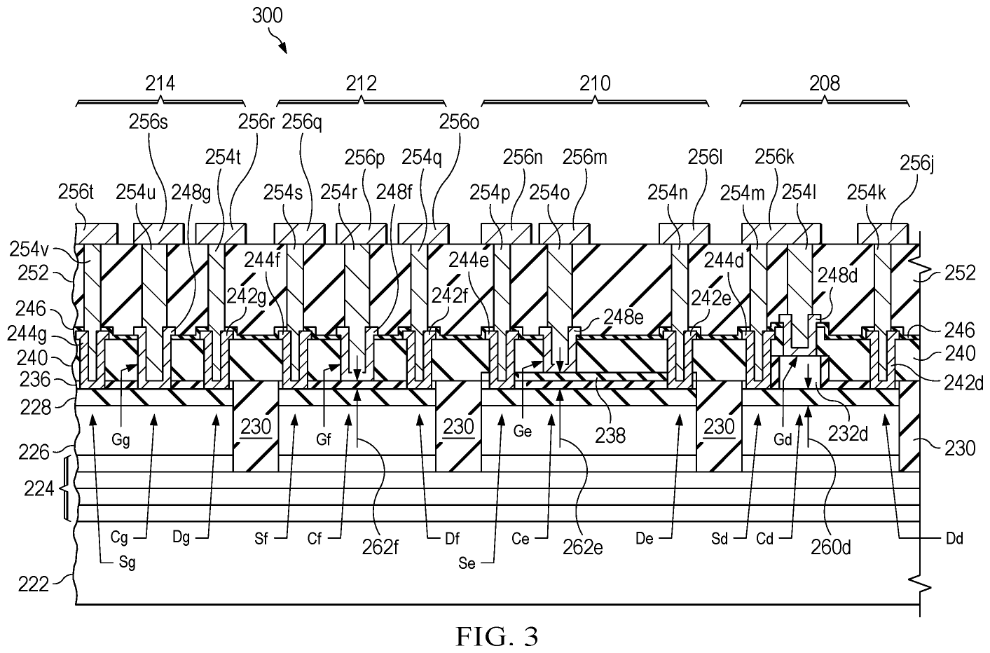

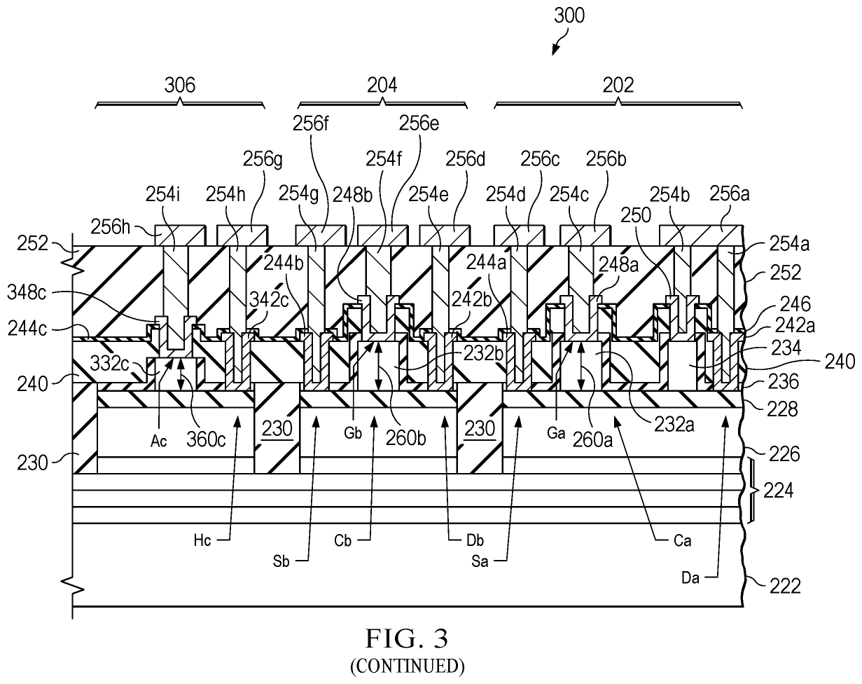

FIG. 3 illustrates a cross-sectional view of an IC 300 according to some examples. The IC 300, in this example, includes a first semiconductor device 202, a second semiconductor device 204, a third semiconductor device 306, a fourth semiconductor device 208, a fifth semiconductor device 210, a sixth semiconductor device 212, and a seventh semiconductor device 214. The semiconductor devices 202, 204, 208, 210, 212, 214 are as described above with respect to FIG. 2. In the illustrated example of FIG. 3, the third semiconductor device 306 is a two-terminal diode. Other semiconductor devices may be included in addition to the illustrated devices or instead of the illustrated devices. Some examples contemplate that some subset of the illustrated devices may be included in an IC. The illustrated devices are shown for ease to describe various aspects.

An anode layer 332c is over and on an upper surface of the barrier layer 228. The anode layer 332c may have similar structure and/or material(s) as the gate layer 232c described above. A cathode metal contact 342c is through the third dielectric layer 240 and the first dielectric layer 236 and contacts the barrier layer 228. The cathode metal contact 342c may have similar structure and/or material(s) as the drain metal contact 242c described above. An anode metal contact 348c is through the fourth dielectric layer 246 and third dielectric layer 240. The anode metal contact 348c contacts the anode layer 332c. The anode metal contact 348c may have similar structure and/or material(s) as the gate metal contact 248c described above. The anode metal contact 348c may form an ohmic junction with the anode layer 332c.

The third semiconductor device 306 includes a cathode terminal He and an anode terminal Ac. The anode terminal Ac is or includes the anode layer 332c. The cathode terminal He is in the channel layer 226 a lateral distance from the anode terminal Ac. The cathode metal contact 342c is electrically coupled to the cathode terminal Hc. The anode metal contact 348c is electrically coupled to the anode terminal Ac (e.g., the anode layer 332c).

The anode layer 332c of the third semiconductor device 306 has a thickness 360c. The thickness 260d (of the gate layer 232d) may be equal to the thickness 360c (e.g., between the upper surface of the barrier layer 228 and metal contact 348c). The thickness 260a (of the gate layer 232a) and thickness 260b (of the gate layer 232b) are each greater than the thickness 360c. The differences in thicknesses results in the magnitudes of the threshold voltages of the first semiconductor device 202 and second semiconductor device being greater than the magnitude of the threshold voltage of the third semiconductor device 306. The threshold voltages of the third semiconductor device 306 and the fourth semiconductor device 208 may be equal. The threshold voltages of the semiconductor devices 202, 204, 306, 208 may be positive voltages.

Although not illustrated in subsequent figures, the third semiconductor device 306 may be included in ICs of other examples. The third semiconductor device 306 may be included in addition to other semiconductor devices described with respect to various examples or may be included replacing another semiconductor device described with respect to various examples.

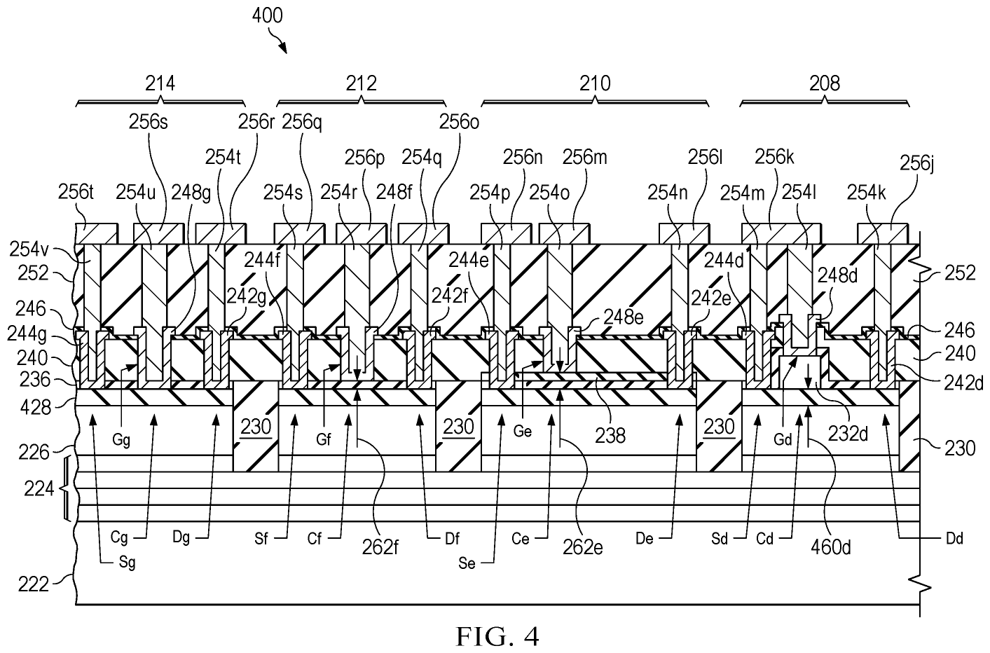

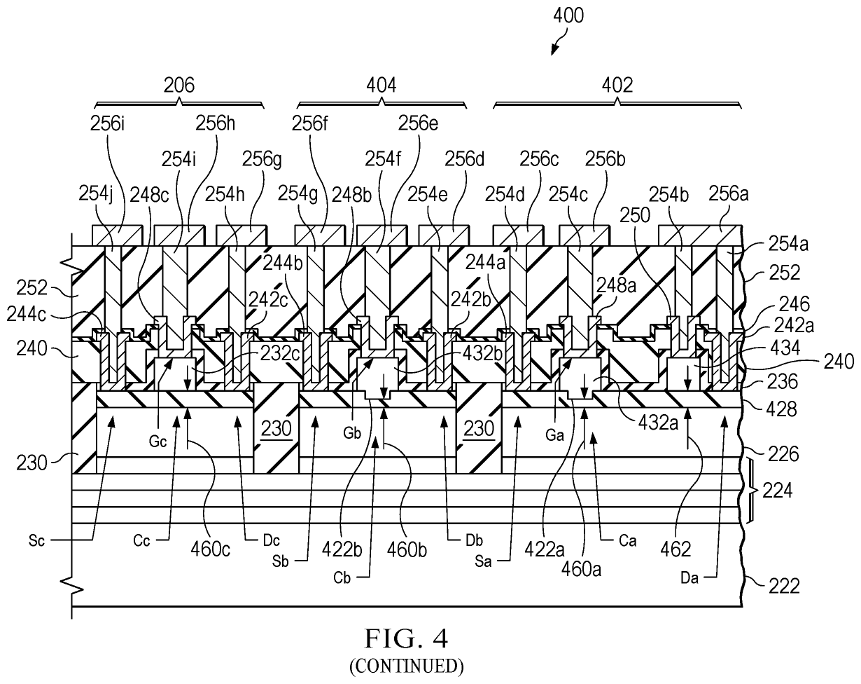

FIG. 4 illustrates a cross-sectional view of an IC 400 according to some examples. The IC 400, in this example, includes a first semiconductor device 402, a second semiconductor device 404, a third semiconductor device 206, a fourth semiconductor device 208, a fifth semiconductor device 210, a sixth semiconductor device 212, and a seventh semiconductor device 214. The semiconductor devices 206, 208, 210, 212, 214 are as described above with respect to FIG. 2. In the illustrated example, the first semiconductor device 402 and second semiconductor device 404 are each an Emode HEMT. More particularly, in some examples, the first semiconductor device 402 may be an Emode HEMT that is rated for a high voltage application and may be a power HEMT. The second semiconductor device 404 may be an Emode HEMT that is rated for a low voltage application and may be a power HEMT. Other semiconductor devices may be included in addition to the illustrated devices or instead of the illustrated devices. Some examples contemplate that some subset of the illustrated devices may be included in an IC. The illustrated devices are shown for ease to describe various aspects.

In some examples, respective magnitudes of threshold voltages of the first semiconductor device 402 and second semiconductor device 404 are greater than each of the magnitudes of the respective threshold voltages of the third semiconductor device 206 and fourth semiconductor device 208. As described subsequently, the different threshold voltages may be achieved by different thicknesses of barrier layers of the semiconductor devices. Although described in the context of the first and second semiconductor devices 402, 404 compared to the third and fourth semiconductor devices 206, 208, at least one of the fifth, sixth, and seventh semiconductor devices 210, 212, 214 may likewise have a different threshold voltage from another of the fifth, sixth, and seventh semiconductor devices 210, 212, 214 because of different thicknesses of barrier layers of the respective semiconductor devices.

A barrier layer 428 is over and on the channel layer 226. Gate recesses 422a, 422b are in the barrier layer 428. The barrier layer 428 may be a material as described above with respect to the barrier layer 228. Gate layers 432a, 432b are at least partially in the gate recesses 422a, 422b, respectively, and may also be partially over and on an upper surface of the barrier layer 428. An injection layer 434 is over and on the upper surface of the barrier layer 428. The gate layers 432a, 432b may be a material as described above with respect to the gate layers 232a, 232b. Similarly, the injection layer 434 may be a material as described above with respect to the injection layer 234.

The first semiconductor device 402 includes a first source terminal Sa, a first channel region Ca, a first drain terminal Da, and a first gate terminal Ga. The first gate terminal Ga is or includes the gate layer 432a. The first channel region Ca is in the channel layer 226 underlying the first gate terminal Ga and underlying the gate recess 422a, in which the gate layer 432a is at least partially disposed. The first channel region Ca is laterally between the first drain terminal Da and the first source terminal Sa, which are also in the channel layer 226. The metal contacts 242a, 244a, 248a are electrically coupled similarly as described above with respect to FIG. 2. Further, the injection layer 434 is laterally between the gate layer 432a and the drain metal contact 242a. The injection layer 434 is electrically coupled with the drain metal contact 242a similarly as described above with respect to FIG. 2. The injection layer 434 electrically coupled with the drain metal contact 242a forms a hybrid drain.

The second semiconductor device 404 includes a second source terminal Sb, a second channel region Cb, a second drain terminal Db, and a second gate terminal Gb. The second gate terminal Gb is or includes the gate layer 432b. The second channel region Cb is in the channel layer 226 underlying the second gate terminal Gb and underlying the gate recess 422b, in which the gate layer 432b is at least partially disposed. The second channel region Cb is laterally between the second drain terminal Db and the second source terminal Sb, which are also in the channel layer 226. The metal contacts 242b, 244b, 248b are electrically coupled similarly as described above with respect to FIG. 2.

The barrier layer 428 in the first semiconductor device 402 has a thickness 460a (e.g., in a direction perpendicular to the upper surface of the barrier layer 428) at the gate recess 422a (e.g., from a bottom surface of the gate recess 422a to a bottom surface of the barrier layer 428, and between the gate layer 432a and the channel layer 226). The barrier layer 428 in the second semiconductor device 404 has a thickness 460b at the gate recess 422b (e.g., between the gate layer 432b and the channel layer 226). The thickness 460b may be equal to the thickness 460a. The barrier layer 428 in the third semiconductor device 206 has a thickness 460c (e.g., between the gate layer 232c and the channel layer 226). The barrier layer 428 in the fourth semiconductor device 208 has a thickness 460d (e.g., between the gate layer 232d and the channel layer 226). The thickness 460d may be equal to the thickness 460c. The thickness 460a and thickness 460b are each less than each of the thickness 460c and thickness 460d.

The differences in thicknesses result in the magnitude of the threshold voltage of the first semiconductor device 402 being greater than each of the respective magnitudes of the threshold voltages of the third semiconductor device 206 and fourth semiconductor device 208. The differences in thicknesses result in the magnitude of the threshold voltage of the second semiconductor device 404 being greater than each of the respective magnitudes of the threshold voltages of the third semiconductor device 206 and fourth semiconductor device 208. The threshold voltages of the first semiconductor device 402 and the second semiconductor device 404 may be equal, and the threshold voltages of the third semiconductor device 206 and the fourth semiconductor device 208 may be equal. The threshold voltages of the semiconductor devices 202-208 may be positive voltages.

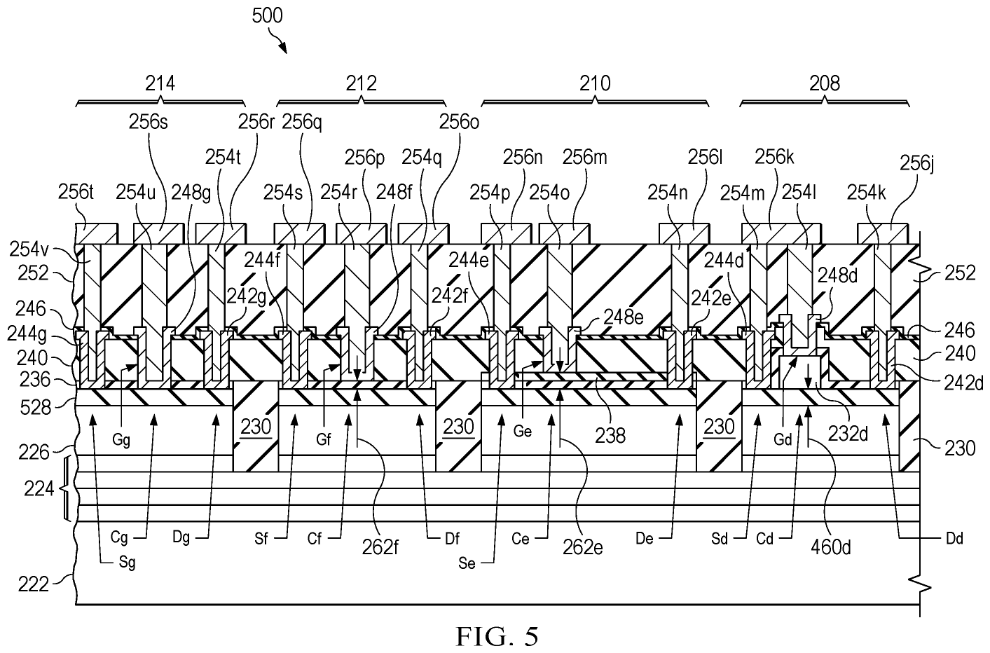

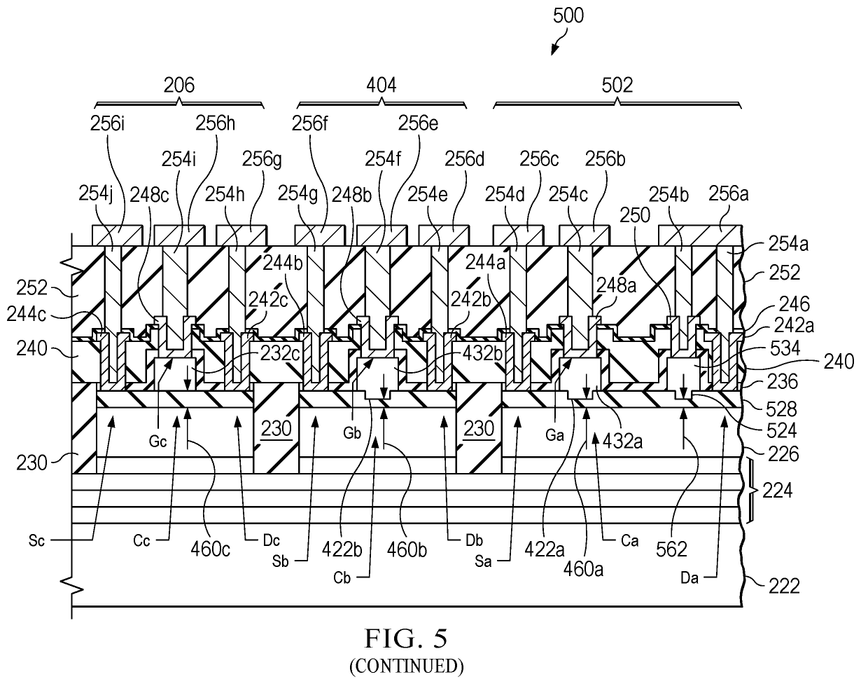

FIG. 5 illustrates a cross-sectional view of an IC 500 according to some examples. The IC 500, in this example, includes a first semiconductor device 502, a second semiconductor device 404, a third semiconductor device 206, a fourth semiconductor device 208, a fifth semiconductor device 210, a sixth semiconductor device 212, and a seventh semiconductor device 214. The semiconductor devices 404, 206, 208, 210, 212, 214 are as described above with respect to FIGS. 2 and 4. In the illustrated example, the first semiconductor device 402 is an Emode HEMT. More particularly, in some examples, the first semiconductor device 402 may be an Emode HEMT that is rated for a high voltage application and may be a power HEMT. Other semiconductor devices may be included in addition to the illustrated devices or instead of the illustrated devices. Some examples contemplate that some subset of the illustrated devices may be included in an IC. The illustrated devices are shown for ease to describe various aspects.

In some examples, respective magnitudes of threshold voltages of the first semiconductor device 502 and second semiconductor device 404 are greater than each of the magnitudes of the respective threshold voltages of the third semiconductor device 206 and fourth semiconductor device 208. As described previously, the differing threshold voltages may be achieved by different thicknesses of barrier layers of the semiconductor devices.

A barrier layer 528 is over and on the channel layer 226. The barrier layer 528 is like the barrier layer 428 in FIG. 4 and has an injection recess 524 therein. An injection layer 534 is at least partially in the injection recess 524 and may further be partially over and on the upper surface of the barrier layer 428. The injection layer 534 may be a material as described above with respect to the injection layer 234.

The first semiconductor device 502 includes a first source terminal Sa, a first channel region Ca, a first drain terminal Da, and a first gate terminal Ga. The first gate terminal Ga is or includes the gate layer 432a. The first channel region Ca is in the channel layer 226 underlying the first gate terminal Ga and underlying the gate recess 422a, in which the gate layer 432a is at least partially disposed. The first channel region Ca is laterally between the first drain terminal Da and the first source terminal Sa, which are also in the channel layer 226. The metal contacts 242a, 244a, 248a are electrically coupled similarly as described above with respect to FIG. 2. Further, the injection layer 534 and the injection recess 524 (in which the injection layer 534 is at least partially) are laterally between the gate layer 432a and the drain metal contact 242a. The injection layer 534 is electrically coupled with the drain metal contact 242a similarly as described above with respect to FIG. 2. The injection layer 534 electrically coupled with the drain metal contact 242a forms a hybrid drain.

Referring to FIGS. 4, the barrier layer 428 has a thickness 462 at the injection layer 434, and referring to FIG. 5, the barrier layer 528 has a thickness 562 at the injection layer 434, which is less than the thickness 462. Varying the thickness of the barrier layer at the injection layer, such as illustrated by the thicknesses 462, 562, may change a drain-to-source on resistance (Rdson). A larger thickness, such as thickness 462, may result in a lower Rdson, while a smaller thickness, such as thickness 562, may result in a higher Rdson.

Although subsequent figures illustrate a hybrid drain as shown in FIG. 4 (e.g., with the injection layer 434 without an injection recess in a barrier layer), various examples described subsequently and illustrated in the figures may be modified to include a hybrid drain as shown in FIG. 5 (e.g., with the injection layer 534 in an injection recess 524 in a barrier layer).

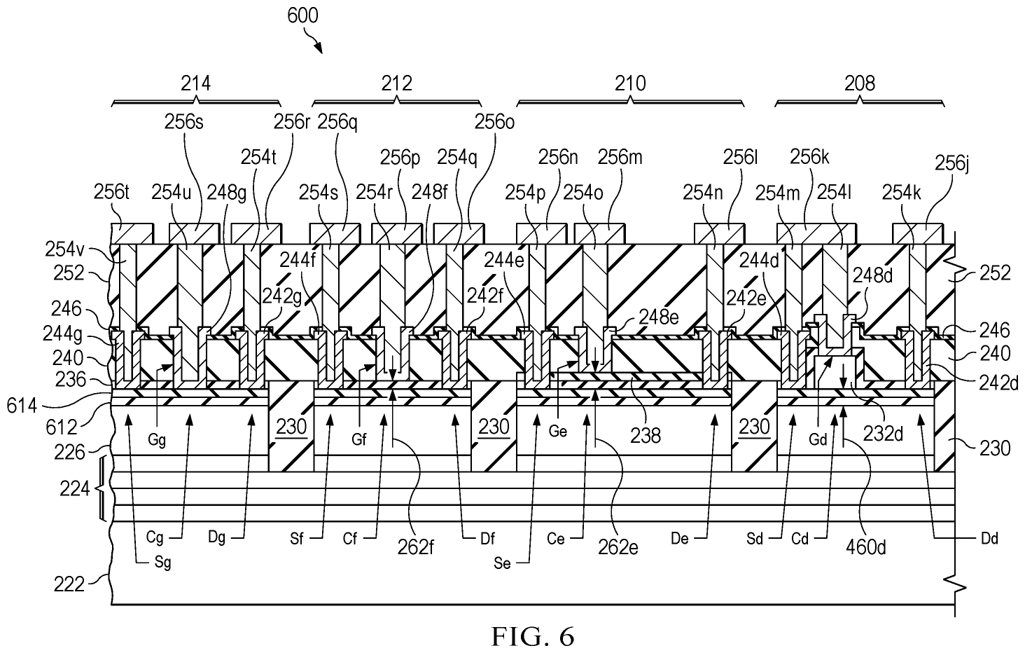

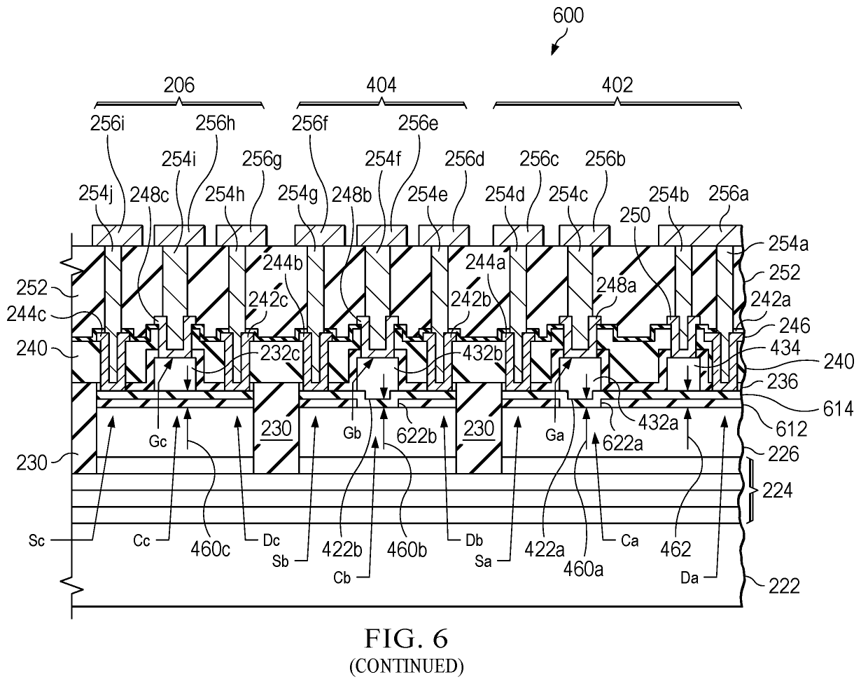

FIG. 6 illustrates a cross-sectional view of an IC 600 according to some examples. The IC 600, in this example, includes a first semiconductor device 402, a second semiconductor device 404, a third semiconductor device 206, a fourth semiconductor device 208, a fifth semiconductor device 210, a sixth semiconductor device 212, and a seventh semiconductor device 214. The semiconductor devices 402, 404, 206, 208, 210, 212, 214 are as described above with respect to FIGS. 2 and 4. Other semiconductor devices may be included in addition to the illustrated devices or instead of the illustrated devices. Some examples contemplate that some subset of the illustrated devices may be included in an IC. The illustrated devices are shown for ease to describe various aspects.

In some examples, respective magnitudes of threshold voltages of the first semiconductor device 402 and second semiconductor device 404 are greater than each of the magnitudes of the respective threshold voltages of the third semiconductor device 206 and fourth semiconductor device 208. As described subsequently, the differing threshold voltages may be achieved by different thicknesses of barrier layers of the semiconductor devices.

The barrier layer in the semiconductor devices 402, 404, 206, 208, 210, 212, 214 includes a first barrier sub-layer 612 and a second barrier sub-layer 614. The first barrier sub-layer 612 is over and on the channel layer 226. Openings 622a, 622b are through the first barrier sub-layer 612. The second barrier sub-layer 614 is conformally over and on the first barrier sub-layer 612. The second barrier sub-layer 614 is conformally on surfaces of sidewall surfaces of the first barrier sub-layer 612 and the upper surface of the channel layer 226 that define the respective openings 622a, 622b. The conformality of the second barrier sub-layer 614 in the openings 622a, 622b forms gate recesses 422a, 422b, respectively. Each of the barrier sub-layers 612, 614 may be a material described above for the barrier layer 228. As described previously, gate layers 432a, 432b are at least partially in the gate recesses 422a, 422b, respectively, and may also partially over and on an upper surface of the barrier layer 228.

The barrier layer (including the barrier sub-layers 612, 614) in the first semiconductor device 402 has a thickness 460a (e.g., in a direction perpendicular to the upper surface of the barrier layer 228) at the gate recess 422a (e.g., from a bottom surface of the gate recess 422a to a bottom surface of the barrier layer). The barrier layer (including the barrier sub-layers 612, 614) in the second semiconductor device 404 has a thickness 460b at the gate recess 422b. The barrier layer in the third semiconductor device 206 has a thickness 460c. The barrier layer in the fourth semiconductor device 208 has a thickness 460d. The thicknesses 460a, 460b, 460c, 460d may be as described above with respect to FIG. 4 and result in the magnitudes of the threshold voltages of the semiconductor device 402, 404, 206, 208 differing as described with respect to FIG. 4.

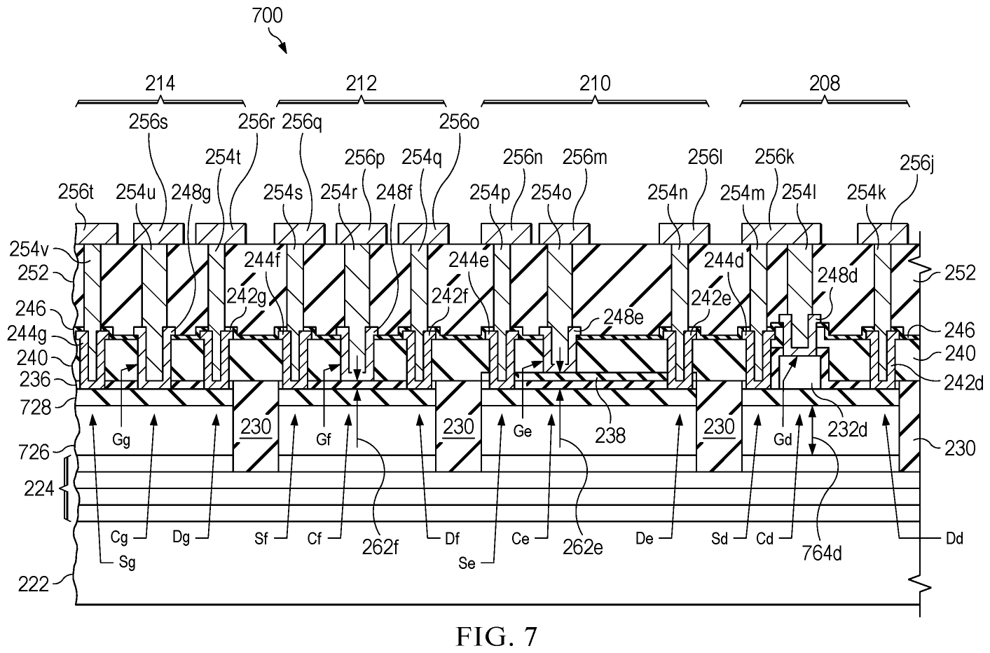

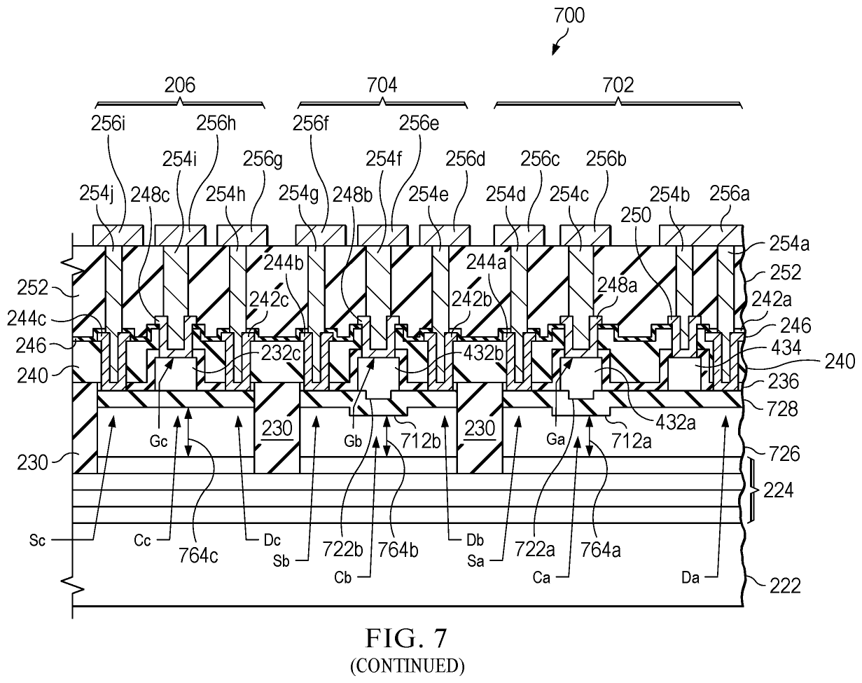

FIG. 7 illustrates a cross-sectional view of an IC 700 according to some examples. The IC 700, in this example, includes a first semiconductor device 702, a second semiconductor device 704, a third semiconductor device 206, a fourth semiconductor device 208, a fifth semiconductor device 210, a sixth semiconductor device 212, and a seventh semiconductor device 214. In the illustrated example, the first semiconductor device 702 and second semiconductor device 204 are each an Emode HEMT. More particularly, in some examples, the first semiconductor device 702 may be an Emode HEMT that is rated for a high voltage application and may be a power HEMT. The second semiconductor device 704 may be an Emode HEMT that is rated for a low voltage application and may be a power HEMT. The semiconductor devices 206, 208, 210, 212, 214 are as described above with respect to FIG. 2. Other semiconductor devices may be included in addition to the illustrated devices or instead of the illustrated devices. Some examples contemplate that some subset of the illustrated devices may be included in an IC. The illustrated devices are shown for ease to describe various aspects.

In some examples, respective magnitudes of threshold voltages of the first semiconductor device 702 and second semiconductor device 704 are greater than each of the magnitudes of the respective threshold voltages of the third semiconductor device 206 and fourth semiconductor device 208. As described subsequently, the differing threshold voltages may be achieved by different thicknesses of channel layers of the semiconductor devices.

A channel layer 726 is over and on the uppermost transition layer 224. Recesses 712a, 712b are in the channel layer 726. A barrier layer 728 is conformally over and on the channel layer 726. The barrier layer 728 is conformally on surfaces of sidewall and bottom surfaces of the channel layer 726 that define the respective recesses 712a, 712b. The conformality of the barrier layer 728 in the recesses 712a, 712b forms gate recesses 722a, 722b, respectively. The channel layer 726 may be a material described above for the channel layer 226, and the barrier layer 728 may be a material described above for the barrier layer 228. Like described previously, gate layers 432a, 432b are at least partially in the gate recesses 722a, 722b, respectively, and may also be partially over and on an upper surface of the barrier layer 728.

The first semiconductor device 702 includes a first source terminal Sa, a first channel region Ca, a first drain terminal Da, and a first gate terminal Ga. The first gate terminal Ga is or includes the gate layer 432a. The first channel region Ca is in the channel layer 726 underlying the first gate terminal Ga and underlying the recess 712a. The first channel region Ca is laterally between the first drain terminal Da and the first source terminal Sa, which are also in the channel layer 726. The metal contacts 242a, 244a, 248a are electrically coupled similarly as described above with respect to FIG. 2. Further, the injection layer 434 is laterally between the gate layer 432a and the drain metal contact 242a. The injection layer 434 is electrically coupled with the drain metal contact 242a similarly as described above with respect to FIG. 2. The injection layer 434 electrically coupled with the drain metal contact 242a forms a hybrid drain.

The second semiconductor device 704 includes a second source terminal Sb, a second channel region Cb, a second drain terminal Db, and a second gate terminal Gb. The second gate terminal Gb is or includes the gate layer 432b. The second channel region Cb is in the channel layer 726 underlying the second gate terminal Gb and underlying the recess 712b. The second channel region Cb is laterally between the second drain terminal Db and the second source terminal Sb, which are also in the channel layer 726. The metal contacts 242b, 244b, 248b are electrically coupled similarly as described above with respect to FIG. 2.

The channel layer 726 in the first semiconductor device 702 has a thickness 764a at the recess 712a (e.g., from a bottom surface of the recess 712a to a bottom surface of the channel layer 726). The channel layer 726 in the second semiconductor device 704 has a thickness 764b at the recess 712b. The thickness 764b may be equal to the thickness 764a. The channel layer 726 in the third semiconductor device 206 has a thickness 764c. The channel layer 726 in the fourth semiconductor device 208 has a thickness 764d. The thickness 764d may be equal to the thickness 764c. The thickness 764a and thickness 764b are each less than each of the thickness 764c and thickness 764d.

The differences in thicknesses result in the magnitude of the threshold voltage of the first semiconductor device 702 being greater than each of the respective magnitudes of the threshold voltages of the third semiconductor device 206 and fourth semiconductor device 208. The differences in thicknesses result in the magnitude of the threshold voltage of the second semiconductor device 704 being greater than each of the respective magnitudes of the threshold voltages of the third semiconductor device 206 and fourth semiconductor device 208. The threshold voltages of the first semiconductor device 702 and the second semiconductor device 704 may be equal, and the threshold voltages of the third semiconductor device 206 and the fourth semiconductor device 208 may be equal. The threshold voltages of the semiconductor devices 202-208 may be positive voltages.

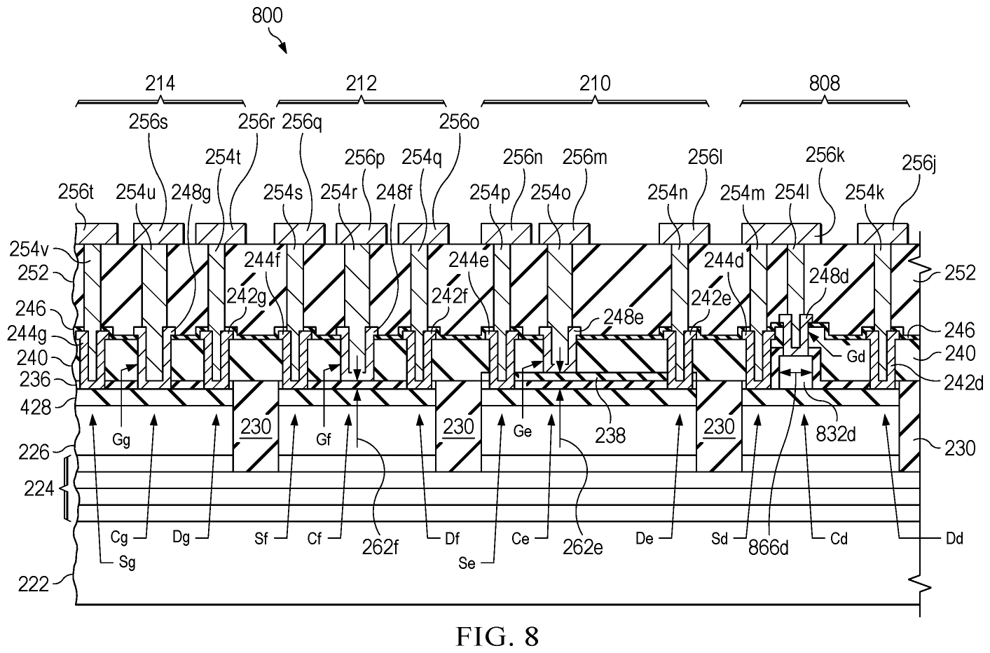

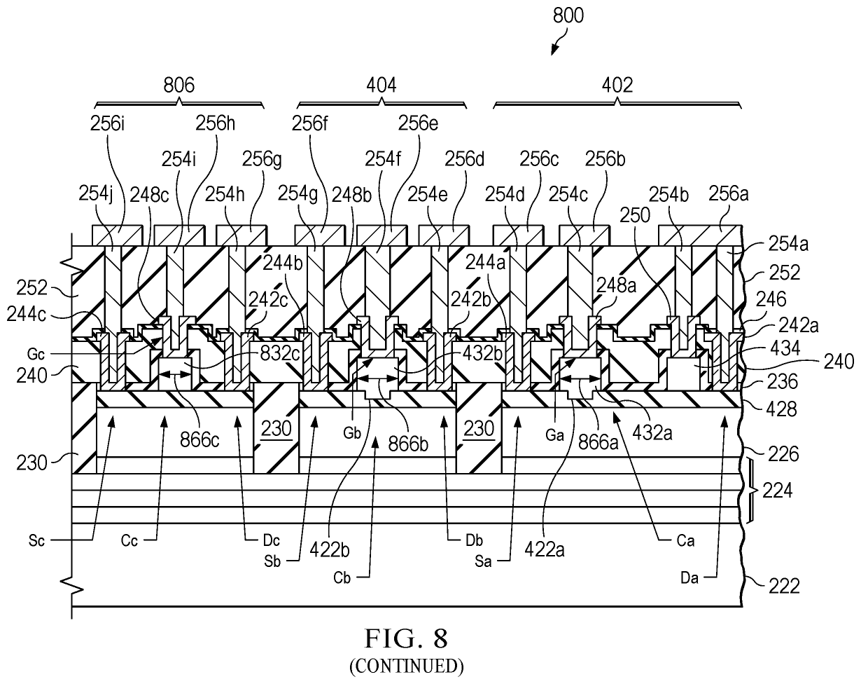

FIG. 8 illustrates a cross-sectional view of an IC 800 according to some examples. The IC 800, in this example, includes a first semiconductor device 402, a second semiconductor device 404, a third semiconductor device 806, a fourth semiconductor device 808, a fifth semiconductor device 210, a sixth semiconductor device 212, and a seventh semiconductor device 214. The semiconductor devices 402, 404, 210, 212, 214 are as described above with respect to FIGS. 2 and 4. In the illustrated example, the third semiconductor device 806 is an Emode HEMT. The fourth semiconductor device 808 is a diode-connected Emode HEMT. More particularly, in some examples, the third semiconductor device 806 may be an Emode HEMT that is rated for a low voltage application and may be an analog HEMT. The fourth semiconductor device 808 may be an Emode HEMT connected in a diode-connected configuration. Other semiconductor devices may be included in addition to the illustrated devices or instead of the illustrated devices. Some examples contemplate that some subset of the illustrated devices may be included in an IC. The illustrated devices are shown for ease to describe various aspects.

In some examples, respective magnitudes of threshold voltages of the first semiconductor device 402 and second semiconductor device 404 are greater than each of the magnitudes of the respective threshold voltages of the third semiconductor device 806 and fourth semiconductor device 808. As described subsequently, the differing threshold voltages may be achieved by different lengths of gate layers of the respective semiconductor devices.

Gate layers 832c, 832d are over and on an upper surface of the barrier layer 428. The gate layers 832c, 832d may be a material as described above with respect to the gate layers 232a, 232b.

The third semiconductor device 806 includes a third source terminal Sc, a third channel region Cc, a third drain terminal Dc, and a third gate terminal Gc. The third gate terminal Gc is or includes the gate layer 832c. The third channel region Cc is in the channel layer 226 underlying the third gate terminal Gc. The third channel region Cc is laterally between the third drain terminal Dc and the third source terminal Sc, which are also in the channel layer 226. The metal contacts 242c, 244c, 248c are electrically coupled similarly as described above with respect to FIG. 2.

The fourth semiconductor device 808 includes a fourth source terminal Sd, a fourth channel region Cd, a fourth drain terminal Dd, and a fourth gate terminal Gd. The fourth gate terminal Gd is or includes the gate layer 832d. The fourth channel region Cd is in the channel layer 226 underlying the fourth gate terminal Gd. The fourth channel region Cd is laterally between the fourth drain terminal Dd and the fourth source terminal Sd, which are also in the channel layer 226. The metal contacts 242d, 244d, 248d are electrically coupled similarly as described above with respect to FIG. 2. The fourth gate terminal Gd is electrically coupled to the fourth source terminal Sd through the gate metal contact 248d, metal vias 2541, 254m, metal line 256k, and source metal contact 244d. Hence, the fourth semiconductor device 808 is electrically connected in a diode-connected configuration.

The gate layer 432a of the first semiconductor device 402 has a length 866a (e.g., in a direction parallel to a drain (Da)-to-source (Sa) direction). The gate layer 432b of the second semiconductor device 404 has a length 866b. The length 866b may be equal to the length 866a. The gate layer 832c of the third semiconductor device 806 has a length 866c. The gate layer 832d of the fourth semiconductor device 808 has a length 866d. The length 866d may be equal to the length 866c. The length 866a and length 866b are each greater than each of the length 866c and length 866d. The lengths 866a-866d may correspond to a respective channel length of the respective semiconductor device 402, 404, 806, 808.

The differences in lengths result in the magnitude of the threshold voltage of the first semiconductor device 402 being greater than each of the respective magnitudes of the threshold voltages of the third semiconductor device 806 and fourth semiconductor device 808. The differences in lengths results in the magnitude of the threshold voltage of the second semiconductor device 404 being greater than each of the respective magnitudes of the threshold voltages of the third semiconductor device 806 and fourth semiconductor device 808. The threshold voltages of the first semiconductor device 402 and the second semiconductor device 404 may be equal, and the threshold voltages of the third semiconductor device 806 and the fourth semiconductor device 808 may be equal. The threshold voltages of the semiconductor devices 402, 404, 806, 808 may be positive voltages.

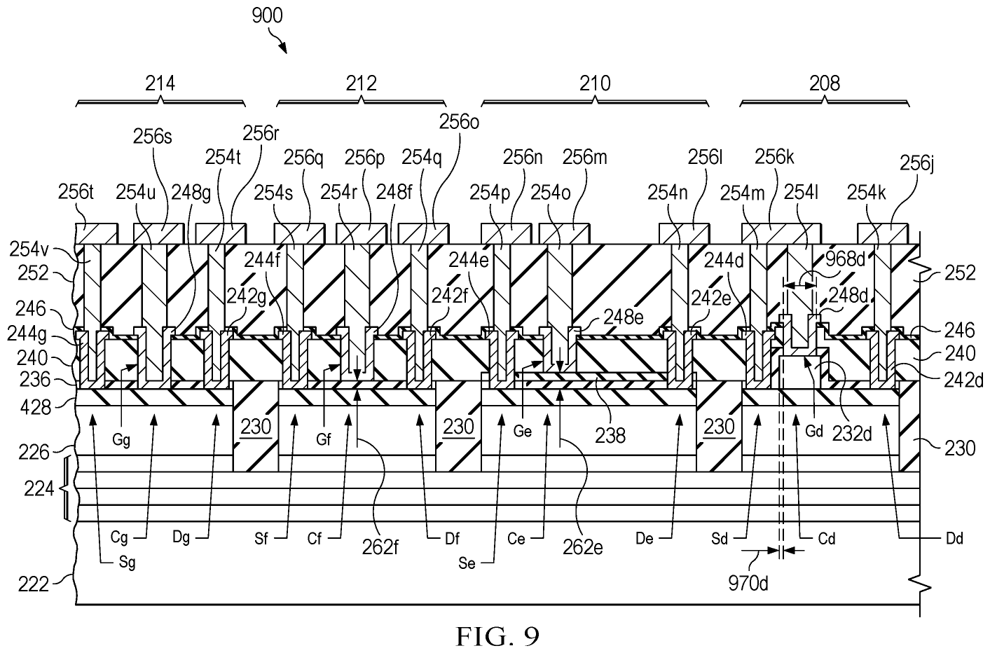

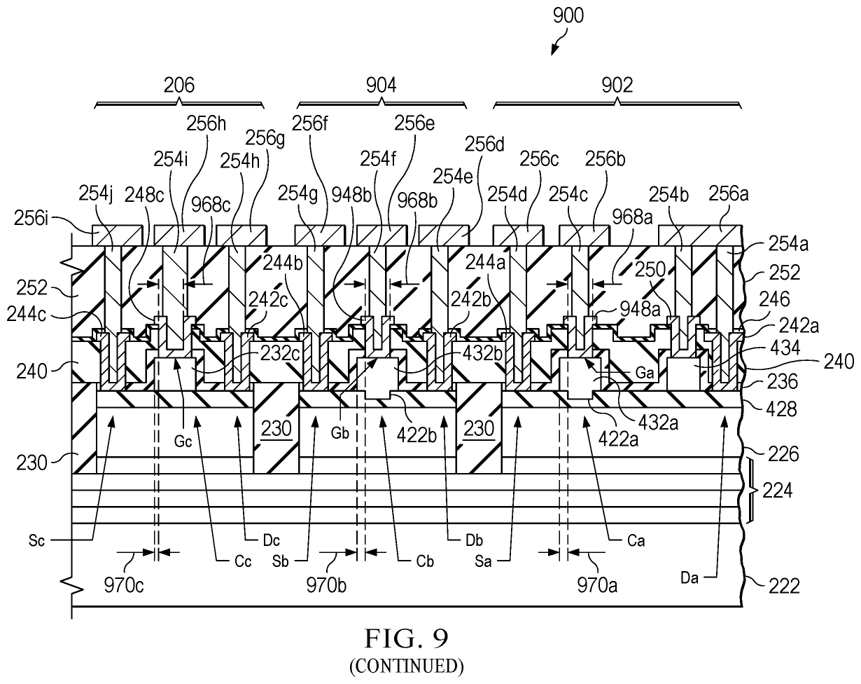

FIG. 9 illustrates a cross-sectional view of an IC 900 according to some examples. The IC 900, in this example, includes a first semiconductor device 902, a second semiconductor device 904, a third semiconductor device 206, a fourth semiconductor device 208, a fifth semiconductor device 210, a sixth semiconductor device 212, and a seventh semiconductor device 214. The semiconductor devices 206, 208, 210, 212, 214 are as described above with respect to FIG. 2. In the illustrated example, the first semiconductor device 902 and second semiconductor device 904 are each an Emode HEMT. More particularly, in some examples, the first semiconductor device 902 may be an Emode HEMT that is rated for a high voltage application. The second semiconductor device 904 may be an Emode HEMT that is rated for a low voltage application. Other semiconductor devices may be included in addition to the illustrated devices or instead of the illustrated devices. Some examples contemplate that some subset of the illustrated devices may be included in an IC. The illustrated devices are shown for ease to describe various aspects.

In some examples, respective magnitudes of threshold voltages of the first semiconductor device 902 and second semiconductor device 904 are greater than each of the magnitudes of the respective threshold voltages of the third semiconductor device 206 and fourth semiconductor device 208. As described subsequently, the differing threshold voltages may be achieved by different offset lengths of gate metal contacts relative to respective gate layers of the semiconductor devices that are contacted by the gate metal contacts.

Gate metal contacts 948a, 948b are through the first dielectric layer 236 and the fourth dielectric layer 246 and third dielectric layer 240. The gate metal contact 948a contacts the gate layer 432a. The gate metal contact 948b contacts the gate layer 432b. The gate metal contacts 948a, 948b may be like the gate metal contacts 248a, 248b described above with respect to FIG. 2.

The first semiconductor device 902 includes a first source terminal Sa, a first channel region Ca, a first drain terminal Da, and a first gate terminal Ga. The first gate terminal Ga is or includes the gate layer 432a. The first channel region Ca is in the channel layer 226 underlying the first gate terminal Ga and underlying the gate recess 422a, in which the gate layer 432a is at least partially disposed. The first channel region Ca is laterally between the first drain terminal Da and the first source terminal Sa, which are also in the channel layer 226. The metal contacts 242a, 244a are electrically coupled similarly as described above with respect to FIG. 2. The gate metal contact 948a is electrically coupled to the first gate terminal Ga (e.g., the gate layer 432a). Further, the injection layer 434 is laterally between the gate layer 432a and the drain metal contact 242a. The injection layer 434 is electrically coupled with the drain metal contact 242a similarly as described above with respect to FIG. 2. The injection layer 434 electrically coupled with the drain metal contact 242a forms a hybrid drain.

The second semiconductor device 904 includes a second source terminal Sb, a second channel region Cb, a second drain terminal Db, and a second gate terminal Gb. The second gate terminal Gb is or includes the gate layer 432b. The second channel region Cb is in the channel layer 226 underlying the second gate terminal Gb and underlying the gate recess 422b, in which the gate layer 432b is at least partially disposed. The second channel region Cb is laterally between the second drain terminal Db and the second source terminal Sb, which are also in the channel layer 226. The metal contacts 242b, 244b are electrically coupled similarly as described above with respect to FIG. 2. The gate metal contact 948b is electrically coupled to the second gate terminal Gb (e.g., the gate layer 432b).

The gate metal contact 948a has a length 968a (e.g., a direction parallel to a drain-to-source direction) where the gate metal contact 948a contacts the gate layer 432a of the first semiconductor device 902. The gate layer 432a has a length (not specifically identified in FIG. 9 and is like the length 866a in FIG. 8), and together, the length of the gate layer 432a and the length 968a result in a contact offset length 970a. The contact offset length 970a is a length from an outer sidewall of the gate metal contact 948a to a corresponding sidewall of the gate layer 432a. With ideal alignment of the gate layer 432a and the gate metal contact 948a, the contact offset length 970a may be half the difference between the length of the gate layer 432a and the length 968a. The gate metal contact 948b has a length 968b where the gate metal contact 948b contacts the gate layer 432b of the second semiconductor device 904, and together, the length of the gate layer 432b and the length 968b result in a contact offset length 970b. The length 968b may be equal to the length 968a. The contact offset length 970b may be equal to the contact offset length 970a.

The gate metal contact 248c has a length 968c where the gate metal contact 248c contacts the gate layer 232c of the third semiconductor device 206, and together, the length of the gate layer 232c and the length 968c result in a contact offset length 970c. The gate metal contact 248d has a length 968d where the gate metal contact 248d contacts the gate layer 232d of the fourth semiconductor device 208, and together, the length of the gate layer 232d and the length 968d result in a contact offset length 970d. The length 968d may be equal to the length 968c. The contact offset length 970d may be equal to the contact offset length 970c.

The contact offset length 970a and contact offset length 970b are each greater than each of the contact offset length 970c and contact offset length 970d. The length 968a and length 968b may each be less than each of the length 968c and length 968d (e.g., assuming the lengths of the gate layers 432a, 432b, 232c, 232d are equal).

The differences in contact offset lengths result in the magnitude of the threshold voltage of the first semiconductor device 902 being greater than each of the respective magnitudes of the threshold voltages of the third semiconductor device 206 and fourth semiconductor device 208, as explained above. The differences in contact offset lengths result in the magnitude of the threshold voltage of the second semiconductor device 904 being greater than each of the respective magnitudes of the threshold voltages of the third semiconductor device 206 and fourth semiconductor device 208. The threshold voltages of the first semiconductor device 902 and the second semiconductor device 904 may be equal, and the threshold voltages of the third semiconductor device 206 and the fourth semiconductor device 208 may be equal. The threshold voltages of the semiconductor devices 902, 904, 206, 208 may be positive voltages.

The barrier layer 428 with gate recesses 422a, 422b as described with respect to FIG. 4 are illustrated in the examples of FIGS. 8 and 9. In some examples, the barrier layer 228 (e.g., without gate recess) may be implemented as a modification to FIG. 8 or 9. In still other examples, the barrier layer (with barrier sub-layers 612, 614) with gate recesses 422a, 422b may be implemented as a modification to FIG. 8 or 9. Further, in some examples, the barrier layer 728 and channel layer 726 may be implemented as a modification to FIG. 8 or 9.

In some examples, respective magnitudes of threshold voltages of the semiconductor devices are greater than each of the magnitudes of the respective threshold voltages of other semiconductor devices resulting, at least in part, from different dopant concentrations in the gate layers of the semiconductor devices. Different doping concentrations may be or include different uniform concentrations in the gate layers or different gradient concentrations in the gate layers. For example, the gate layers 232a, 232b, 432a, 432b may have a first dopant concentration, and the gate layers 232c, 232d, 832c, 832d (and anode layer 332c) may have a second dopant concentration different from the first dopant concentration. As an example, the first dopant concentration of the gate layers 232a, 232b, 432a, 432b may be greater than second dopant concentration of the gate layers 232c, 232d, 832c, 832d.

The difference in dopant concentration, which impacts how much charge can be provided by the gate layer/anode layer to replenish the depleted charge in the channel for a given gate/anode voltage, results in the magnitude of the threshold voltage of the first semiconductor device 202, 402, 502, 702, 902 being greater than each of the respective magnitudes of the threshold voltages of the third semiconductor device 206, 306, 806 and fourth semiconductor device 208, 808. The difference in dopant concentration results in the magnitude of the threshold voltage of the second semiconductor device 204, 404, 704, 904 being greater than each of the respective magnitudes of the threshold voltages of the third semiconductor device 206, 306, 806 and fourth semiconductor device 208, 808. The threshold voltages of the first semiconductor device 202, 402, 502, 702, 902 and the second semiconductor device 204, 404, 704, 904 may be equal, and the threshold voltages of the third semiconductor device 206, 306, 806 and the fourth semiconductor device 208, 808 may be equal. The threshold voltages of the semiconductor devices may be positive voltages.

In some examples, respective magnitudes of threshold voltages of the semiconductor devices are greater than each of the magnitudes of the respective threshold voltages of other semiconductor devices resulting, at least in part, from different metal-barrier work functions in the semiconductor devices due to different metals of the gate metal contacts. For example, the gate metal contacts 248a, 248b, 948a, 948b may be or include a metal, and the gate metal contacts 248c, 248d and anode metal contact 348c different from the metal of the gate metal contacts 248a, 248b, 948a, 948b.

The difference in the metals of the gate metal contacts results in different metal-barrier work functions, which results in the magnitude of the threshold voltage of the first semiconductor device 202, 402, 502, 702, 902 being different from each of the respective magnitudes of the threshold voltages of the third semiconductor device 206, 306, 806 and fourth semiconductor device 208, 808. The difference in metals results in the magnitude of the threshold voltage of the second semiconductor device 204, 404, 704, 904 being different from each of the respective magnitudes of the threshold voltages of the third semiconductor device 206, 306, 806 and fourth semiconductor device 208, 808. The threshold voltages of the first semiconductor device 202, 402, 502, 702, 902 and the second semiconductor device 204, 404, 704, 904 may be equal, and the threshold voltages of the third semiconductor device 206, 306, 806 and the fourth semiconductor device 208, 808 may be equal. The threshold voltages of the semiconductor devices may be positive voltages.

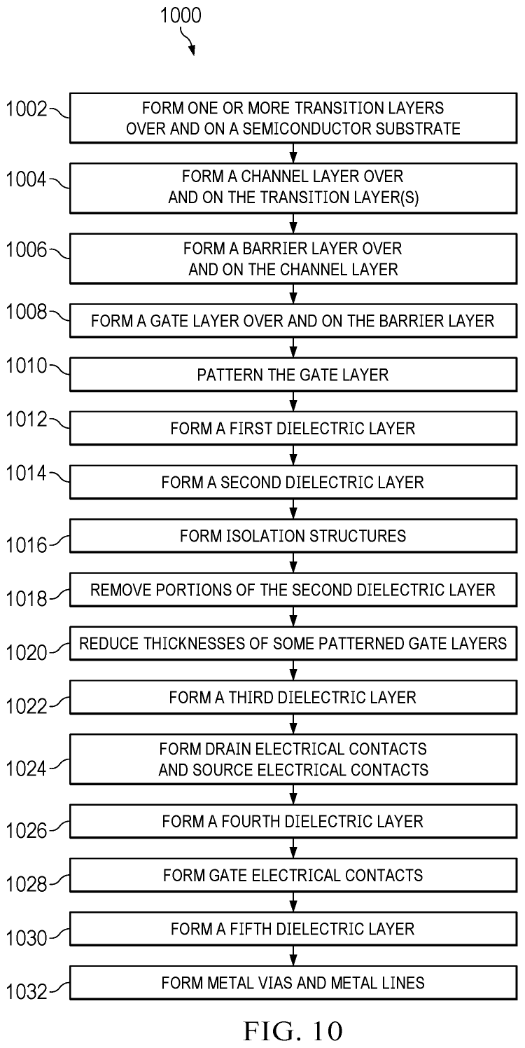

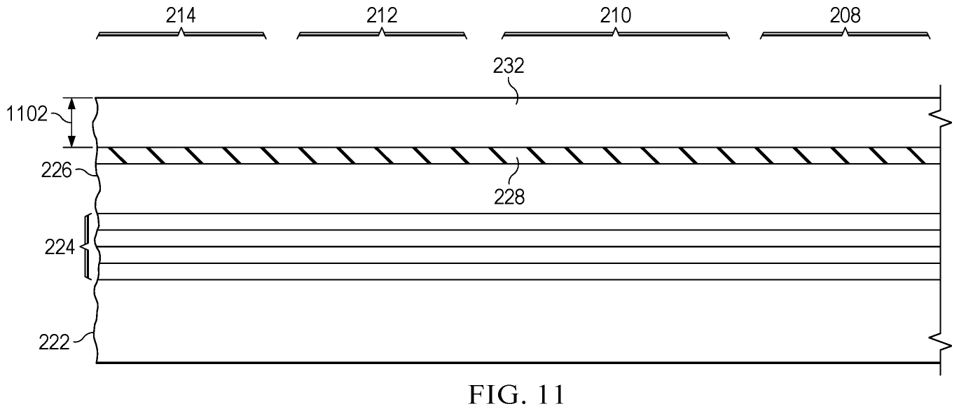

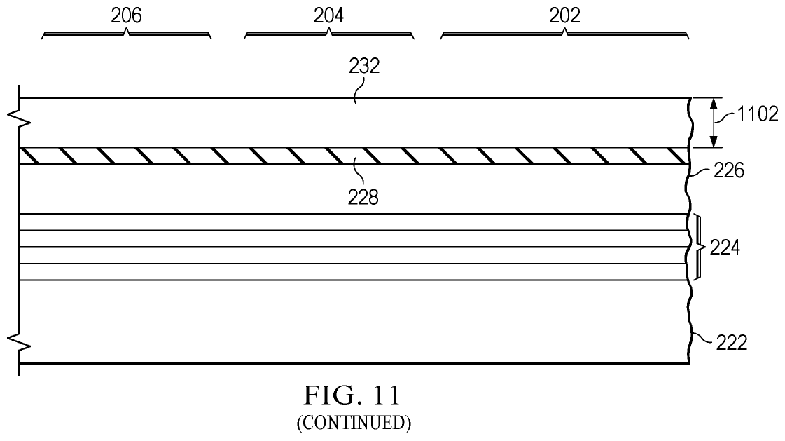

FIG. 10 is a flowchart of a method 1000 of manufacturing the IC 200 of FIG. 2 according to some examples. The method 1000 of FIG. 10 is illustrated by and described in the context of FIGS. 11 through 21, which illustrate cross-sectional views of the IC 200 at various stages of manufacturing. Although the method 1000 of FIG. 10 is illustrated in the context of FIGS. 11 through 21 to manufacture the IC 200 of FIG. 2, the method 1000 of FIG. 10 may also be implemented to manufacture examples consistent with aspects of any IC described herein.

Referring to block 1002 of FIG. 10 and to FIG. 11, one or more transition layers 224 are formed over and on a semiconductor substrate 222. At block 1004, a channel layer 226 is formed over and on the transition layer(s) 224. At block 1006, a barrier layer 228 is formed over and on the channel layer 226. In some examples, the transition layer(s) 224, channel layer 226, and barrier layer 228 may be formed by using any appropriate deposition process, which may further be an epitaxial growth process. For example, the transition layer(s) 224, channel layer 226, and barrier layer 228 may each be epitaxially grown using metal-organic chemical vapor deposition (MOCVD), molecular beam epitaxy (MBE), low pressure chemical vapor deposition (LPCVD), or another epitaxy process. The materials of the semiconductor substrate 222, transition layer(s) 224, channel layer 226, and barrier layer 228 may be as described previously.

At block 1008, a gate layer 232 is formed over and on the barrier layer 228. In some examples, the gate layer 232 may be epitaxially grown, such as by MOCVD, MBE, LPCVD, plasma enhanced chemical vapor deposition (PECVD), atomic layer epitaxy, or another epitaxy process. The gate layer 232 may be doped in situ during deposition (e.g., epitaxial growth) or by implantation (e.g., ion implantation) subsequent to deposition. As formed, the gate layer 232 has a thickness 1102. The materials of the gate layer 232, any dopant, and any concentration of a dopant may be as described previously.

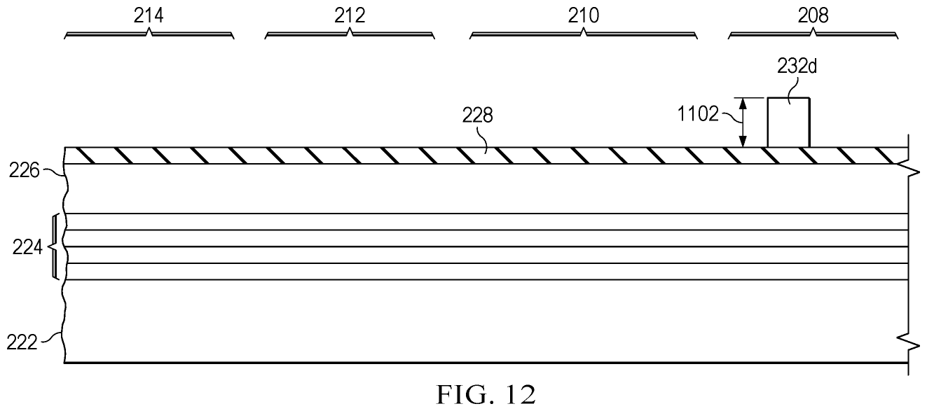

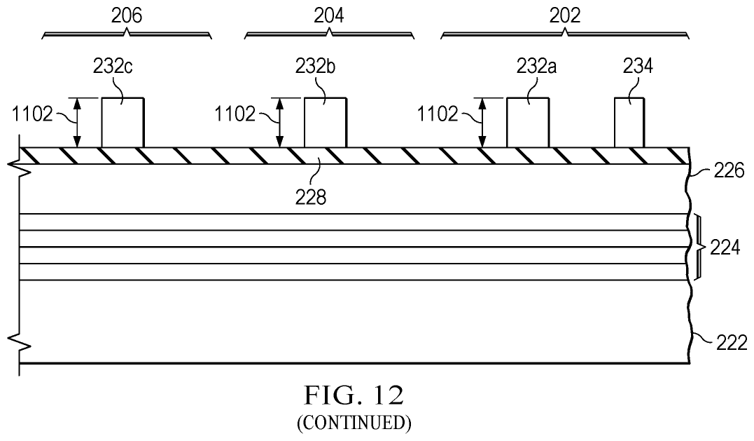

Referring to block 1010 of FIG. 10 and to FIG. 12, the gate layer 232 is patterned into the gate layers 232a, 232b, 232c, 232d and the injection layer 234. Once patterned, each of the gate layers 232a-232d and injection layer 234 have approximately the thickness 1102 of the gate layer 232 (e.g., possibly with minor loss due to the patterning process). The gate layer 232 may be patterned using appropriate photolithography and etch processes. For example, to pattern the gate layer 232, a photoresist is deposited (e.g., by spin-on) over and/or on the semiconductor substrate 222 (e.g., over and/or on the gate layer 232) and patterned using photolithography. The photoresist is patterned to remain in an area corresponding to an area where the gate layers 232a-232d and the injection layer 234 are to be formed. With the patterned photoresist, an etch process, such as an anisotropic etch like a reactive ion etch (RIE) or the like, is performed, using the patterned photoresist as a mask, to pattern the gate layer 232. After the etch process, the photoresist is removed, such as by ashing.

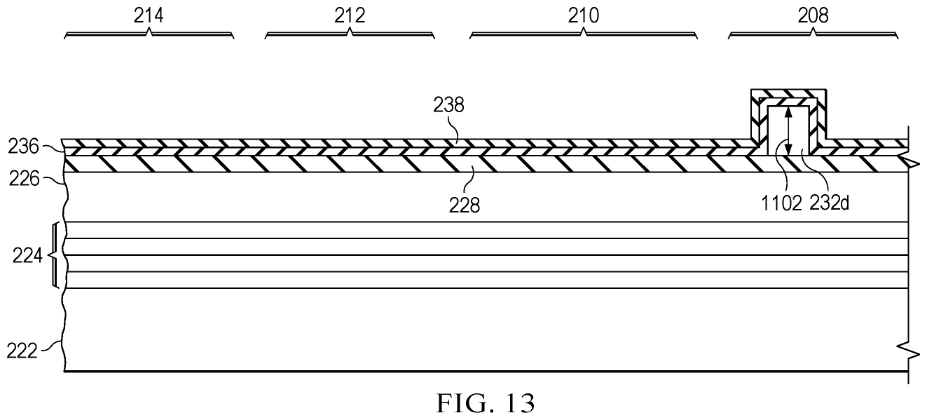

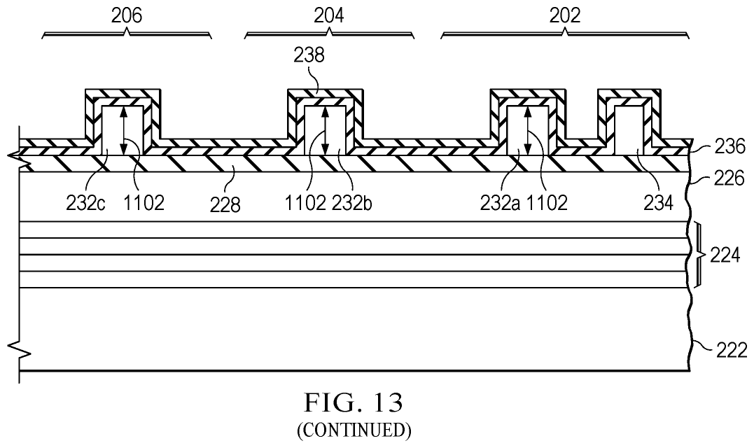

Referring to block 1012 of FIG. 10 and to FIG. 13, the first dielectric layer 236 is formed conformally over and on the barrier layer 228, gate layers 232a-232d, and injection layer 234. The first dielectric layer 236 may be deposited using any appropriate deposition process, such as LPCVD, PECVD, or the like. The material(s) of the first dielectric layer 236 may be as described above. At block 1014, the second dielectric layer 238 is formed conformally over and on the first dielectric layer 236. The second dielectric layer 238 may be deposited using any appropriate deposition process, such as LPCVD, PECVD, or the like. The material(s) of the second dielectric layer 238 may be as described above.

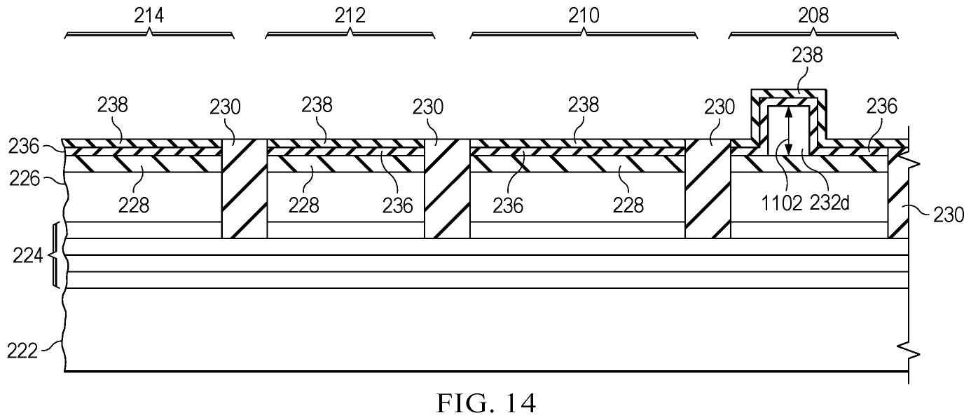

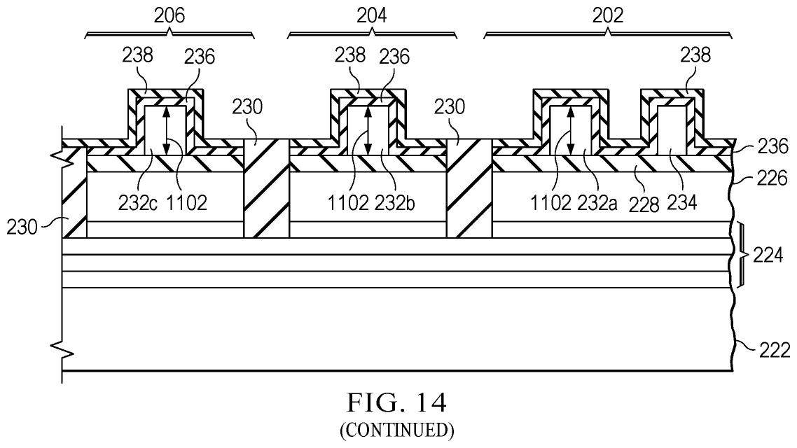

Referring to block 1016 of FIG. 10 and to FIG. 14, the isolation structures 230 are formed. The isolation structures 230, which are trench isolation structures in this example, may be formed by forming recesses through the second dielectric layer 238, first dielectric layer 236, barrier layer 228, and channel layer 226 into the transition layer(s) 224. The recesses may be formed using appropriate photolithography and etch processes like described above. An isolation material may be deposited in the recesses, such as by chemical vapor deposition (CVD), such as high aspect ratio CVD (HAR-CVD), flowable CVD (FCVD), or the like. Any excess isolation material over the second dielectric layer 238 may be removed by an etch selective to the isolation material, which may be a wet, isotropic etch. Other isolation structures may be formed by other processing in other examples.

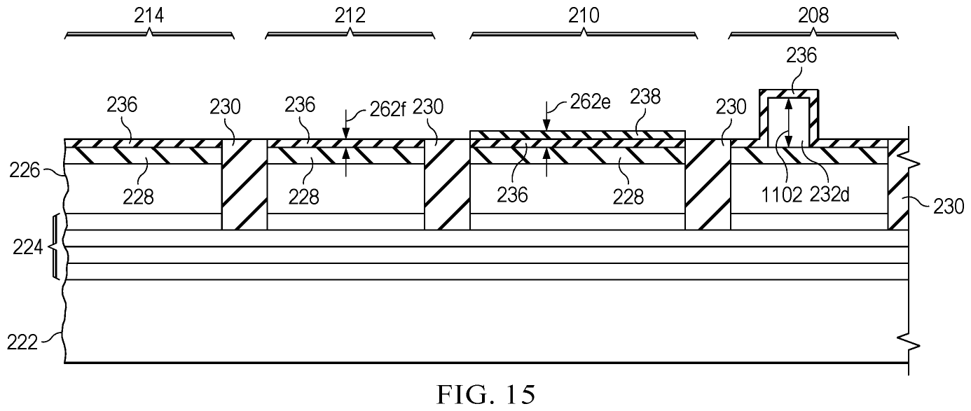

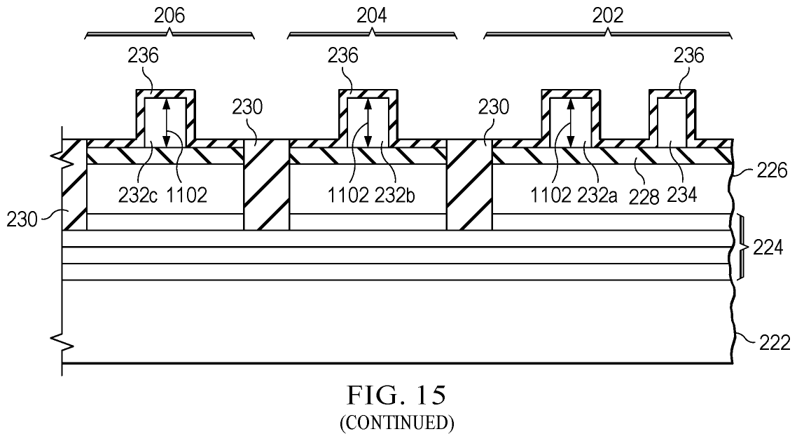

Referring to block 1018 of FIG. 10 and to FIG. 15, portions of the second dielectric layer 238 are removed from regions in which the sixth semiconductor device 212 and seventh semiconductor device 214 are to be formed. Additionally, respective portions of the second dielectric layer 238 may be removed from regions in which the semiconductor devices 202-208 are to be formed, as illustrated. By removing the portion of the second dielectric layer 238 from the region in which the sixth semiconductor device 212 is to be formed and masking the portion of the second dielectric layer 238 in the region in which the fifth semiconductor device 210 is to be formed (e.g., such that the portion remains), the thickness 262e of the gate insulator or gate dielectric layer (e.g., the first dielectric layer 236 and second dielectric layer 238) of the fifth semiconductor device 210 may be achieved, and the thickness 262f of the gate insulator (e.g., the first dielectric layer) of the sixth semiconductor device 212 may be achieved. The portion(s) of the second dielectric layer 238 may be removed using appropriate photolithography processes, such as described above, to mask the region in which the fifth semiconductor device 210 is to be formed and selectively etching exposed portions of the second dielectric layer 238. The etch process may be a wet, isotropic etch.

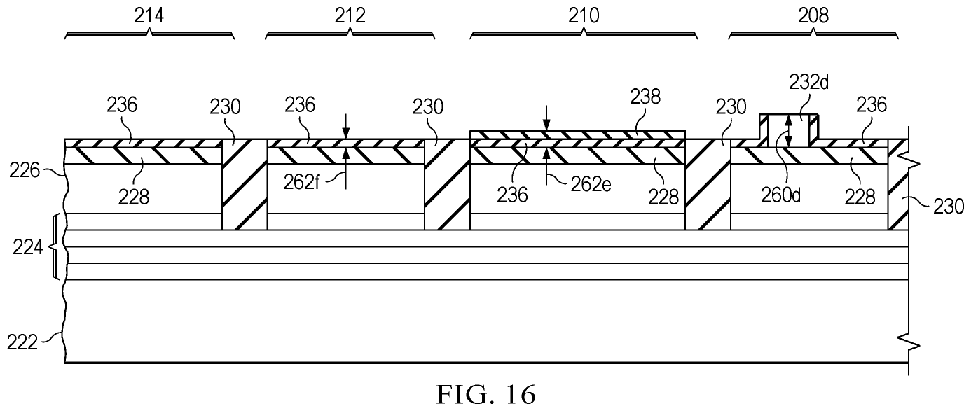

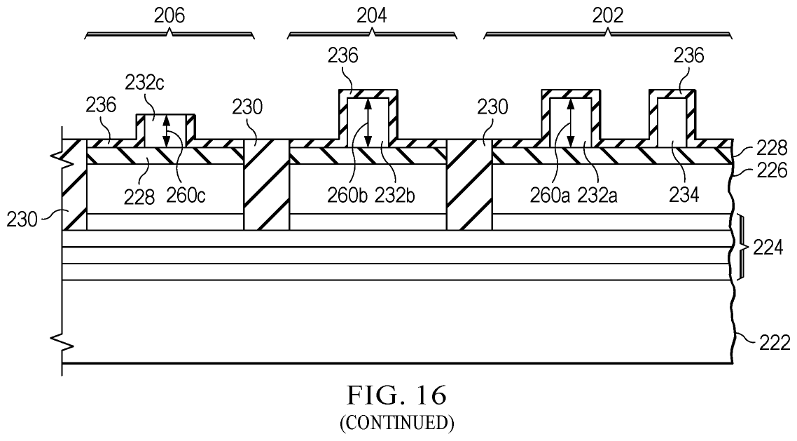

Referring to block 1020 of FIG. 10 and to FIG. 16, respective thicknesses of the gate layers 232c, 232d are reduced. The thicknesses of the gate layers 232c, 232d are reduced from thickness 1102 to thicknesses 260c, 260d. The thicknesses of the gate layers 232a, 232b, in some examples, are not reduced from thickness 1102, which are shown in FIG. 16 to be thicknesses 260a, 260b. The thicknesses of the gate layers 232c, 232d may be reduced using appropriate photolithography processes, such as described above, to expose areas corresponding to the gate layers 232c, 232d while masking other regions. Using the photoresist as a mask, the first dielectric layer 236 over the gate layers 232c, 232d and the gate layers 232c, 232d are etched, such as by an anisotropic etch. Etching the gate layers 232c, 232d may reduce the respective thicknesses.

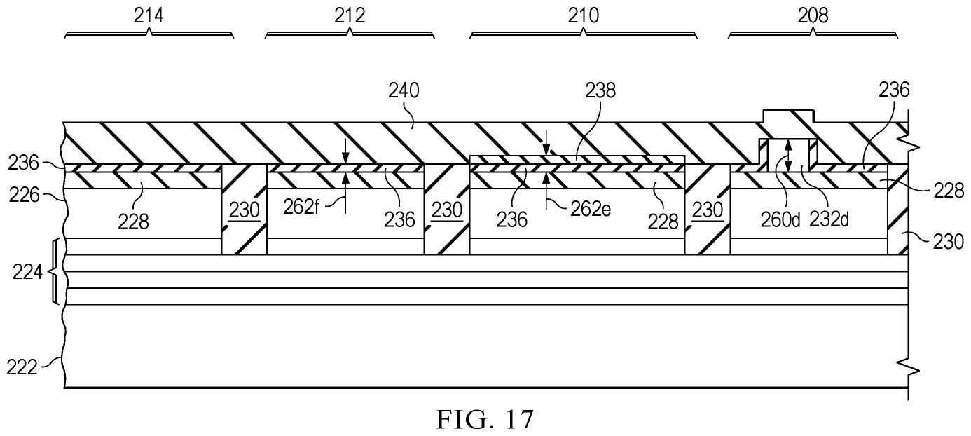

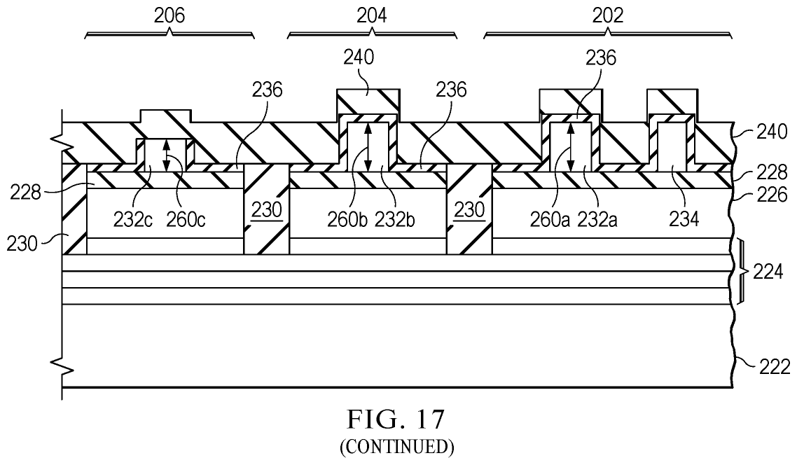

Referring to block 1022 of FIG. 10 and to FIG. 17, the third dielectric layer 240 is formed over the semiconductor substrate 222. The third dielectric layer 240 is over and on the first dielectric layer 236 and the second dielectric layer 238. The third dielectric layer 240 is over the gate layers 232a-232d and the injection layer 234. The third dielectric layer 240 may be deposited using any appropriate deposition process, such as CVD, LPCVD, PECVD, or the like. The material(s) of the third dielectric layer 240 may be as described above.

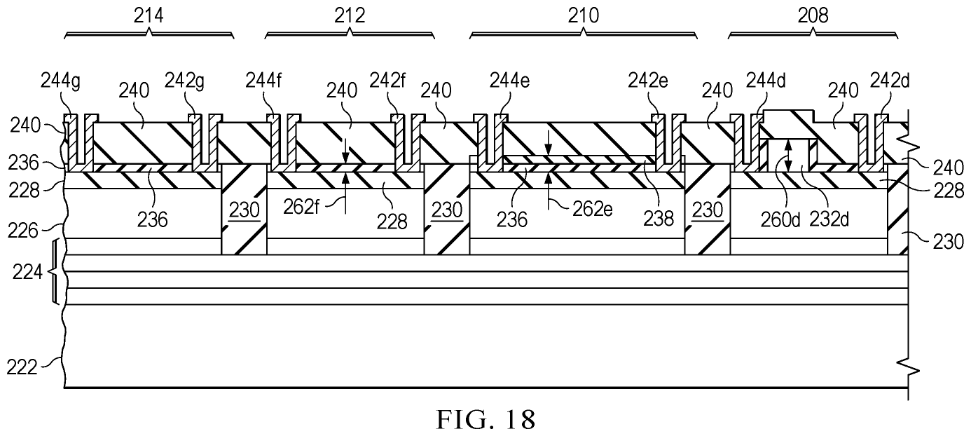

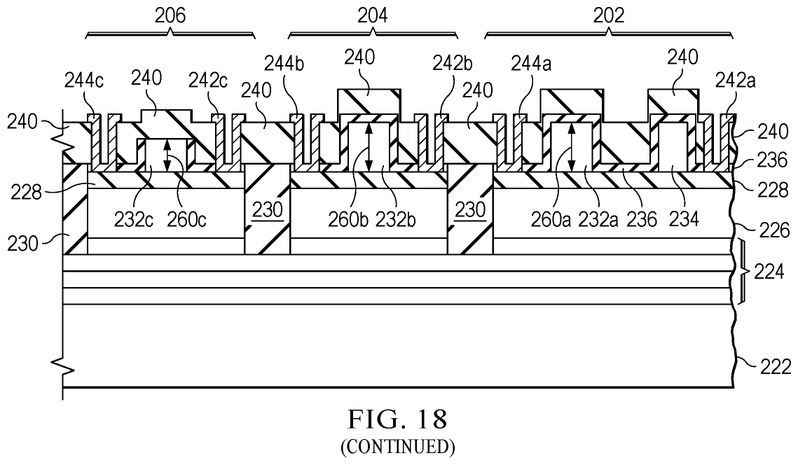

Referring to block 1024 and to FIG. 18, the drain metal contacts 242a-242g and source metal contacts 244a-244g are formed through the third dielectric layer 240, the first dielectric layer 236, and where appropriate, the second dielectric layer 238. Respective source/drain contact openings may be formed through the third dielectric layer 240, the first dielectric layer 236, and where appropriate, the second dielectric layer 238 to the barrier layer 228, into the barrier layer 228, or through the barrier layer 228 to the channel layer 226. The source/drain contact openings may be formed using appropriate photolithography and etch processes. One or more metals are deposited into the source/drain contact openings and over and on an upper surface of the third dielectric layer 240. The one or more metals deposited into the source/drain contact openings form the drain metal contacts 242a-242g and source metal contacts 244a-244g. The metal(s) may be deposited using an appropriate deposition process(es), such as CVD, physical vapor deposition (PVD), or the like. In some examples, the metal(s) may be respective conformal layer(s) in the source/drain contact openings that do not fill the source/drain contact openings, and in some examples, the metal(s) may fill the source/drain contact openings. The metal(s) over the upper surface of the third dielectric layer 240 are patterned into the portions of the drain metal contacts 242a-242g and source metal contacts 244a-244g on the upper surface of the third dielectric layer 240. The metal(s) may be patterned using appropriate photolithography and etch processes.

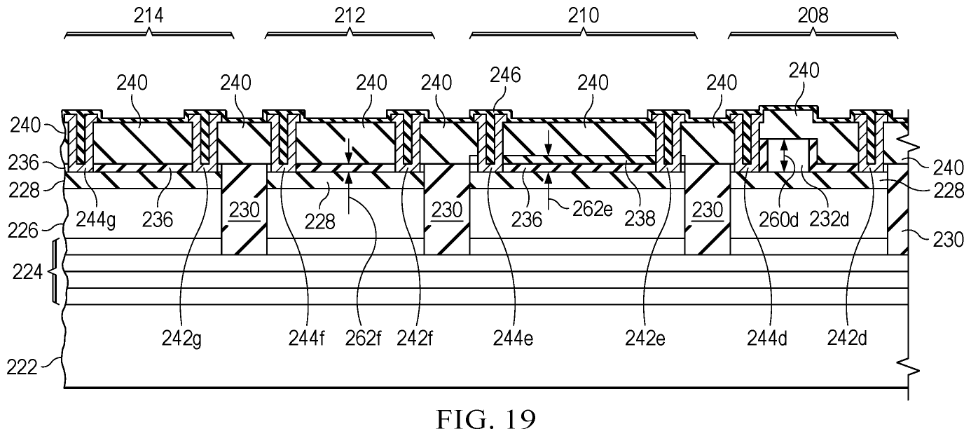

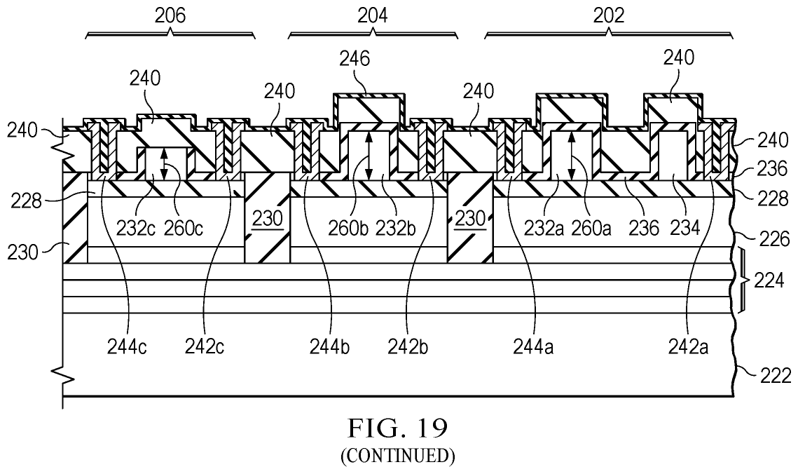

Referring to block 1026 of FIG. 10 and to FIG. 19, the fourth dielectric layer 246 is formed over the semiconductor substrate 222. The fourth dielectric layer 246 is conformally over and on the third dielectric layer 240 and the drain metal contacts 242a-242g and source metal contacts 244a-244g. The fourth dielectric layer 246 may be deposited using any appropriate deposition process, such as CVD, LPCVD, PECVD, or the like. The material(s) of the fourth dielectric layer 246 may be as described above.

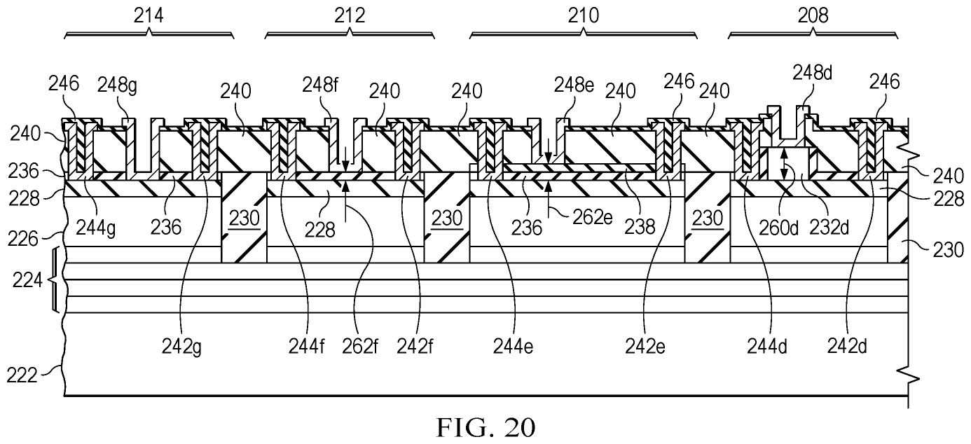

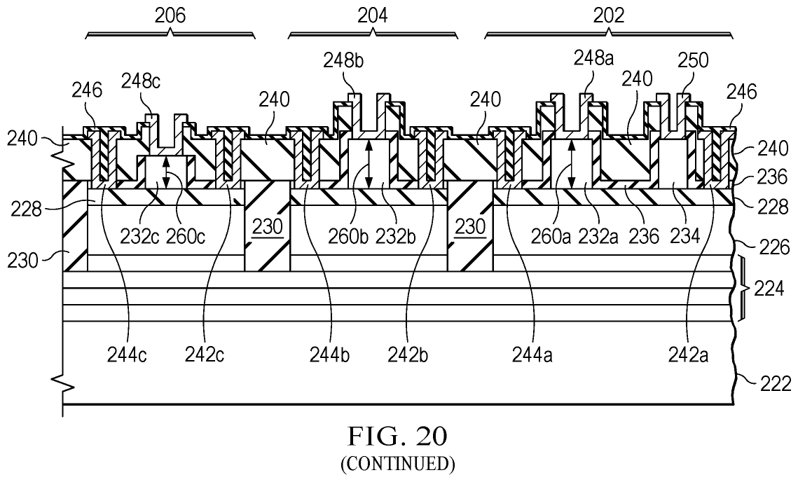

Referring to block 1028 and to FIG. 20, the gate metal contacts 248a-248g and the injection metal contact 250 are formed through the fourth dielectric layer 246 and the third dielectric layer 240. Respective gate/injection contact openings may be formed through the fourth dielectric layer 246 and the third dielectric layer 240 to, where appropriate, the gate layers 232a-232d, the injection layer 234, the second dielectric layer 238, the first dielectric layer 236, and the barrier layer 228. The gate/injection contact openings may be formed using appropriate photolithography and etch processes. Multiple photolithography and etch processes may be implemented to form the gate/injection contact openings. For example, photolithography and etch processes may be used to form gate/injection contact openings through the fourth dielectric layer 246, the third dielectric layer 240, and (in some areas) the first dielectric layer 236, such as to form gate/injection contact openings to the gate layers 232a-232d and injection layer 234 (for the semiconductor devices 202-208) and a gate/injection contact opening to the barrier layer 228 (for the seventh semiconductor device 214). Other photolithography and etch processes may be used to form gate/injection contact openings through the fourth dielectric layer 246 and the third dielectric layer 240 to the second dielectric layer 238 and the first dielectric layer 236, such as to form a gate/injection contact opening to the second dielectric layer 238 (for the fifth semiconductor device 210) and a gate/injection contact opening to the first dielectric layer 236 (for the sixth semiconductor device 212). In some examples, gate/injection contact openings for the gate metal contacts 248a-248g may be formed using one photolithography process and one etch process, such as by including one or more etch stop layers to cause the etch process to stop at appropriate depths in the structure.

One or more metals are deposited into the gate/injection contact openings and over and on an upper surface of the fourth dielectric layer 246. The one or more metals deposited into the gate/injection contact openings form the gate metal contacts 248a-248g and injection metal contact 250. The metal(s) may be deposited using an appropriate deposition process(es), such as CVD, PVD, or the like. In some examples, the metal(s) may be respective conformal layer(s) in the gate/injection contact openings that do not fill the gate/injection contact openings, and in some examples, the metal(s) may fill the gate/injection contact openings. The metal(s) over the upper surface of the fourth dielectric layer 246 are patterned into the portions of the gate metal contacts 248a-248g and injection metal contact 250 on the upper surface of the fourth dielectric layer 246. The metal(s) may be patterned using appropriate photolithography and etch processes.

In some examples, different metals may be implemented for different gate metal contacts 248a-248g and injection metal contact 250. The different metal for the gate metal contacts 248a-248g may be implemented to achieve different threshold voltages. For some semiconductor devices, a Schottky junction may be desirable between a gate metal contact and a corresponding gate layer, while for other semiconductor devices, an ohmic junction may be desirable between a gate metal contact and a corresponding gate layer. The junctions may be achieved based on the material of the gate layer and the material of the gate metal contact. For example, to implement the semiconductor device 306 that is a diode, an ohmic junction may be desirable, whereas to implement, e.g., the first semiconductor device 202 that is an Emode HEMT, a Schottky junction may be desirable. Different depositions of respective different metals and different patterning of those metal may be implemented to achieve the different metals as gate metal contacts 248a-248g.

Although the injection metal contact 250 is illustrated as being formed by the processing to form the gate metal contacts 248a-248g, the injection metal contact 250 may be formed by the processing that forms the drain metal contacts 242a-242g and source metal contacts 244a-244g, as described above with respect to FIG. 18.

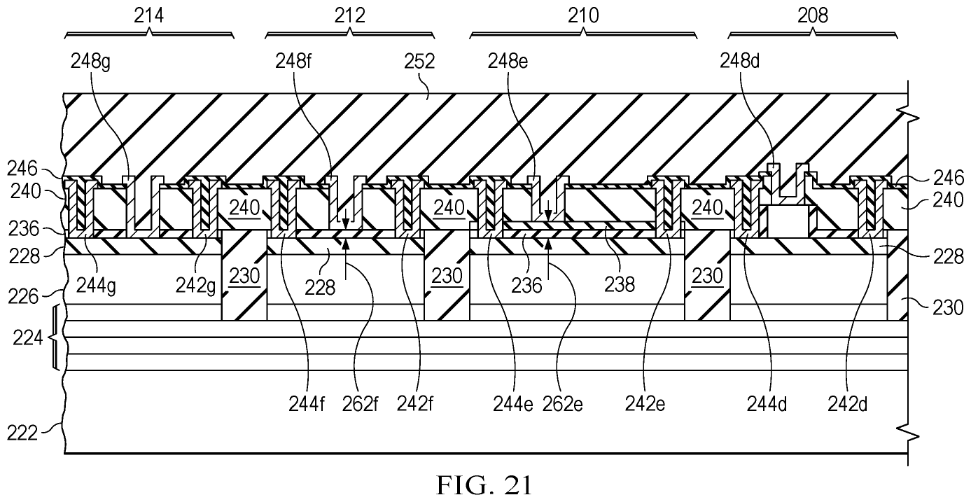

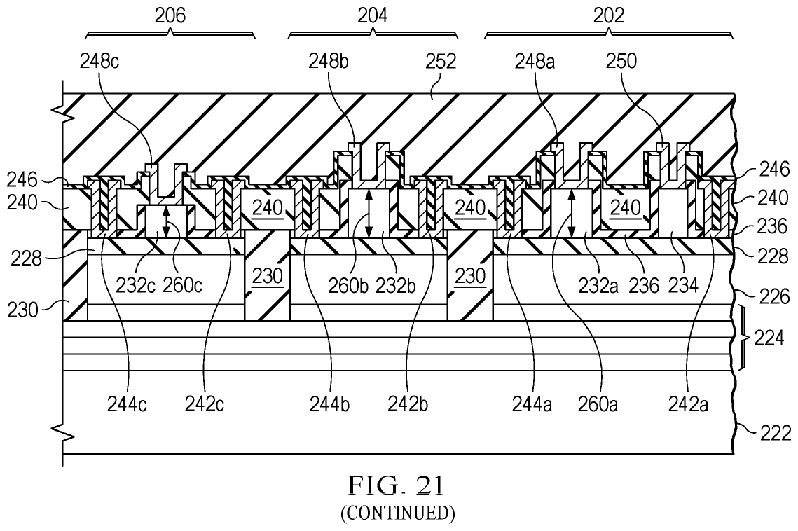

Referring to block 1030 and to FIG. 21, the fifth dielectric layer 252 is formed over and on the gate electricals contact 248a-248g, the injection metal contact 250, and the fourth dielectric layer 246. The fifth dielectric layer 252 may be deposited using any appropriate deposition process, such as PECVD or the like. The fifth dielectric layer 252 may be any material described above with respect to the fifth dielectric layer 252. The fifth dielectric layer 252 may be planarized, such as by a chemical mechanical polish (CMP).

Referring to block 1032 and to FIG. 2, metal vias 254a-254v are formed through the fifth dielectric layer 252 and, where appropriate, the fourth dielectric layer 246, and metal lines 256a-256t are formed over and on the fifth dielectric layer 252. Via openings may be formed through the fifth dielectric layer 252 and, where appropriate, the fourth dielectric layer 246 to respective metal contacts 242a-242g, 244a-244g, 248a-248g, 250 using appropriate photolithography and etching processes. A metal(s) of the metal vias 254a-254v and metal lines 256a-256t are deposited over the fifth dielectric layer 252 and in the via openings. The metal(s) may be deposited using an appropriate deposition process(es), such as CVD, PVD, or the like. The metal(s) may be patterned into the metal lines 256a-256t using appropriate photolithography and etching processes. The metal(s) underlying the metal lines 256a-256t and in the respective via openings through the fifth dielectric layer 252 and, where appropriate, the fourth dielectric layer 246 form the metal vias 254a-254v.

The method 1000 of FIG. 10 may also be implemented to manufacture the IC 300 of FIG. 3. To do so, the source metal contact 244c may be omitted (e.g., the source/drain opening corresponding to the source metal contact 244c is omitted, and patterning the metal(s) corresponding to the source metal contact 244c is omitted). Further, and similarly, the metal via 254j and metal line 256i may be omitted. The anode layer 332c may be formed like the gate layer 232c; the cathode metal contact 342c may be formed like the drain metal contact 242c; and the anode metal contact 348c may be formed like the gate metal contact 248c. Such modifications may be made to subsequently described methods of manufacturing ICs to implement the third semiconductor device 306 or similar semiconductor devices.

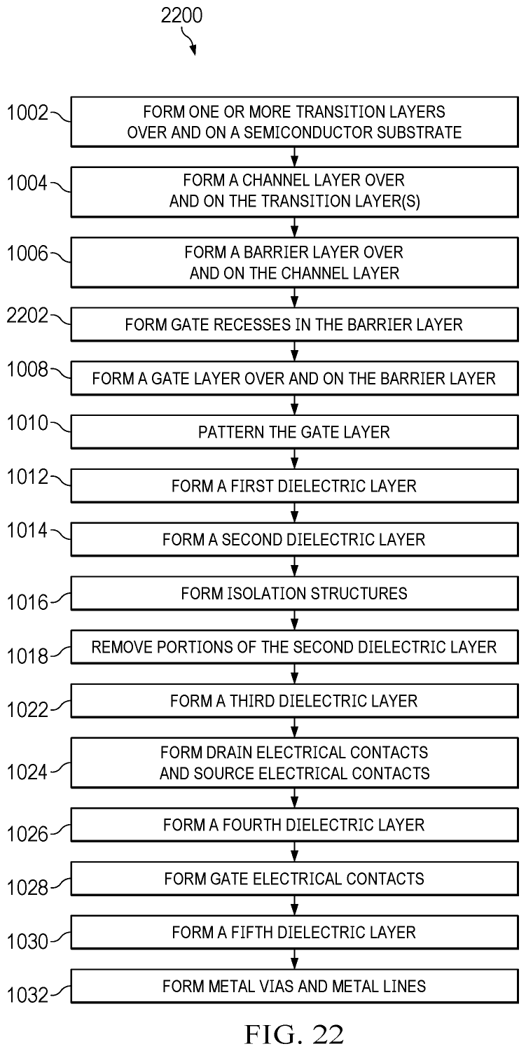

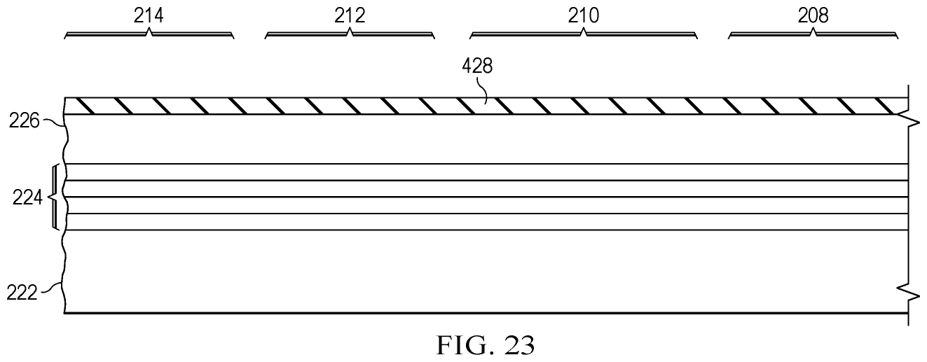

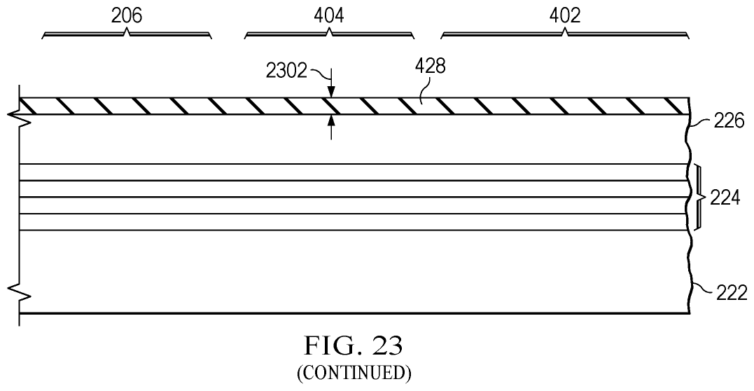

FIG. 22 is a flowchart of a method 2200 of manufacturing the IC 400 of FIG. 4 according to some examples. The method 2200 of FIG. 22 is illustrated by and described in the context of FIGS. 23 through 26, which illustrate cross-sectional views of the IC 400 at various stages of manufacturing. Although the method 2200 of FIG. 22 is illustrated in the context of FIGS. 23 through 26 to manufacture the IC 400 of FIG. 4, the method 2200 of FIG. 22 may also be implemented to manufacture examples consistent with aspects of any IC described herein.

Referring to block 1002 of FIG. 22 and to FIG. 23, one or more transition layers 224 are formed over and on a semiconductor substrate 222. At block 1004, a channel layer 226 is formed over and on the transition layer(s) 224. At block 1006, a barrier layer 428 is formed over and on the channel layer 226. The processing for blocks 1002-1006 may be as described previously. The barrier layer 428 is formed with a thickness 2302.

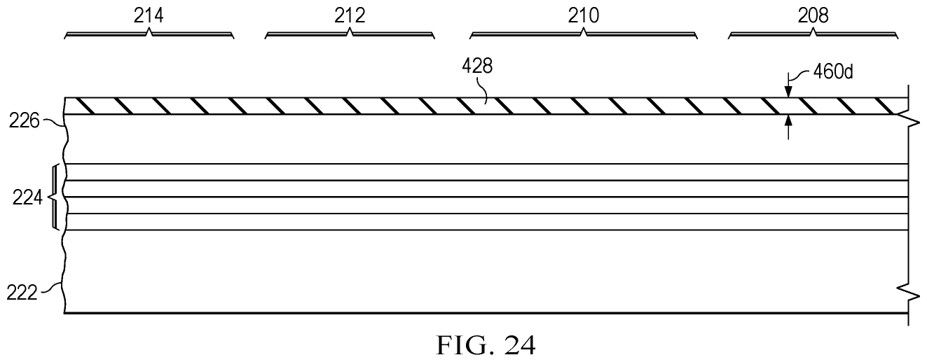

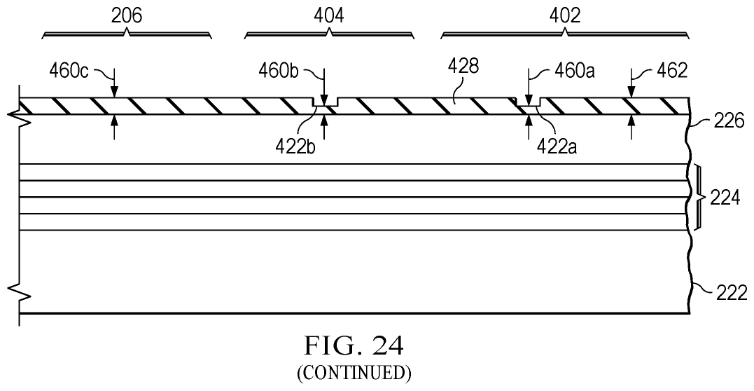

Referring to block 2202 and to FIG. 24, gate recesses 422a, 422b are formed in the barrier layer 428. The gate recesses 422a, 422b may be formed using appropriate photolithography and etch processes. After forming the gate recesses 422a, 422b, the barrier layer 428 has thicknesses 460a, 460b at the respective gate recesses 422a, 422b. Further, after forming the gate recesses 422a, 422b, the barrier layer 428 has thicknesses 460c, 460d, 462, which is approximately the thickness 2302 (e.g., possibly with minor loss due to processing).

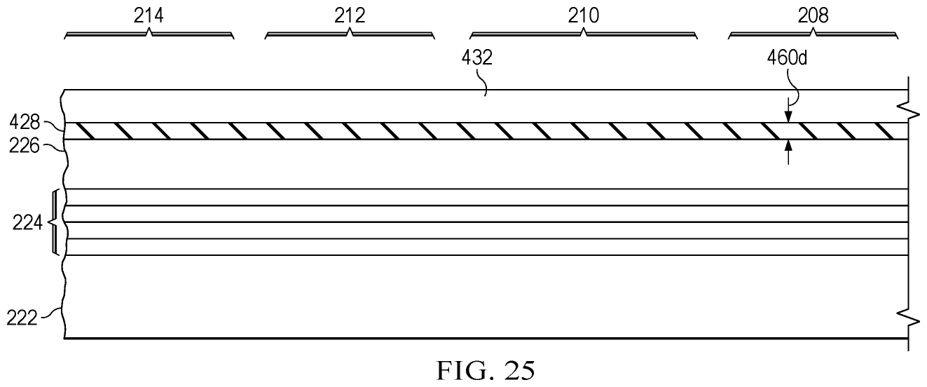

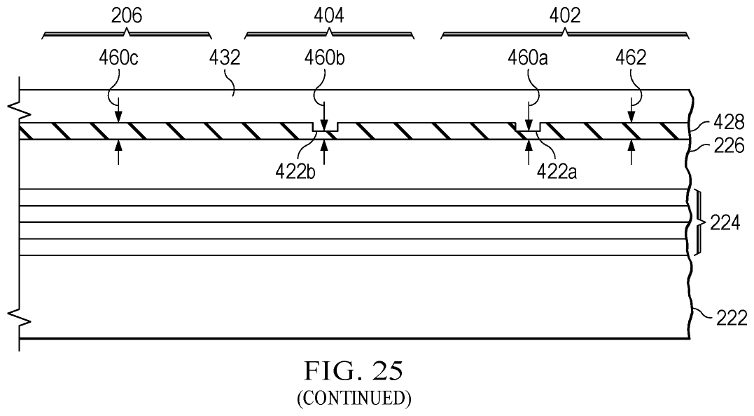

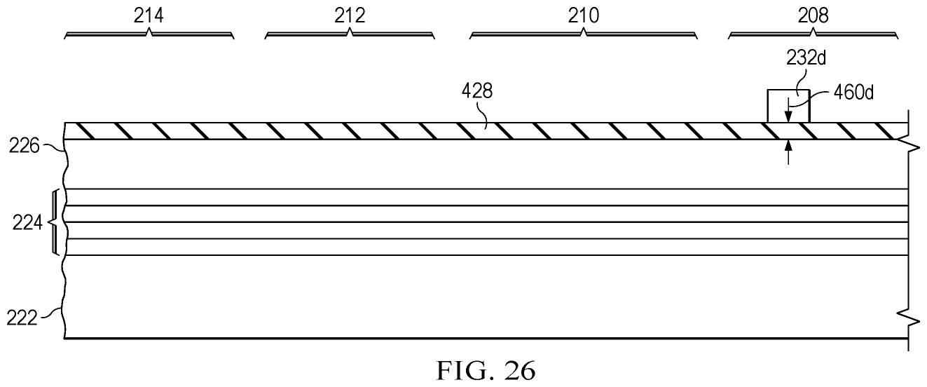

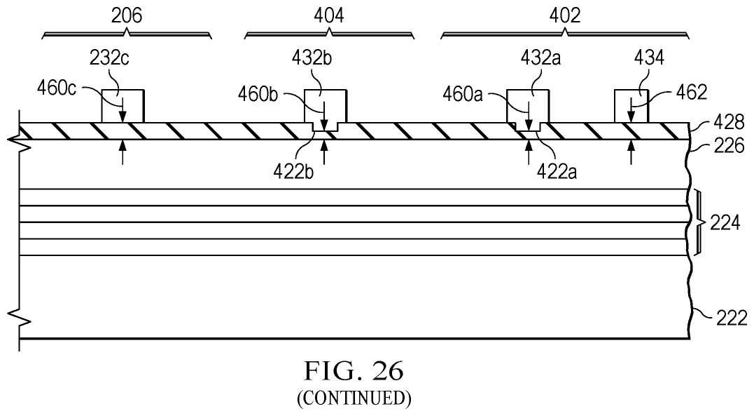

Referring to block 1008 of FIG. 22 and to FIG. 25, a gate layer 432 is formed over and on the barrier layer 428. Forming the gate layer 432 forms the gate layer 432 conformally in the gate recesses 422a, 422b. Referring to block 1010 of FIG. 22 and to FIG. 26, the gate layer 432 is patterned into the gate layers 432a, 432b, 232c, 232d and the injection layer 434. Subsequently, to form the IC 400 of FIG. 4, at block 1012, the first dielectric layer 236 is formed conformally over and on the barrier layer 428, gate layers 432a, 432b, 232c, 232d, and injection layer 434. At block 1014, the second dielectric layer 238 is formed conformally over and on the first dielectric layer 236. At block 1016, the isolation structures 230 are formed. At block 1018, portions of the second dielectric layer 238 are removed from regions in which the sixth semiconductor device 212 and seventh semiconductor device 214 are to be formed. The processing for blocks 1008-1018 may be as described previously.

At block 1022 of FIG. 22, the third dielectric layer 240 is formed. At block 1024, the drain metal contacts 242a-242g and source metal contacts 244a-244g are formed. At block 1026 of FIG. 22, the fourth dielectric layer 246 is formed. At block 1028 of FIG. 22, the gate metal contacts 248a-248g and the injection metal contact 250 are formed. At block 1030 of FIG. 22, the fifth dielectric layer 252 is formed. At block 1032, metal vias 254a-254v and metal lines 256a-256t are formed. The processing for blocks 1022-1032 may be as described previously.

The method 2200 of FIG. 22 may also be implemented to manufacture the IC 500 of FIG. 5. To do so, the injection recess 524 is formed, such as when the gate recesses 422a, 422b are formed. The injection layer 534 may be formed like the injection layer 434. Such modifications may be made to subsequently described methods of manufacturing ICs to implement this aspect of the IC 500.

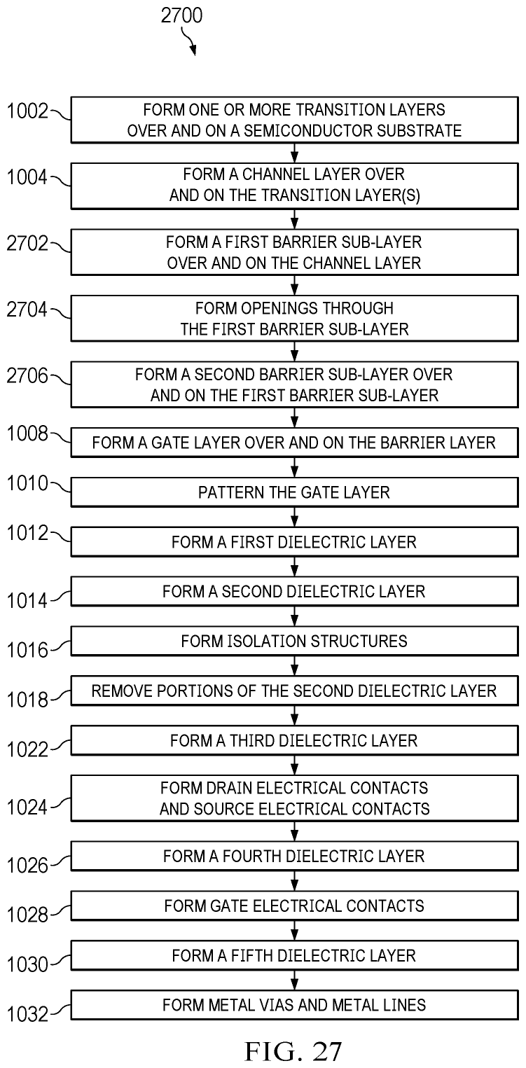

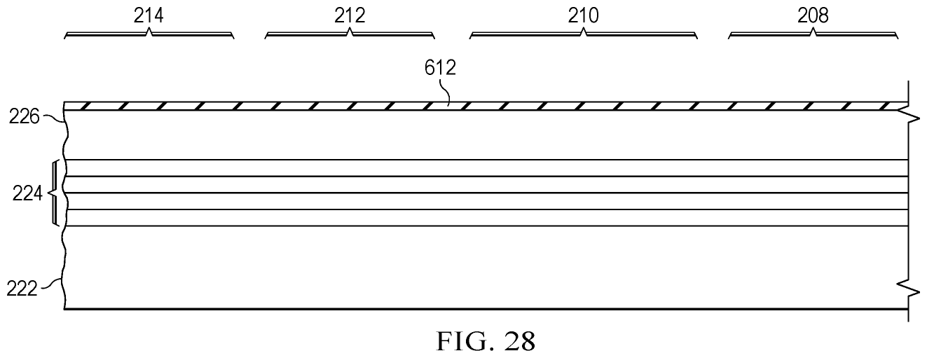

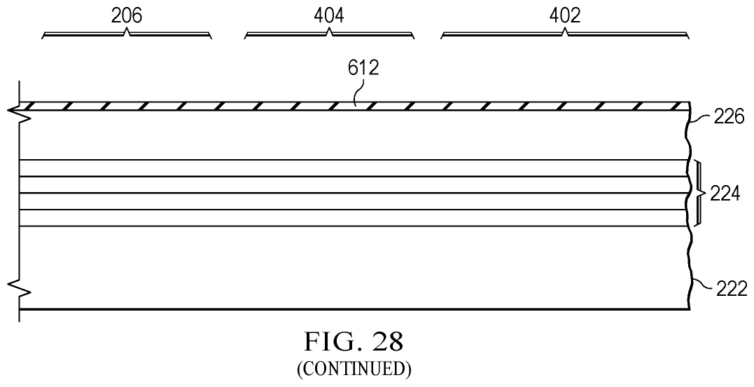

FIG. 27 is a flowchart of a method 2700 of manufacturing the IC 600 of FIG. 6 according to some examples. The method 2700 of FIG. 27 is illustrated by and described in the context of FIGS. 28 through 32, which illustrate cross-sectional views of the IC 600 at various stages of manufacturing. Although the method 2700 of FIG. 27 is illustrated in the context of FIGS. 28 through 32 to manufacture the IC 600 of FIG. 6, the method 2700 of FIG. 27 may also be implemented to manufacture examples consistent with aspects of any IC described herein.

Referring to block 1002 of FIG. 27 and to FIG. 28, one or more transition layers 224 are formed over and on a semiconductor substrate 222. At block 1004, a channel layer 226 is formed over and on the transition layer(s) 224. The processing for blocks 1002, 1004 may be as described previously. At block 2702, the first barrier sub-layer 612 is formed over and on the channel layer 226. The first barrier sub-layer 612 may be formed using processes described with forming the barrier layer 228 in block 1006.

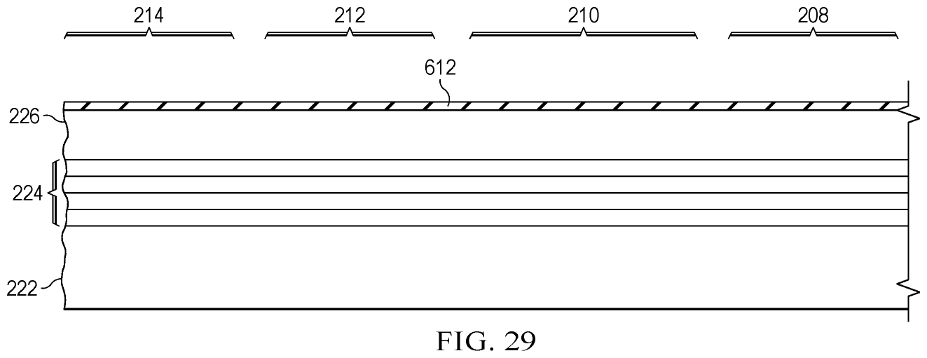

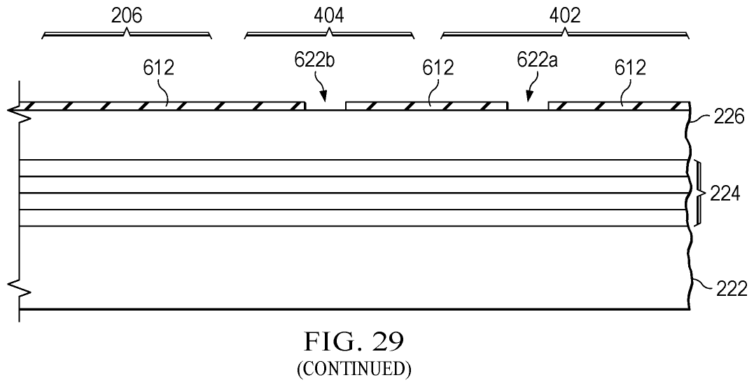

Referring to block 2704 and to FIG. 29, openings 622a, 622b are formed through the first barrier sub-layer 612. The openings 622a, 622b may be formed using appropriate photolithography and etch processes.

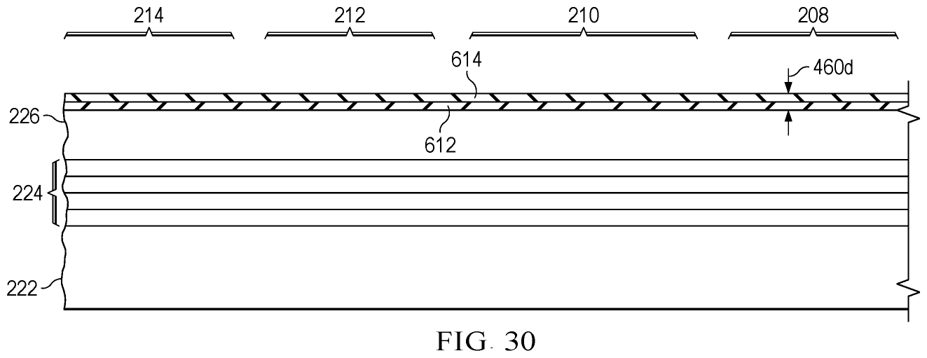

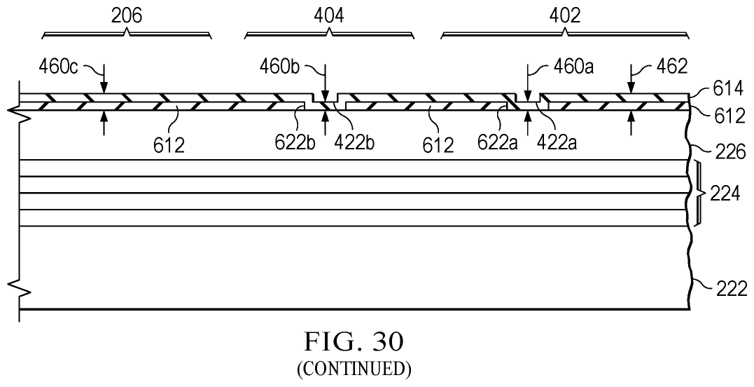

Referring to block 2706 and to FIG. 30, the second barrier sub-layer 614 is formed over and on the first barrier sub-layer 612 and the channel layer 226 exposed through the openings 622a, 622b. The second barrier sub-layer 614 is formed conformally on the first barrier sub-layer 612 and in the openings 622a, 622b. The second barrier sub-layer 614 conforming to the surfaces of the openings 622a, 622b through the first barrier sub-layer 612 forms gate recesses 422a, 422b. The first barrier sub-layer 612 and the second barrier sub-layer 614 may together form a barrier layer. The second barrier sub-layer 614 may be considered a regrowth layer. The barrier layer at the gate recesses 422a, 422b has thicknesses 460a, 460b, which correspond to a thickness of the second barrier sub-layer 614. The barrier layer also has thicknesses 460c, 460d, which correspond to a combined thickness of the first barrier sub-layer 612 and the second barrier sub-layer 614. The second barrier sub-layer 614 may be formed using processes described with forming the barrier layer 228 in block 1006.

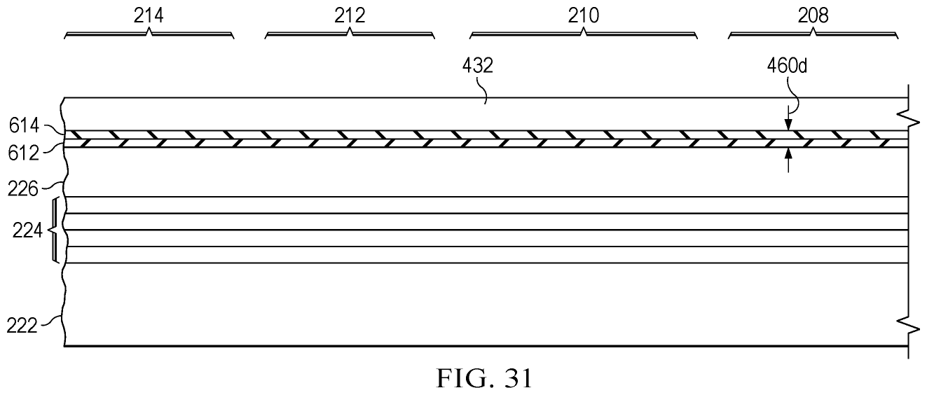

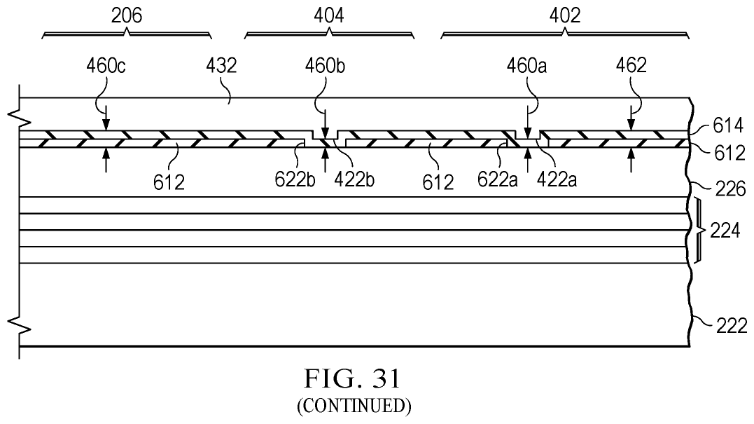

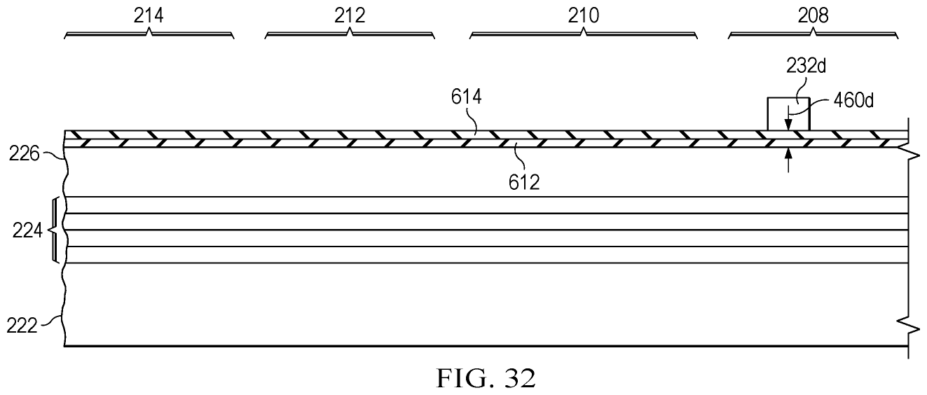

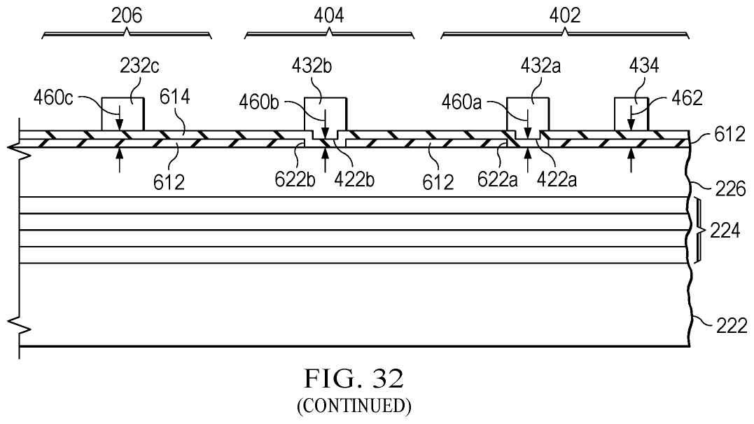

Referring to block 1008 of FIG. 27 and to FIG. 31, a gate layer 432 is formed over and on the barrier layer (e.g., the second barrier sub-layer 614). Referring to block 1010 of FIG. 27 and to FIG. 32, the gate layer 432 is patterned into the gate layers 432a, 432b, 232c, 232d and the injection layer 434. The processing for blocks 1008, 1010 may be as described previously.

Subsequently, to form the IC 600 of FIG. 6, at block 1012 of FIG. 27, the first dielectric layer 236 is formed conformally over and on the barrier layer 428, gate layers 432a, 432b, 232c, 232d, and injection layer 434. At block 1014, the second dielectric layer 238 is formed conformally over and on the first dielectric layer 236. At block 1016, the isolation structures 230 are formed. At block 1018, portions of the second dielectric layer 238 are removed from regions in which the sixth semiconductor device 212 and seventh semiconductor device 214 are to be formed. The processing for blocks 1012-1018 may be as described previously.

At block 1022, the third dielectric layer 240 is formed. At block 1024, the drain metal contacts 242a-242g and source metal contacts 244a-244g are formed. At block 1026 of FIG. 27, the fourth dielectric layer 246 is formed. At block 1028 of FIG. 27, the gate metal contacts 248a-248g and the injection metal contact 250 are formed. At block 1030 of FIG. 27, the fifth dielectric layer 252 is formed. At block 1032 of FIG. 27, metal vias 254a-254v and metal lines 256a-256t are formed. The processing for blocks 1022-1032 may be as described previously.

The method 2700 of FIG. 27 may also be implemented to manufacture an IC similar to the IC 500 of FIG. 5. To do so, an opening corresponding to an injection layer is formed through the first barrier sub-layer 612, such as when the openings 622a, 622b are formed. This may form an injection recess like the injection recess 524 in FIG. 5. The injection layer may be formed in the injection recess like the injection layer 534. Such modifications may be made to subsequently described methods of manufacturing ICs to implement this aspect of the IC 500.

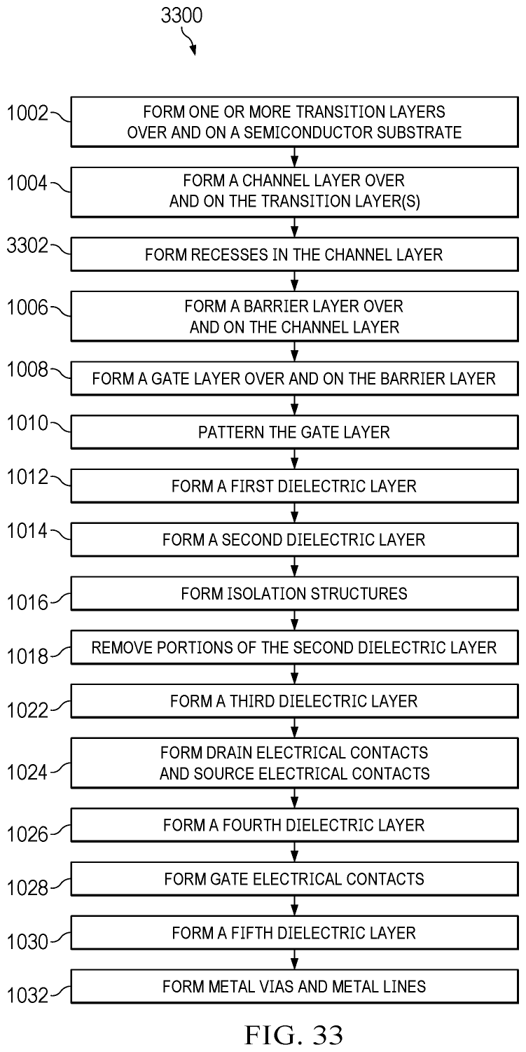

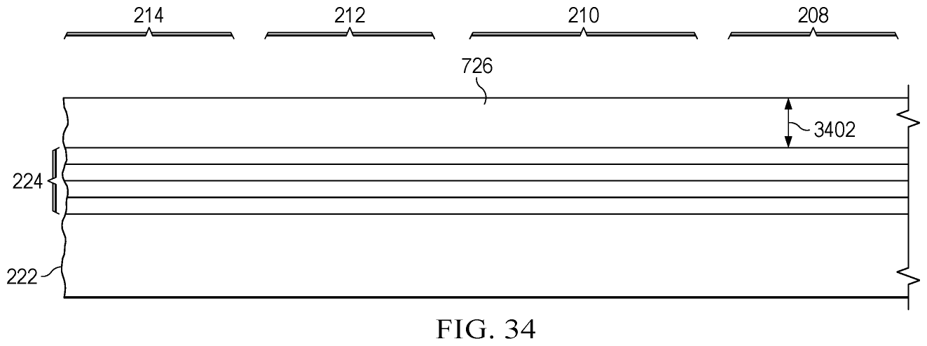

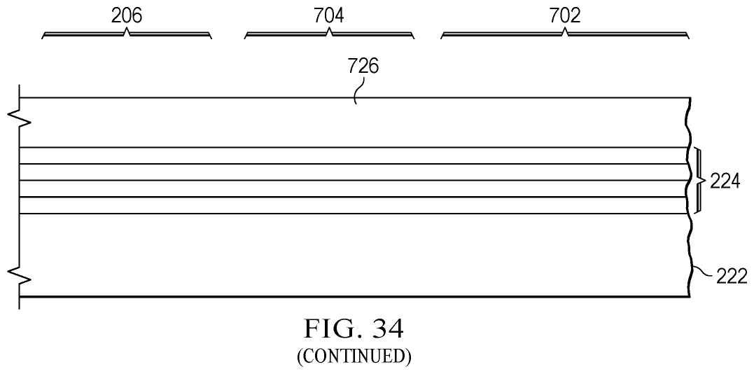

FIG. 33 is a flowchart of a method 3300 of manufacturing the IC 700 of FIG. 7 according to some examples. The method 3300 of FIG. 33 is illustrated by and described in the context of FIGS. 34 through 37, which illustrate cross-sectional views of the IC 700 at various stages of manufacturing. Although the method 3300 of FIG. 33 is illustrated in the context of FIGS. 34 through 37 to manufacture the IC 700 of FIG. 7, the method 3300 of FIG. 33 may also be implemented to manufacture examples consistent with aspects of any IC described herein.

Referring to block 1002 of FIG. 33 and to FIG. 34, one or more transition layers 224 are formed over and on a semiconductor substrate 222. At block 1004, a channel layer 726 is formed over and on the transition layer(s) 224. The channel layer 726 is formed with a thickness 3402. The processing for blocks 1002, 1004 may be as described previously.

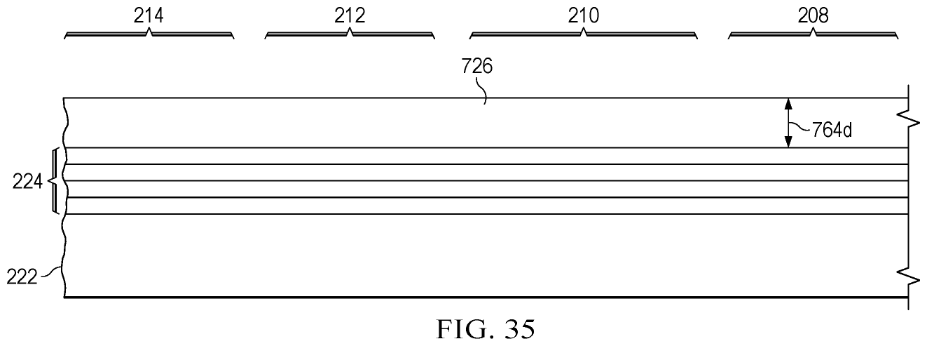

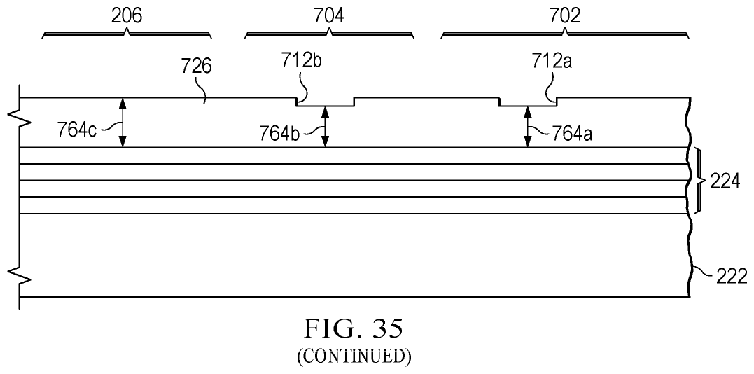

Referring to block 3302 of FIG. 33 and to FIG. 35, recesses 712a, 712b are formed in the channel layer 726. The recesses 712a, 712b may be formed using appropriate photolithography and etch processes. After forming the recesses 712a, 712b, the channel layer 726 has thicknesses 764a, 764b at the respective recesses 712a, 712b. Further, after forming the recesses 712a, 712b, the channel layer 726 has thicknesses 764c, 764d, which is approximately the thickness 3402 (e.g., possibly with minor loss due to processing).

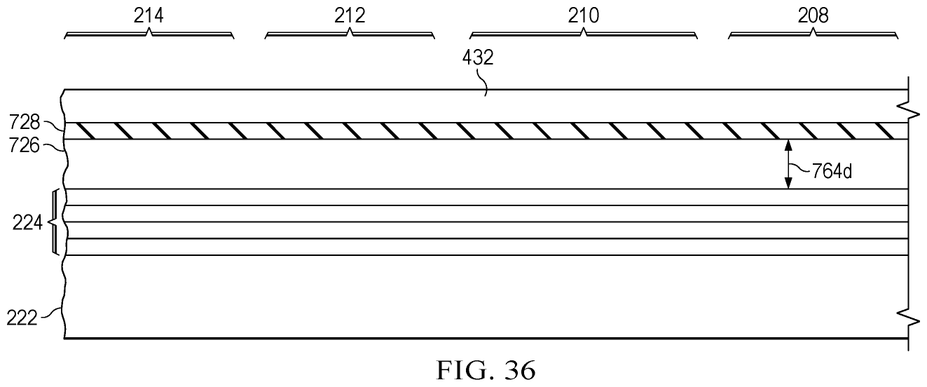

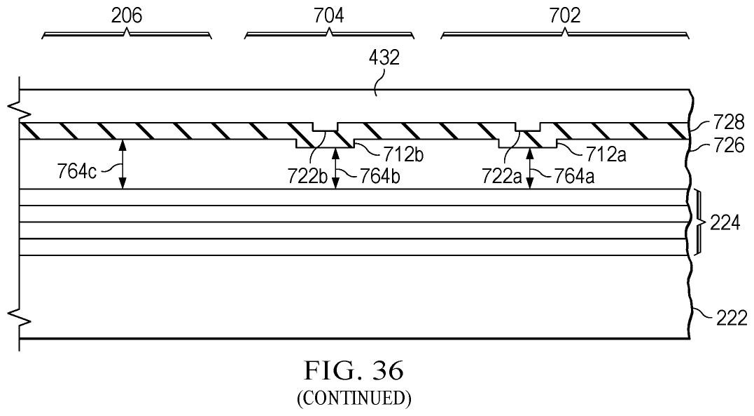

Referring to block 1006 of FIG. 33 and to FIG. 36, the barrier layer 728 is formed over and on the channel layer 726. The barrier layer 728 is formed conformally on the channel layer 726 and in the recesses 712a, 712b. The barrier layer 728 conforming to the surfaces of the recesses 712a, 712b in the channel layer 726 forms gate recesses 722a, 722b. At block 1008, a gate layer 432 is formed over and on the barrier layer 728. Forming the gate layer 432 forms the gate layer 432 conformally in the gate recesses 722a, 722b. The processing for blocks 1006, 1008 may be as described previously.

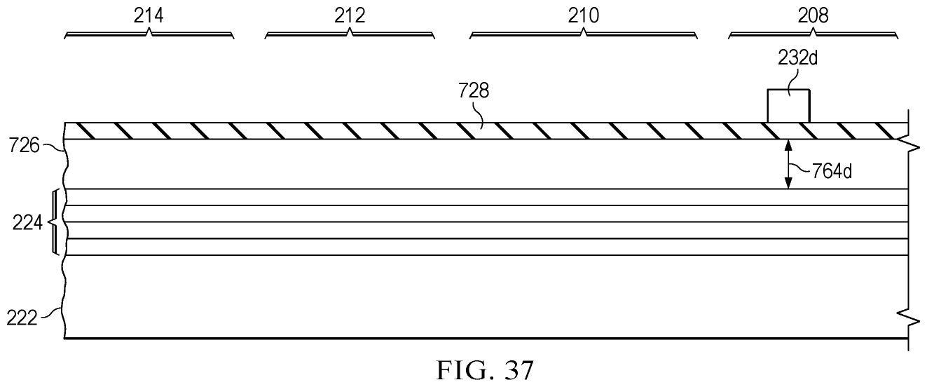

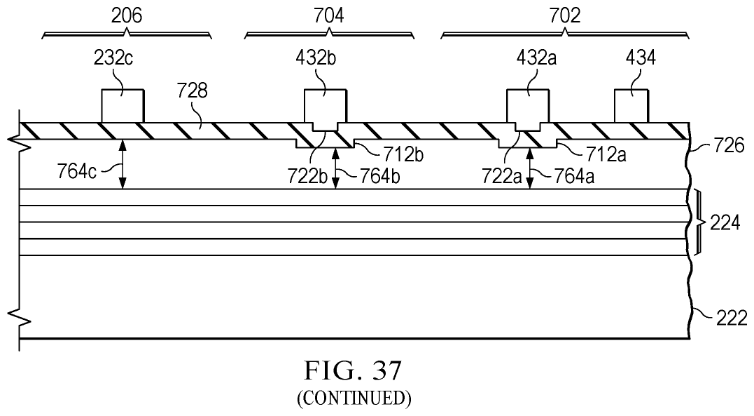

Referring to block 1010 of FIG. 33 and to FIG. 37, the gate layer 432 is patterned into the gate layers 432a, 432b, 232c, 232d and the injection layer 434. Subsequently, to form the IC 700 of FIG. 7, at to block 1012 of FIG. 33, the first dielectric layer 236 is formed conformally over and on the barrier layer 428, gate layers 432a, 432b, 232c, 232d, and injection layer 434. At block 1014, the second dielectric layer 238 is formed conformally over and on the first dielectric layer 236. At block 1016, the isolation structures 230 are formed. At block 1018, portions of the second dielectric layer 238 are removed from regions in which the sixth semiconductor device 212 and seventh semiconductor device 214 are to be formed. The processing for blocks 1010-1018 may be as described previously.

At block 1022, the third dielectric layer 240 is formed. At block 1024, the drain metal contacts 242a-242g and source metal contacts 244a-244g are formed. At block 1026, the fourth dielectric layer 246 is formed. At block 1028, the gate metal contacts 248a-248g and the injection metal contact 250 are formed. At block 1030, the fifth dielectric layer 252 is formed. At block 1032, metal vias 254a-254v and metal lines 256a-256t are formed. The processing for blocks 1022-1032 may be as described previously.

The IC 800 of FIG. 8 (or another IC implementing varied lengths of gate layers) may be manufactured using any of the methods described above and by implementing a photolithography mask during patterning the gate layers that achieves the lengths 866a, 866b, 866c, 866d. The photolithography mask may be used in a photolithography process implemented, for example, at block 1010 and in reference to FIG. 12, 26, 32, or 37.

The IC 900 of FIG. 9 (or another IC implementing varied lengths of gate metal contacts) may be manufactured using any of the methods described above and by implementing a photolithography mask during patterning the gate contact openings that achieves the lengths 968a, 968b, 968c, 968d. The photolithography mask may be used in a photolithography process implemented, for example, at block 1028 and in reference to FIG. 20.

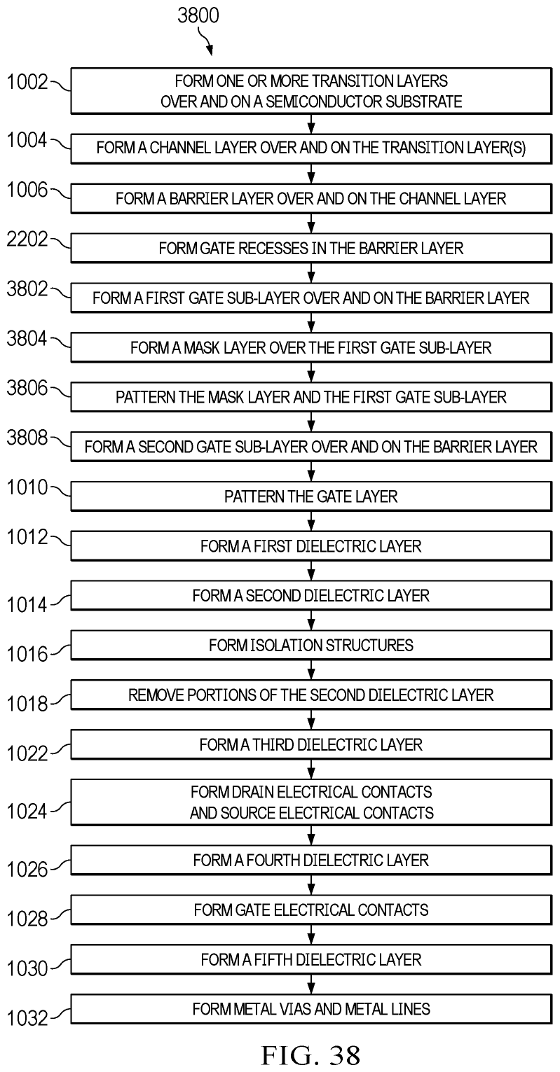

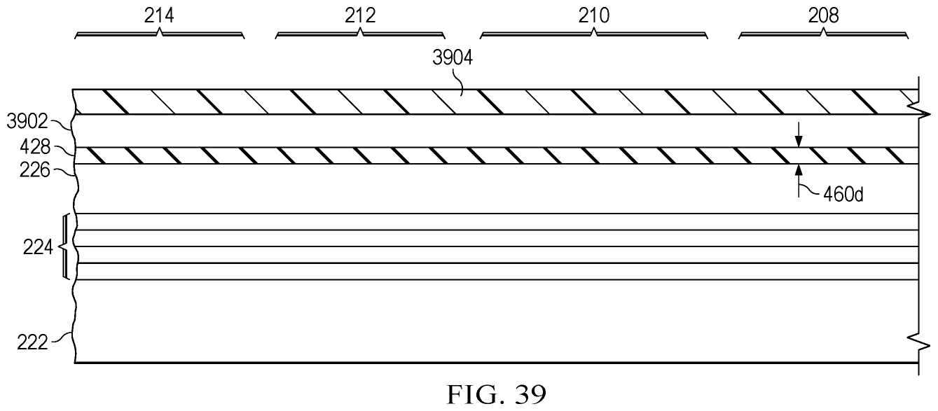

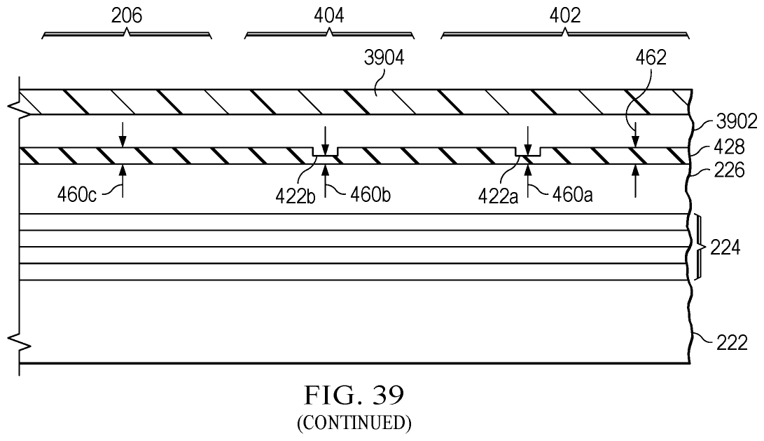

FIG. 38 is a flowchart of a method 3800 of manufacturing an IC in which gate layers have different doping concentrations according to some examples. The method 3800 of FIG. 38 is illustrated by and described in the context of FIGS. 39 through 42, which illustrate cross-sectional views of the IC at various stages of manufacturing. Although the method 3800 of FIG. 38 is illustrated in the context of FIGS. 39 through 42 to manufacture the illustrated IC, the method 3800 of FIG. 38 may also be implemented to manufacture examples consistent with aspects of any IC described herein.

Referring to block 1002 of FIG. 38 and to FIG. 39, one or more transition layers 224 are formed over and on a semiconductor substrate 222. At block 1004, a channel layer 226 is formed over and on the transition layer(s) 224. At block 1006, a barrier layer 428 is formed over and on the channel layer 226. At block 2202, gate recesses 422a, 422b are formed in the barrier layer 428. The processing for blocks 1002-1006, 2202 may be as described previously.

At block 3802, a first gate sub-layer 3902 is formed over and on the barrier layer 428. The first gate sub-layer 3902 may be formed using processing as described above with respect to forming the gate layer 432 at block 1008. More specifically, the first gate sub-layer 3902 may be formed using an epitaxial growth process with in situ doping at a first dopant concentration, e.g., of a p-type dopant. At block 3804, a mask layer 3904 is formed over the first gate sub-layer 3902. The mask layer 3904 may be or include silicon nitride or the like and may be deposited by PECVD or another deposition process.

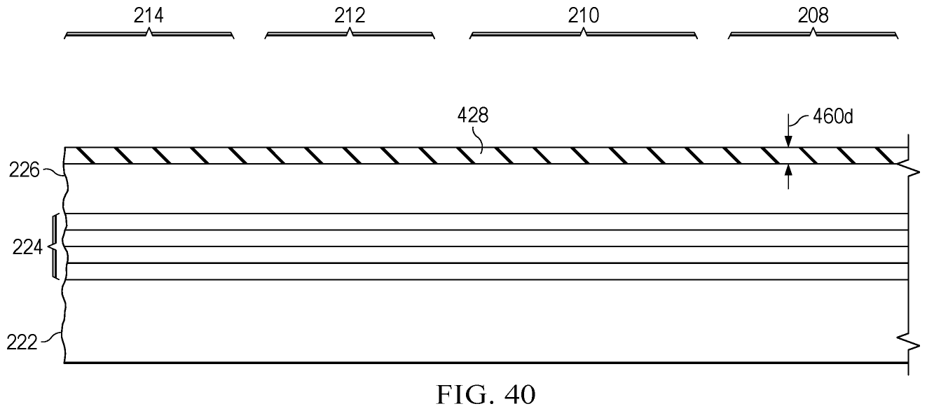

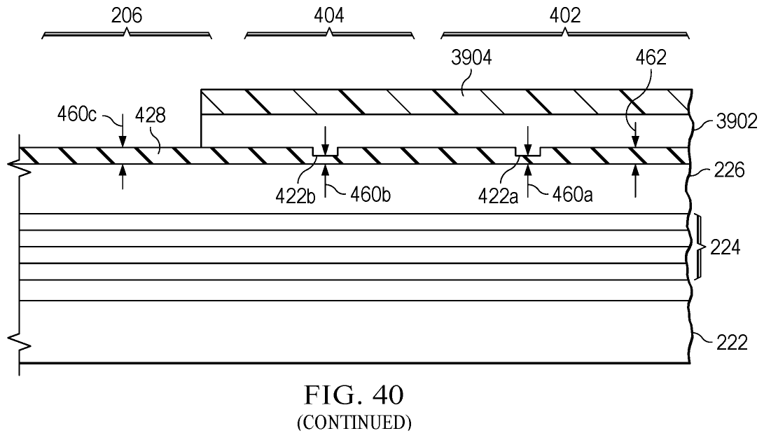

Referring to block 3806 of FIG. 38 and to FIG. 40, the mask layer 3904 and first gate sub-layer 3902 are patterned. The patterning may be by appropriate photolithography and etch processes.

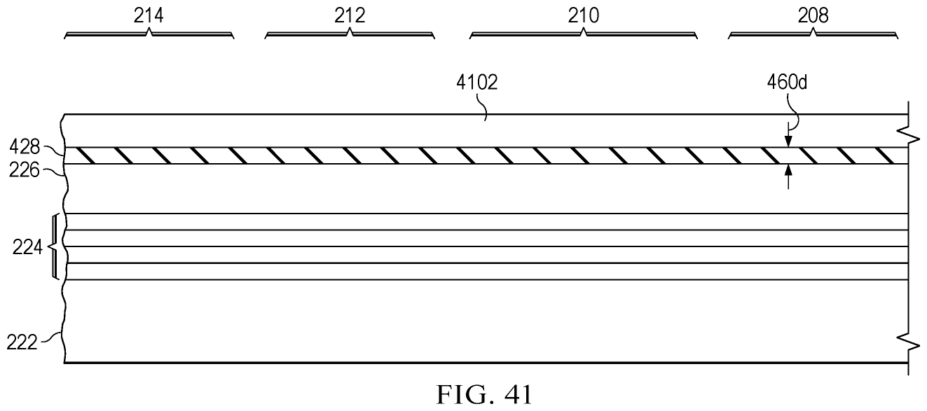

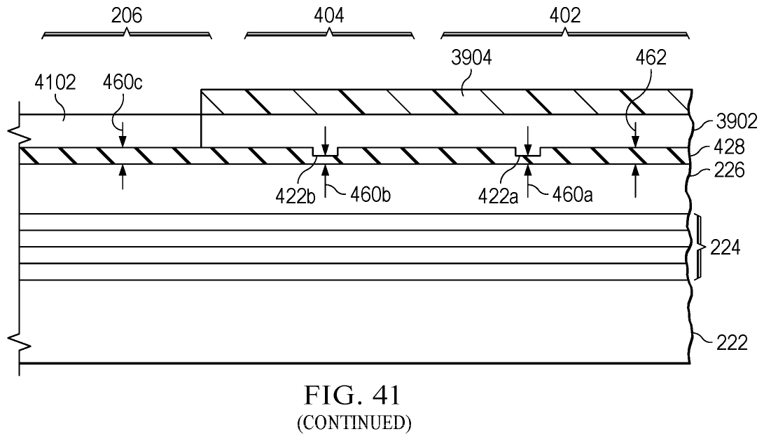

Referring to block 3808 of FIG. 38 and to FIG. 41, a second gate sub-layer 4102 is formed over and on the barrier layer 428. The second gate sub-layer 4102 is formed where the first gate sub-layer 3902 was removed in the patterning at block 3806. The second gate sub-layer 4102 may be formed using processing as described above with respect to forming the gate layer 432 at block 1008. More specifically, the second gate sub-layer 4102 may be formed using a selective epitaxial growth process with in situ doping at a second dopant concentration, e.g., of a p-type dopant. The second dopant concentration is different from the first dopant concentration (e.g., by different uniform concentration or by different gradient concentration). Following the formation of the second gate sub-layer 4102, the mask layer 3904 may be removed, such as using an etch process (e.g., a wet etch) that is selective to the material of the mask layer 3904. Together, the first gate sub-layer 3902 and second gate sub-layer 4102 form a gate layer (e.g., gate layer 432).

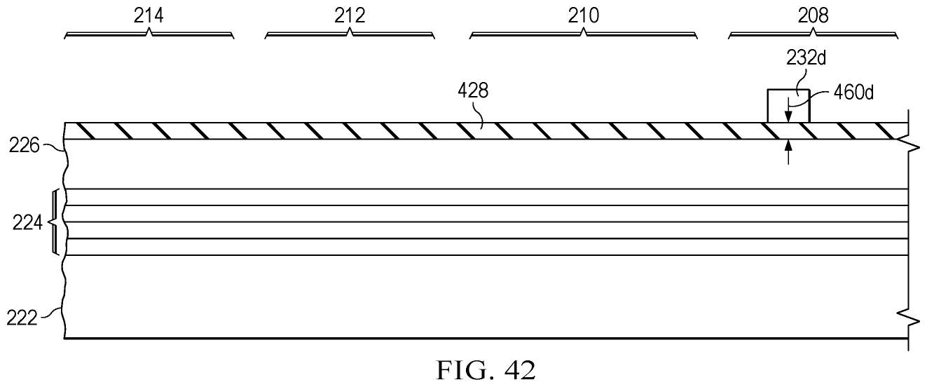

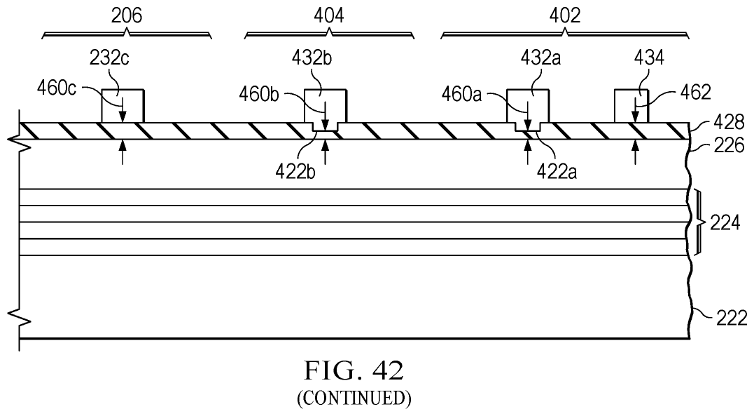

Referring to block 1010 of FIG. 38 and to FIG. 42, the gate layer 432 is patterned into the gate layers 432a, 432b, 232c, 232d and the injection layer 434. The gate layers 432a, 432b and injection layer 434 are patterned from the first gate sub-layer 3902 and have the first dopant concentration. The gate layers 232c, 232d are patterned from the second gate sub-layer 4102 and have the second dopant concentration. Subsequently, at block 1012, the first dielectric layer 236 is formed conformally over and on the barrier layer 428, gate layers 432a, 432b, 232c, 232d, and injection layer 434. At block 1014, the second dielectric layer 238 is formed conformally over and on the first dielectric layer 236. At block 1016 of FIG. 38, the isolation structures 230 are formed. At block 1018, portions of the second dielectric layer 238 are removed from regions in which the sixth semiconductor device 212 and seventh semiconductor device 214 are to be formed. The processing for blocks 1010-1018 may be as described previously.

At block 1022, the third dielectric layer 240 is formed. At block 1024, the drain metal contacts 242a-242g and source metal contacts 244a-244g are formed. At block 1026, the fourth dielectric layer 246 is formed. At block 1028, the gate metal contacts 248a-248g and the injection metal contact 250 are formed. At block 1030, the fifth dielectric layer 252 is formed. At block 1032, metal vias 254a-254v and metal lines 256a-256t are formed. The processing for blocks 1022-1032 may be as described previously.

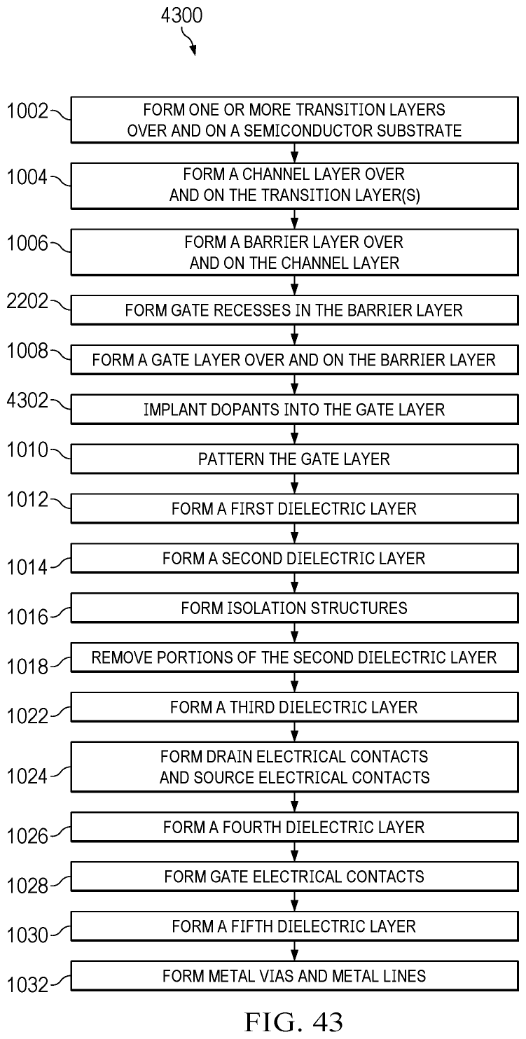

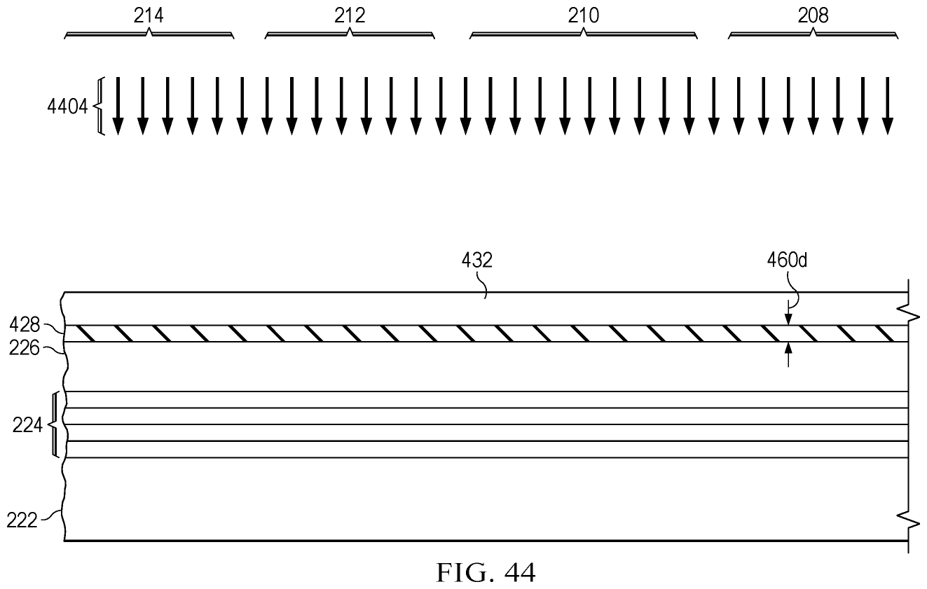

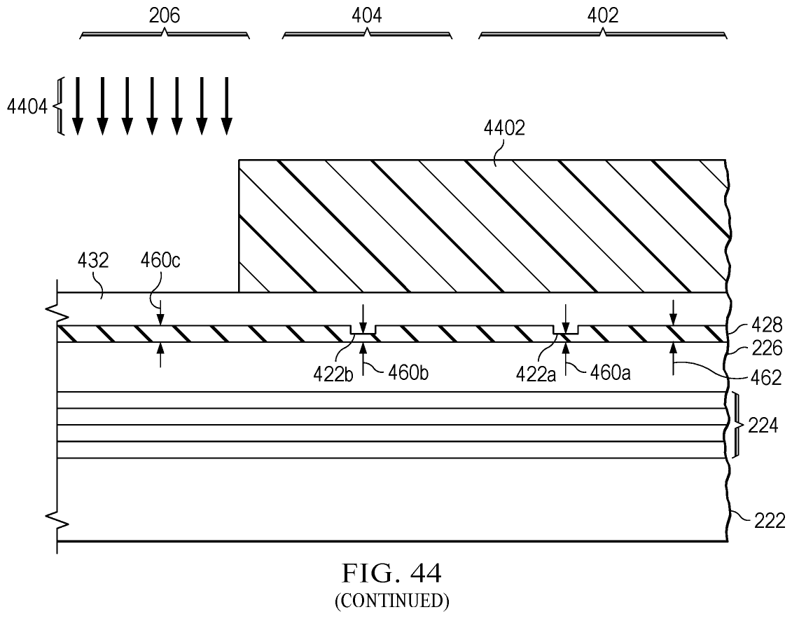

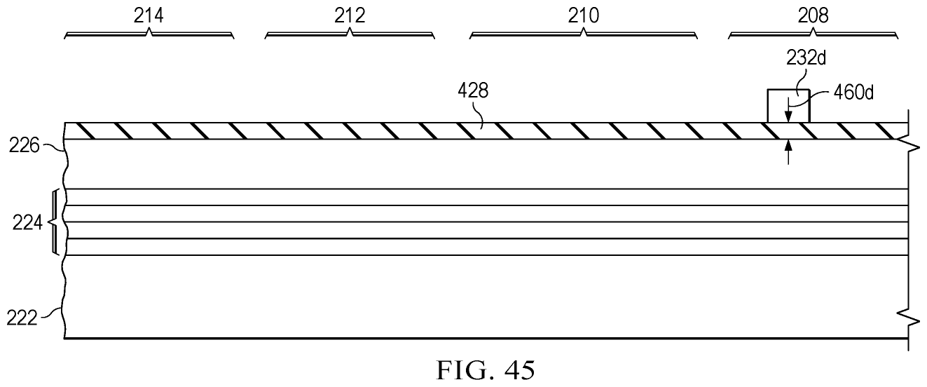

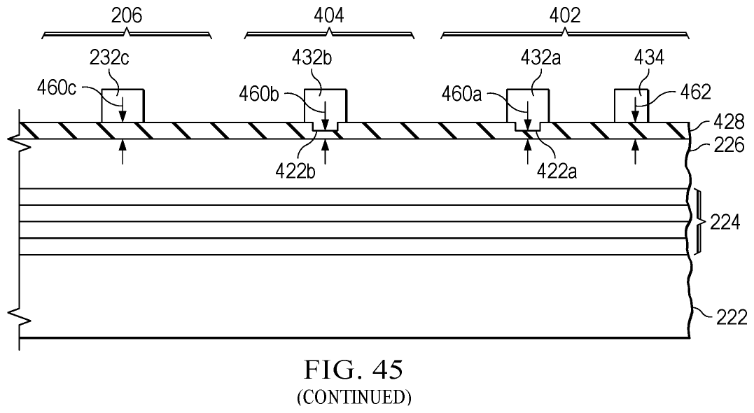

FIG. 43 is a flowchart of a method 4300 of manufacturing an IC in which gate layers have different doping concentrations according to some examples. The method 4300 of FIG. 43 is illustrated by and described in the context of FIGS. 44 and 45, which illustrate cross-sectional views of the IC at various stages of manufacturing. Although the method 4300 of FIG. 43 is illustrated in the context of FIGS. 44 and 45 to manufacture the illustrated IC, the method 4300 of FIG. 43 may also be implemented to manufacture examples consistent with aspects of any IC described herein.

Referring to block 1002 of FIG. 43 and to FIG. 44, one or more transition layers 224 are formed over and on a semiconductor substrate 222. At block 1004, a channel layer 226 is formed over and on the transition layer(s) 224. At block 1006, a barrier layer 428 is formed over and on the channel layer 226. At block 2202, gate recesses 422a, 422b are formed in the barrier layer 428. The processing for blocks 1002-1006, 2202 may be as described previously.

At block 1008 of FIG. 43, a gate layer 432 is formed over and on the barrier layer 428. The gate layer 432 may be formed using processing as described above with respect to block 1008. More specifically, the gate layer 432 may be formed using an epitaxial growth process with in situ doping at a first dopant concentration, e.g., of a p-type dopant. At block 4302, dopants are implanted into the gate layer 432. The dopants are implanted into portions of the gate layer 432 where the dopant concentration is to be greater than the first dopant concentration. For example, some portions of the gate layer 432 may be masked, such as by a photoresist 4402 illustrated in FIG. 44, and other portions of the gate layer 432 are exposed and implanted with dopants by an implantation 4404. The photoresist 4402 may be deposited and patterned using appropriate photolithography processes. The implantation 4404 implants dopants into the exposed portions of the gate layer 432 to a second concentration greater than the first concentration. The photoresist 4402 may thereafter be removed, such as by ashing.

Referring to block 1010 of FIG. 43 and to FIG. 45, the gate layer 432 is patterned into the gate layers 432a, 432b, 232c, 232d and the injection layer 434. The gate layers 432a, 432b and injection layer 434 have the first dopant concentration since the portion of the gate layer 432 from which the gate layers 432a, 432b and injection layer 434 were formed was masked by the photoresist 4402 during the implantation 4404. The gate layers 232c, 232d have the second dopant concentration since the portion of the gate layer 432 from which the gate layers 232c, 232d were formed was implanted with dopants by the implantation 4404. The processing for block 1010 may be as described previously.

Subsequently, at block 1012, the first dielectric layer 236 is formed conformally over and on the barrier layer 428, gate layers 432a, 432b, 232c, 232d, and injection layer 434. At block 1014, the second dielectric layer 238 is formed conformally over and on the first dielectric layer 236. At block 1016, the isolation structures 230 are formed. At block 1018, portions of the second dielectric layer 238 are removed from regions in which the sixth semiconductor device 212 and seventh semiconductor device 214 are to be formed. The processing for blocks 1012-1018 may be as described previously.

At block 1022, the third dielectric layer 240 is formed. At block 1024, the drain metal contacts 242a-242g and source metal contacts 244a-244g are formed. At block 1026, the fourth dielectric layer 246 is formed. At block 1028, the gate metal contacts 248a-248g and the injection metal contact 250 are formed. At block 1030, the fifth dielectric layer 252 is formed. At block 1032, metal vias 254a-254v and metal lines 256a-256t are formed. The processing for blocks 1022-1032 may be as described previously.

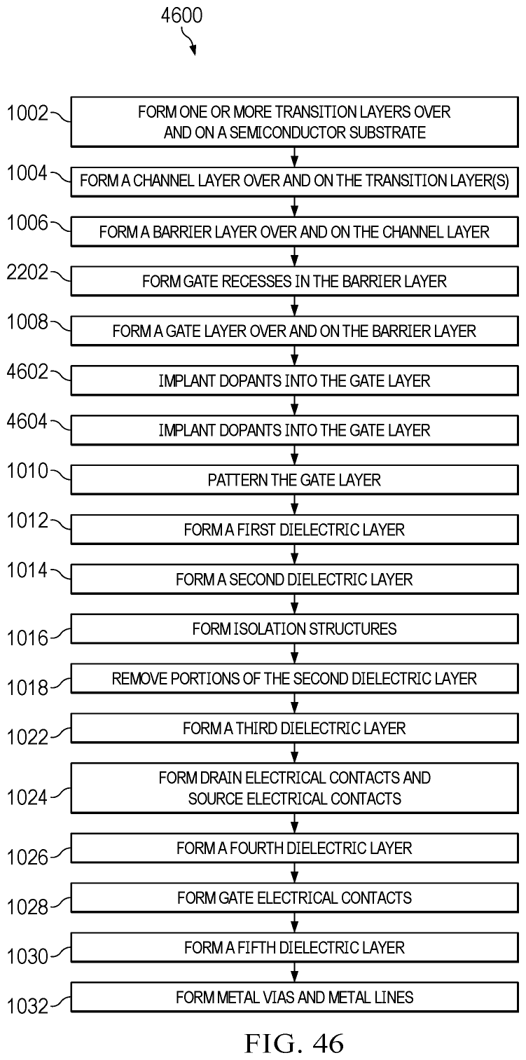

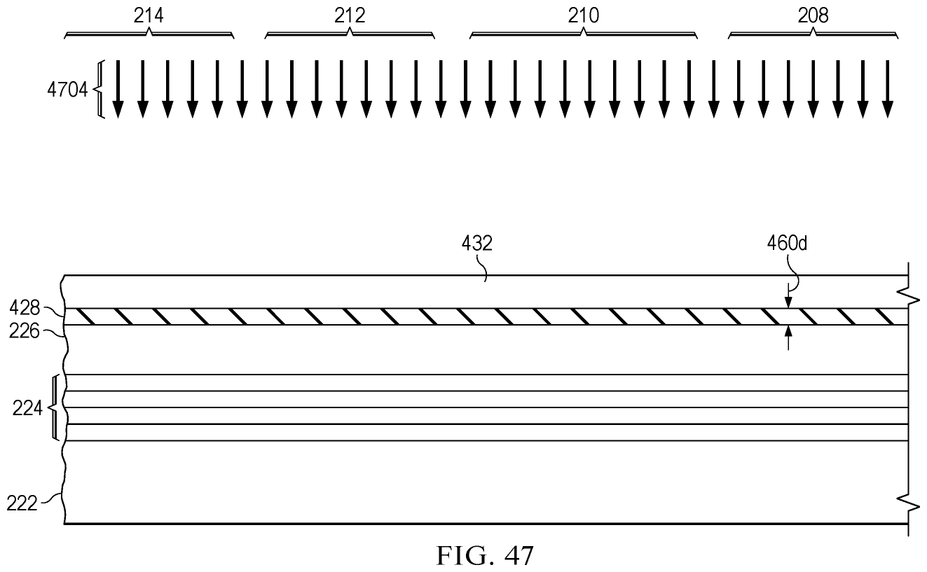

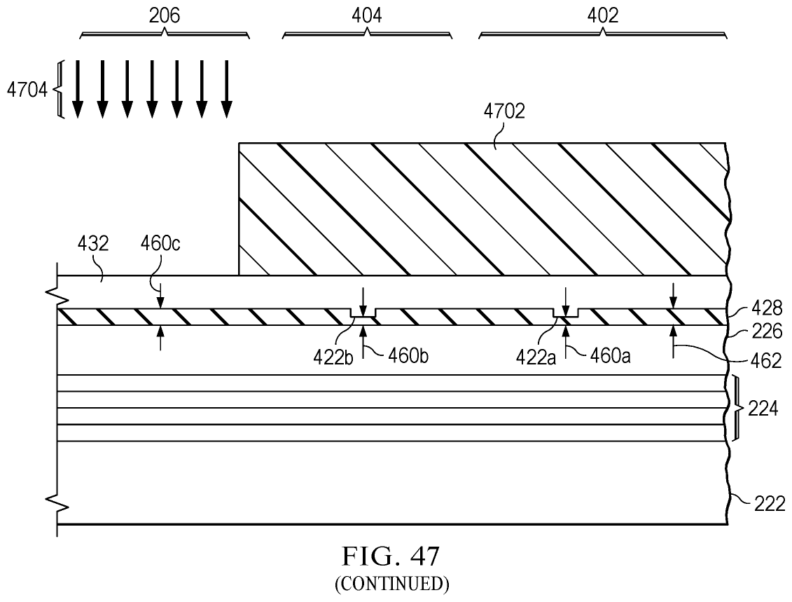

FIG. 46 is a flowchart of a method 4600 of manufacturing an IC in which gate layers have different doping concentrations according to some examples. The method 4600 of FIG. 46 is illustrated by and described in the context of FIGS. 47 through 49, which illustrate cross-sectional views of the IC at various stages of manufacturing. Although the method 4600 of FIG. 46 is illustrated in the context of FIGS. 47 through 49 to manufacture the illustrated IC, the method 4600 of FIG. 46 may also be implemented to manufacture examples consistent with aspects of any IC described herein.

Referring to block 1002 of FIG. 46 and to FIG. 47, one or more transition layers 224 are formed over and on a semiconductor substrate 222. At block 1004, a channel layer 226 is formed over and on the transition layer(s) 224. At block 1006, a barrier layer 428 is formed over and on the channel layer 226. At block 2202, gate recesses 422a, 422b are formed in the barrier layer 428. The processing for blocks 1002-1006, 2202 may be as described previously.

At block 1008, a gate layer 432 is formed over and on the barrier layer 428. The gate layer 432 may be formed using processing as described above with respect to block 1008. The gate layer 432 may or may not be in situ doped during formation. At block 4602, dopants are implanted into the gate layer 432. The dopants are implanted into portions of the gate layer 432 where the dopant concentration is to be a first dopant concentration. For example, some portions of the gate layer 432 may be masked, such as by a photoresist 4702 illustrated in FIG. 47, and other portions of the gate layer 432 are exposed and implanted with dopants by an implantation 4704. The photoresist 4702 may be deposited and patterned using appropriate photolithography processes. The implantation 4704 implants dopants into the exposed portions of the gate layer 432 to a first concentration. The photoresist 4702 may thereafter be removed, such as by ashing.

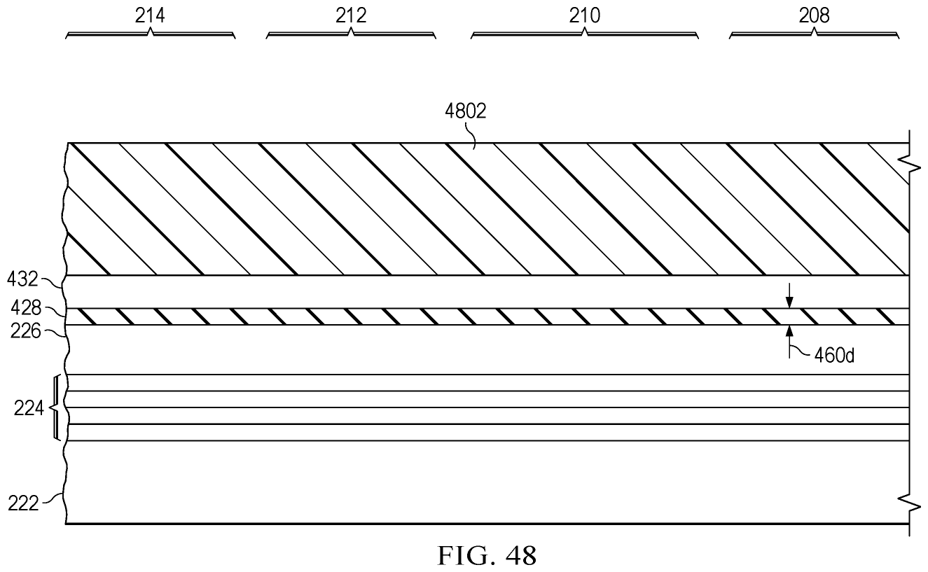

Referring to block 4604 of FIG. 46 and to FIG. 48, dopants are implanted into the gate layer 432. The dopants are implanted into portions of the gate layer 432 where the dopant concentration is to be a second dopant concentration. For example, some portions of the gate layer 432 may be masked, such as by a photoresist 4802 illustrated in FIG. 48, and other portions of the gate layer 432 are exposed and implanted with dopants by an implantation 4804. The photoresist 4802 may be deposited and patterned using appropriate photolithography processes. The implantation 4804 implants dopants into the exposed portions of the gate layer 432 to a second concentration different from the first concentration. The photoresist 4802 may thereafter be removed, such as by ashing.

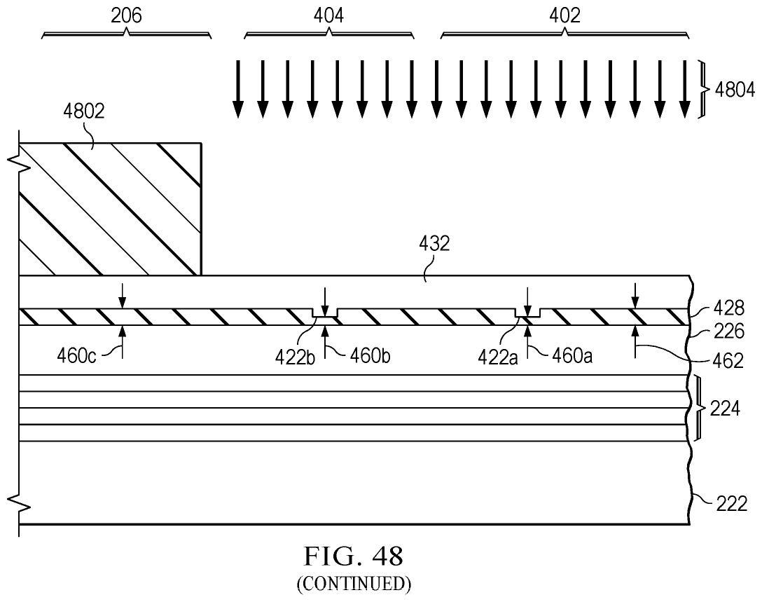

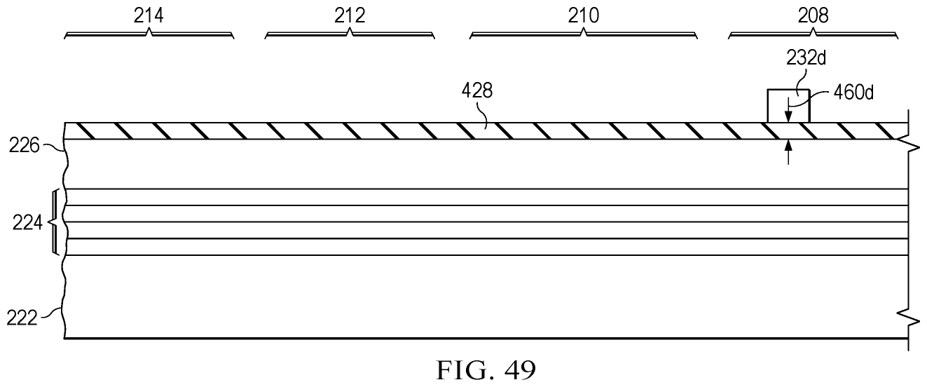

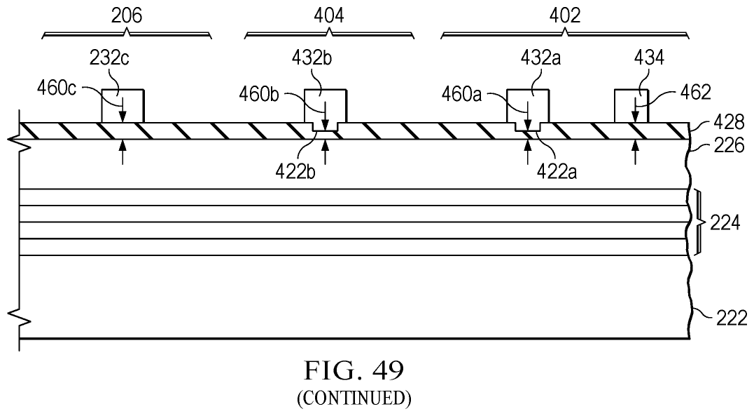

Referring to block 1010 of FIG. 46 and to FIG. 49, the gate layer 432 is patterned into the gate layers 432a, 432b, 232c, 232d and the injection layer 434. The gate layers 432a, 432b and injection layer 434 have the second dopant concentration since the portion of the gate layer 432 from which the gate layers 432a, 432b and injection layer 434 were formed was implanted by the implantation 4804 and masked by the photoresist 4702 during the implantation 4704. The gate layers 232c, 232d the first dopant concentration since the portion of the gate layer 432 from which the gate layers 232c, 232d were formed was implanted by the implantation 4704 and masked by the photoresist 4802 during the implantation 4804. The processing for block 1010 may be as described previously.

Subsequently, at block 1012, the first dielectric layer 236 is formed conformally over and on the barrier layer 428, gate layers 432a, 432b, 232c, 232d, and injection layer 434. At block 1014, the second dielectric layer 238 is formed conformally over and on the first dielectric layer 236. At block 1016, the isolation structures 230 are formed. At block 1018, portions of the second dielectric layer 238 are removed from regions in which the sixth semiconductor device 212 and seventh semiconductor device 214 are to be formed. The processing for blocks 1012-1018 may be as described previously.

At block 1022, the third dielectric layer 240 is formed. At block 1024, the drain metal contacts 242a-242g and source metal contacts 244a-244g are formed. At block 1026, the fourth dielectric layer 246 is formed. At block 1028, the gate metal contacts 248a-248g and the injection metal contact 250 are formed. At block 1030, the fifth dielectric layer 252 is formed. At block 1032, metal vias 254a-254v and metal lines 256a-256t are formed. The processing for blocks 1022-1032 may be as described previously.

Various methods have been described in which a gate metal contact is formed “last” that is, the last metal contacts of the metal contacts that are formed. Drain metal contacts and source metal contacts are formed before the gate metal contacts in the foregoing examples. In other examples, gate metal contacts may be formed before the source metal contacts and the drain metal contacts. In such examples in which the gate metal contacts are formed before the source and drain metal contacts, the method may be considered a gate first process.

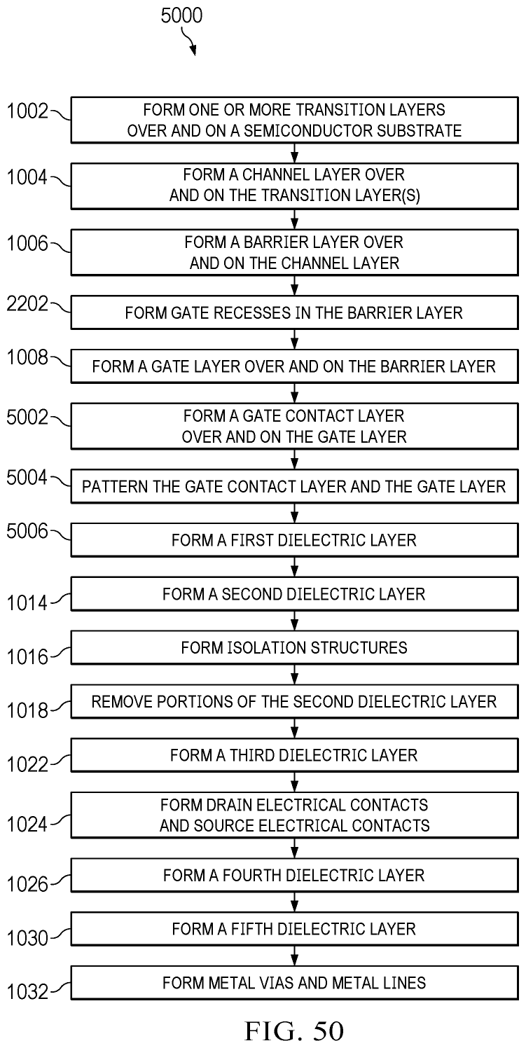

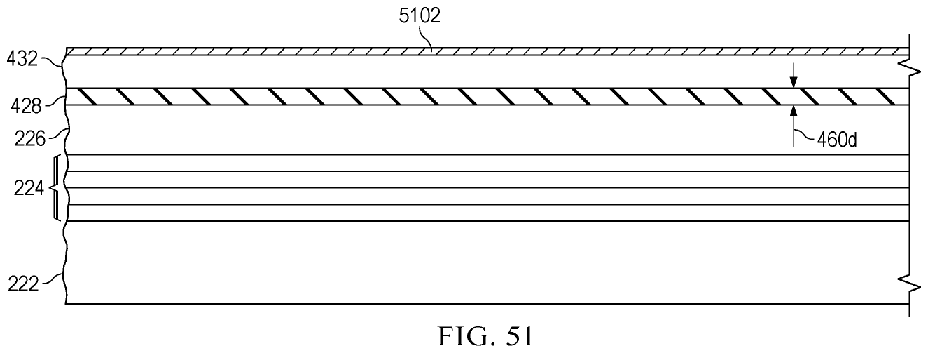

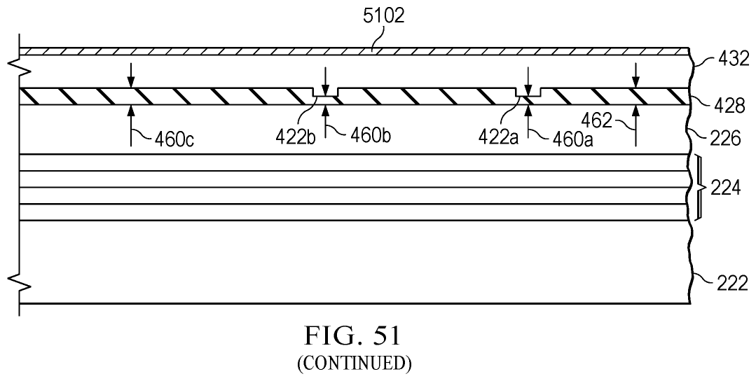

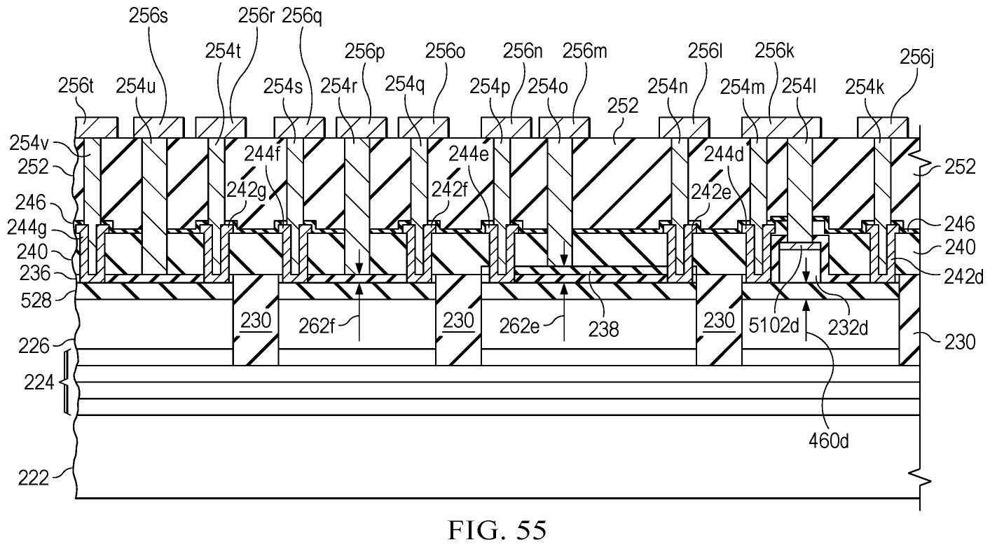

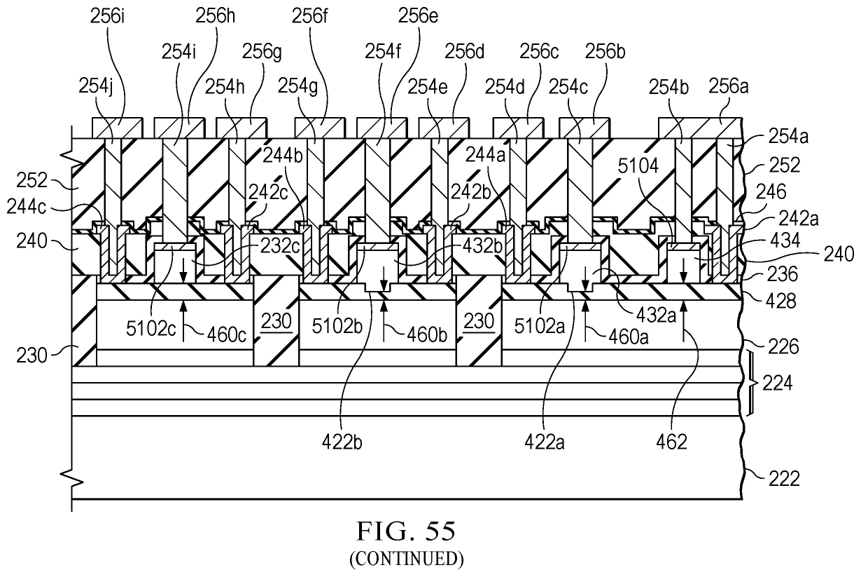

FIG. 50 is a flowchart of a method 5000 of manufacturing an IC using a gate first process according to some examples. The method 5000 of FIG. 50 is also a self-aligned process for aligning, e.g., gate metal contacts with respective gate layers. The method 5000 of FIG. 50 is illustrated by and described in the context of FIGS. 51 through 55, which illustrate cross-sectional views of an IC at various stages of manufacturing. The manufactured IC at FIG. 55 is similar to the IC 400 of FIG. 4. Although the method 5000 of FIG. 50 is illustrated in the context of FIGS. 51 through 55 to manufacture such an IC, the method 5000 of FIG. 50 may also be implemented to manufacture examples consistent with aspects of any IC described herein.

Referring to block 1002 of FIG. 50 and to FIG. 51, one or more transition layers 224 are formed over and on a semiconductor substrate 222. At block 1004, a channel layer 226 is formed over and on the transition layer(s) 224. At block 1006, a barrier layer 428 is formed over and on the channel layer 226. At block 2202, gate recesses 422a, 422b are formed in the barrier layer 428. At block 1008, a gate layer 432 is formed over and on the barrier layer 428. The processing for blocks 1002-1006, 2202, 1008 may be as described previously.

At block 5002, a gate contact layer 5102 is formed over and on the gate layer 432. The gate contact layer 5102 may be a material of the gate metal contacts 248a-248d and injection metal contact 250. The gate contact layer 5102 may be deposited by PVD, CVD, or another deposition process.

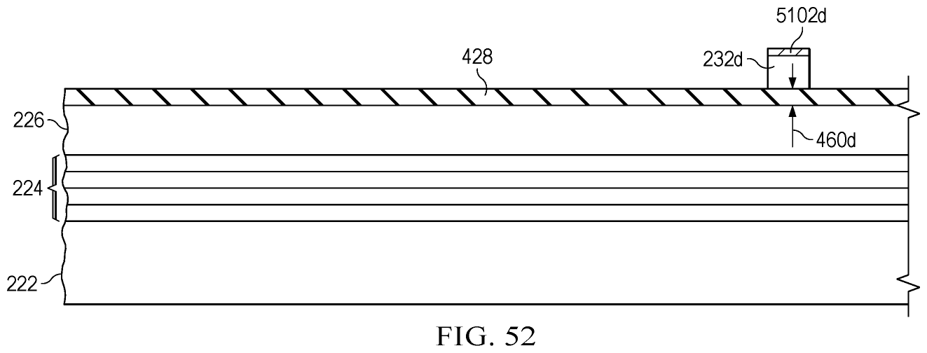

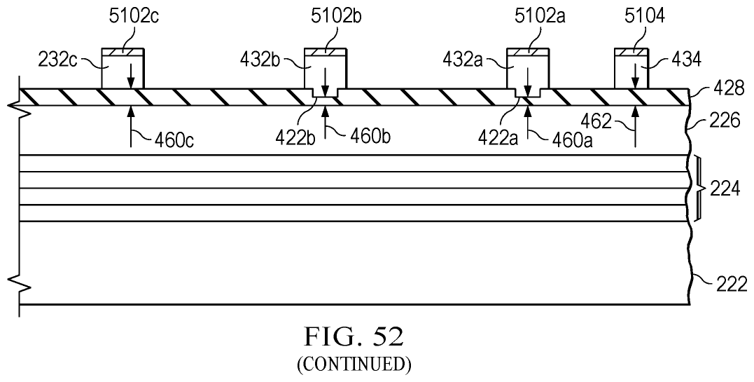

Referring to block 5004 of FIG. 50 and to FIG. 52, the gate contact layer 5102 and the gate layer 432 are patterned. The gate contact layer 5102 is patterned into gate metal contacts 5102a, 5102b, 5102c, 5102d and an injection metal contact 5104. The gate layer 432 is patterned into the gate layers 432a, 432b, 232c, 232d and the injection layer 434. The gate contact layer 5102 and the gate layer 432 may be patterned using appropriate photolithography and etch processes.

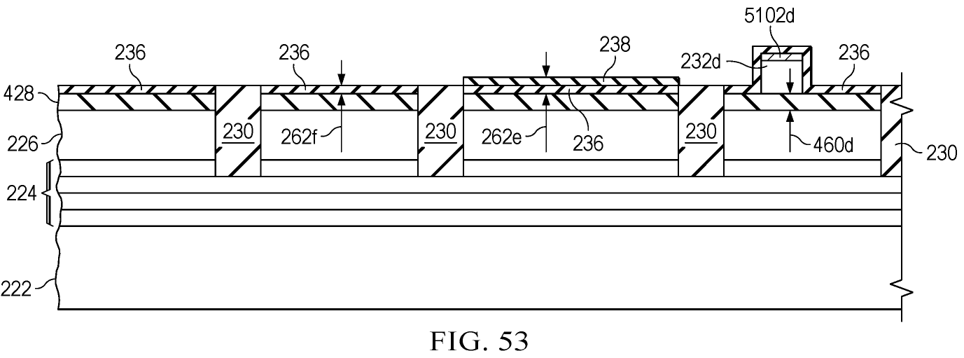

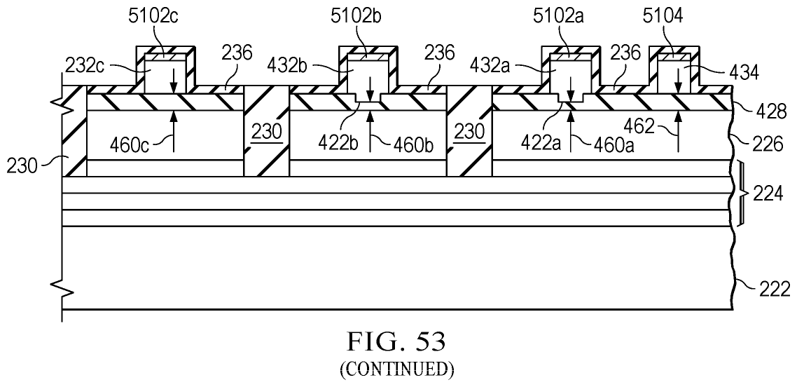

Referring to block 5006 of FIG. 50 and FIG. 53, the first dielectric layer 236 is formed conformally over and on the barrier layer 428, gate layers 432a, 432b, 232c, 232d, injection layer 434, gate metal contacts 5102a, 5102b, 5102c, 5102d and an injection metal contact 5104. The processing of block 5006 may be like the processing of block 1012.

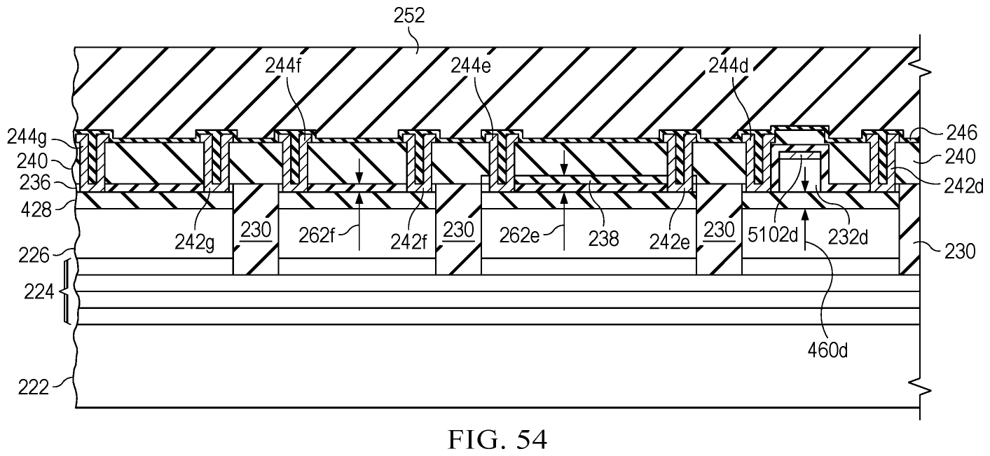

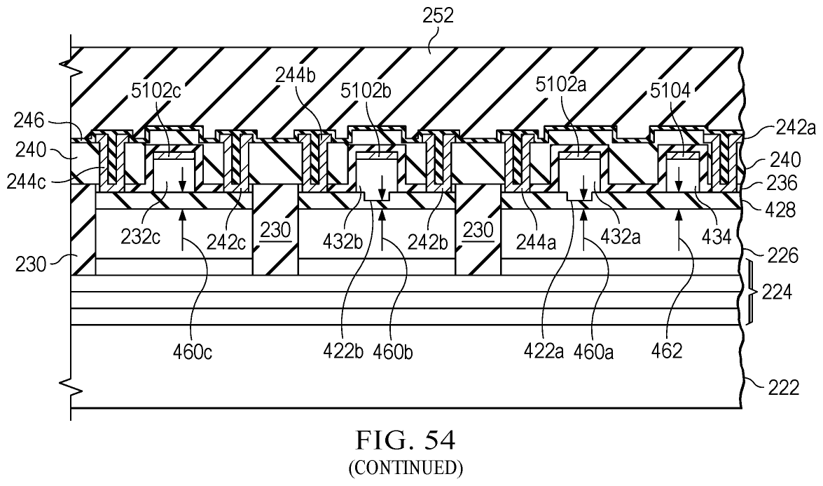

Referring to block 1014 of FIG. 50 and to FIG. 54, the second dielectric layer 238 is formed conformally over and on the first dielectric layer 236. At block 1016, the isolation structures 230 are formed. At block 1018, portions of the second dielectric layer 238 are removed from regions in which the sixth semiconductor device 212 and seventh semiconductor device 214 are to be formed. The processing for blocks 1014-1018 may be as described previously.

At block 1022, the third dielectric layer 240 is formed. At block 1024, the drain metal contacts 242a-242g and source metal contacts 244a-244g are formed. At block 1026, the fourth dielectric layer 246 is formed. At block 1030, the fifth dielectric layer 252 is formed. The processing for blocks 1022, 1024, 1026, 1030 may be as described previously.

Referring to block 1032 of FIG. 50 and FIG. 55, metal vias 254a-254v and metal lines 256a-256t are formed. The processing for block 1032 may be as described previously. Via openings for the metal vias 254b, 254c, 254f, 254i, 2541 are formed through the fifth dielectric layer 252 and the first dielectric layer 236 to expose the injection metal contact 5104 and gate metal contacts 5102a, 5102b, 5102c, 5102d, respectively. Hence, the metal vias 254b, 254c, 254f, 254i, 2541 electrically couple and contact the injection metal contact 5104 and gate metal contacts 5102a, 5102b, 5102c, 5102d, respectively. Further, the via openings for the metal vias 254o, 254r, 254u may expose the second dielectric layer 238, the first dielectric layer 236, and the barrier layer 228, respectively. The metal vias 254o, 254r, 254u may form the gate terminals of the respective semiconductor devices 210, 212, 214.

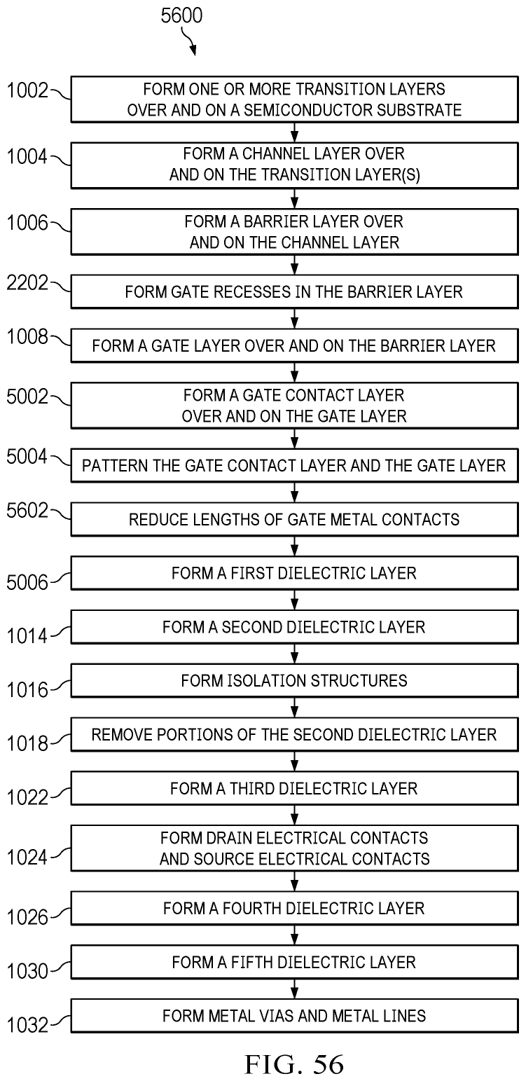

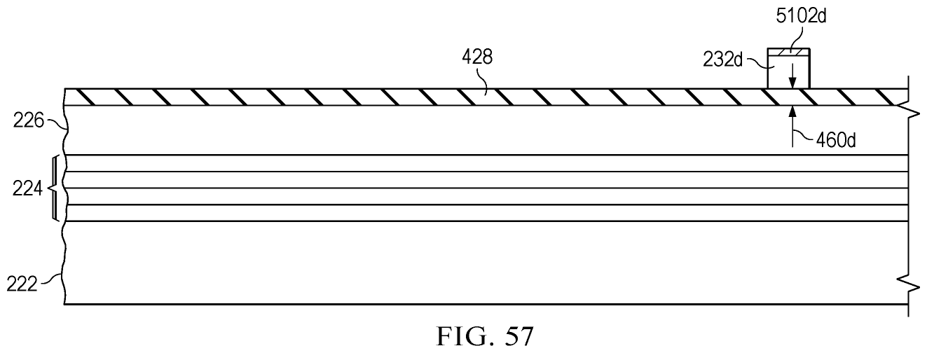

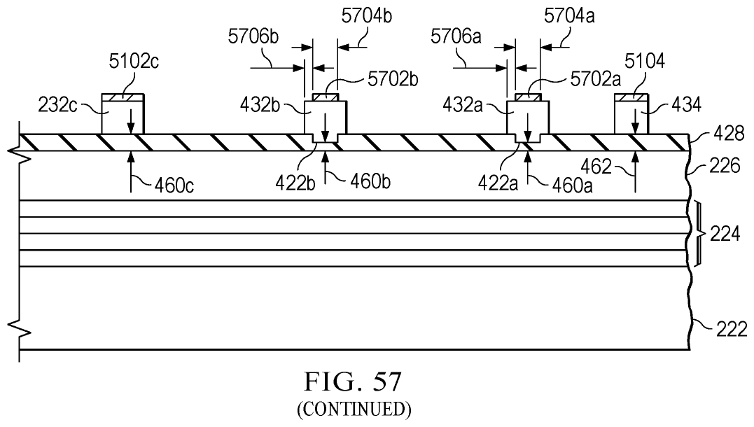

FIG. 56 is a flowchart of a method 5600 of manufacturing an IC using a gate first process according to some examples. The method 5600 of FIG. 56 is also a self-aligned process for aligning, e.g., gate metal contacts with respective gate layers. The processing is performed as described above with respect to the method 5000 of FIG. 50 and illustrated in FIGS. 51 through 55. Referring to FIG. 56, following the patterning of the gate contact layer 5102 and the gate layer 432 into gate metal contacts 5102a, 5102b, 5102c, 5102d and an injection metal contact 5104 at block 5004, lengths of the gate metal contacts are reduced at block 5602, as shown in FIG. 57. In FIG. 57, the lengths of the gate metal contacts 5102a, 5102b are reduced to form gate metal contacts 5702a, 5702b. The gate metal contacts 5102c, 5102d and injection metal contact 5104 may be masked, such as by a photoresist patterned using photolithography. An isotropic etch, such as a wet etch, selective to the metal of the gate metal contacts 5102a, 5102b is performed to reduce the lengths of the gate metal contacts 5102a, 5102b. The isotropic etch may also reduce a thickness of the gate metal contacts 5102a, 5102b. The resulting gate metal contacts 5702a, 5702b have reduced lengths 5704a, 5704b, which further result in contact offset length 5706a, 5706b. Hence, in the illustrated example, the gate metal contacts 5102c, 5102d have a same lateral footprint as the gate layers 232c, 232d, respectively, and the gate metal contacts 5702a, 5702b have different lateral footprints as the gate layers 232a, 232b, respectively. Processing then proceeds as described above with respect to block 5006 and subsequent processing.

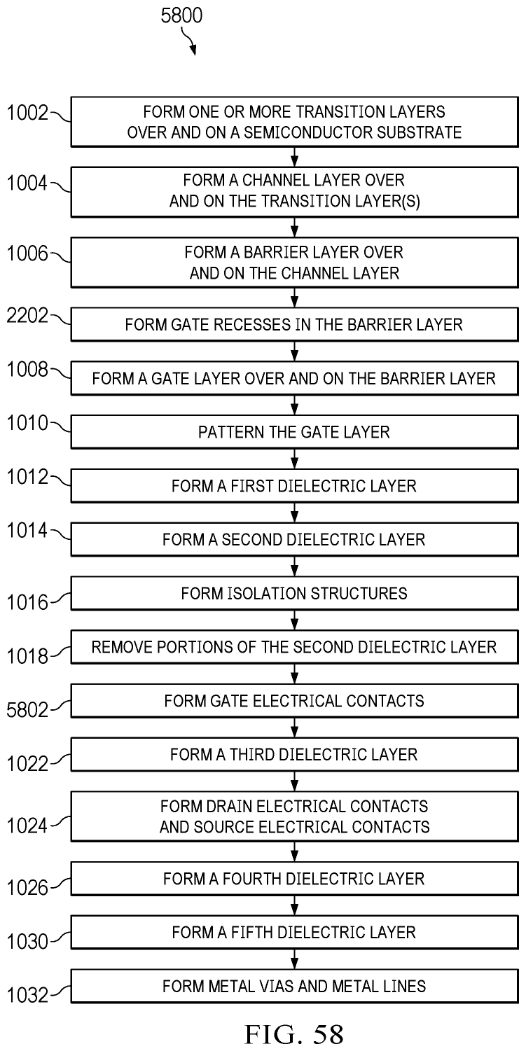

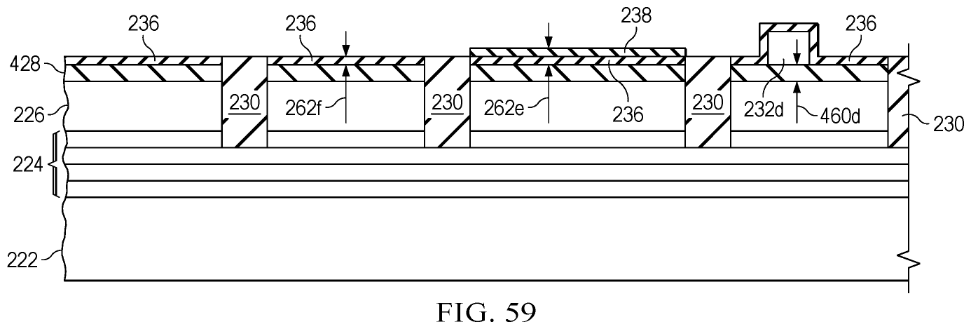

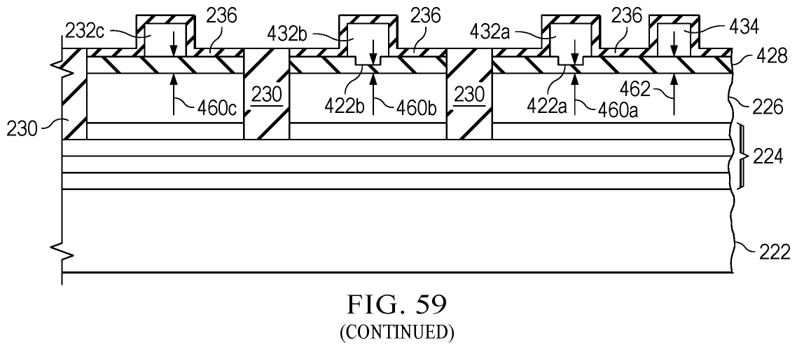

FIG. 58 is a flowchart of a method 5800 of manufacturing an IC using a gate first process according to some examples. The method 5800 of FIG. 58 is illustrated by and described in the context of FIGS. 59 through 62, which illustrate cross-sectional views of an IC at various stages of manufacturing. The manufactured IC at FIG. 58 is similar to the IC 400 of FIG. 4. Although the method 5800 of FIG. 58 is illustrated in the context of FIGS. 59 through 62 to manufacture such an IC, the method 5800 of FIG. 58 may also be implemented to manufacture examples consistent with aspects of any IC described herein.

Referring to block 1002 of FIG. 58 and to FIG. 59, one or more transition layers 224 are formed over and on a semiconductor substrate 222. At block 1004, a channel layer 226 is formed over and on the transition layer(s) 224. At block 1006, a barrier layer 428 is formed over and on the channel layer 226. At block 2202, gate recesses 422a, 422b are formed in the barrier layer 428. At block 1008, a gate layer 432 is formed over and on the barrier layer 428. At block 1010, the gate layer 432 is patterned into the gate layers 432a, 432b, 232c, 232d and the injection layer 434. At block 1012, the first dielectric layer 236 is formed conformally over and on the barrier layer 428, gate layers 432a, 432b, 232c, 232d, and injection layer 434. At block 1014, the second dielectric layer 238 is formed conformally over and on the first dielectric layer 236. At block 1016, the isolation structures 230 are formed. At block 1018, portions of the second dielectric layer 238 are removed from regions in which the sixth semiconductor device 212 and seventh semiconductor device 214 are to be formed. The processing for blocks 1002-1006, 2202, 1008-1018 may be as described previously.

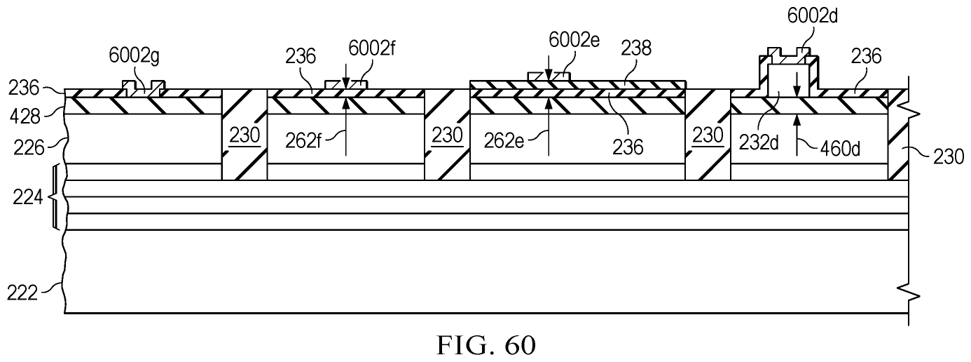

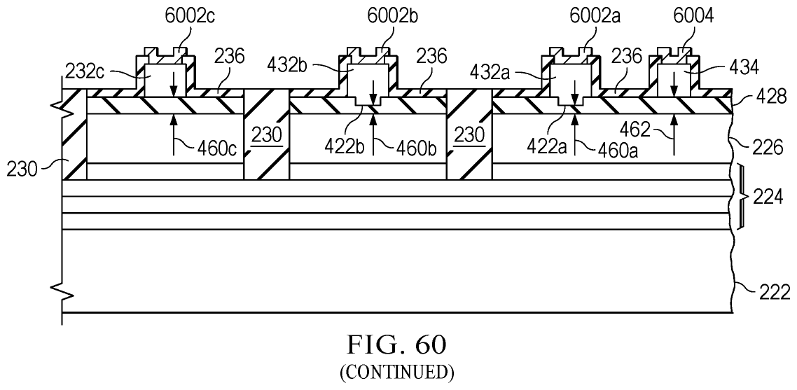

Referring to block 5802 of FIG. 58 and FIG. 60, gate metal contacts 6002a, 6002b, 6002c, 6002d, 6002e, 6002f, 6002g and an injection metal contact 6004 are formed. The gate metal contacts 6002a, 6002b, 6002c, 6002d, 6002g and the injection metal contact 6004 are formed through the first dielectric layer 236. Respective gate/injection contact openings may be formed through the first dielectric layer 236 to, where appropriate, the gate layers 232a-232d, the injection layer 234, and the barrier layer 228. The gate/injection contact openings may be formed using appropriate photolithography and etch processes. One or more metals are deposited into the gate/injection contact openings and over and on an upper surface of the first dielectric layer 236 or second dielectric layer 238. The metal(s) may be deposited using an appropriate deposition process(es), such as CVD, PVD, or the like. In some examples, the metal(s) may be respective conformal layer(s) in the gate/injection contact openings that do not fill the gate/injection contact openings, and in some examples, the metal(s) may fill the gate/injection contact openings. The metal(s) over the upper surface of the respective dielectric layer 236, 238 are patterned into the portions of the gate metal contacts 6002a-6002g and injection metal contact 6004 on the upper surface of the respective dielectric layer 236, 238. The metal(s) may be patterned using appropriate photolithography and etch processes. The patterned metal(s), some of which may be deposited into respective gate/injection contact openings, form the gate metal contacts 6002a-6002g and injection metal contact 6004. The gate metal contacts 6002e, 6002f, 6002g may form the gate terminals of the respective semiconductor devices 210, 212, 214.

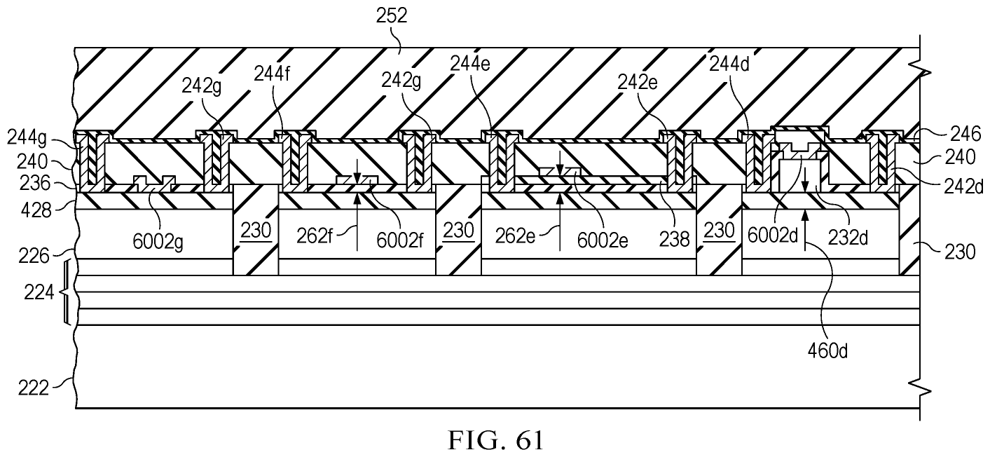

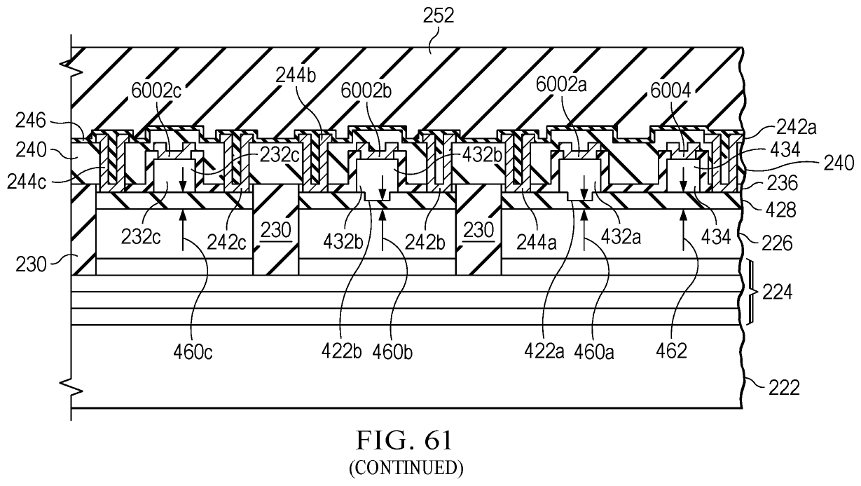

Referring to block 1022 of FIG. 58 and FIG. 61, the third dielectric layer 240 is formed. At block 1024, the drain metal contacts 242a-242g and source metal contacts 244a-244g are formed. At block 1026, the fourth dielectric layer 246 is formed. At block 1030, the fifth dielectric layer 252 is formed. The processing for blocks 1022, 1024, 1026, 1030 may be as described previously.

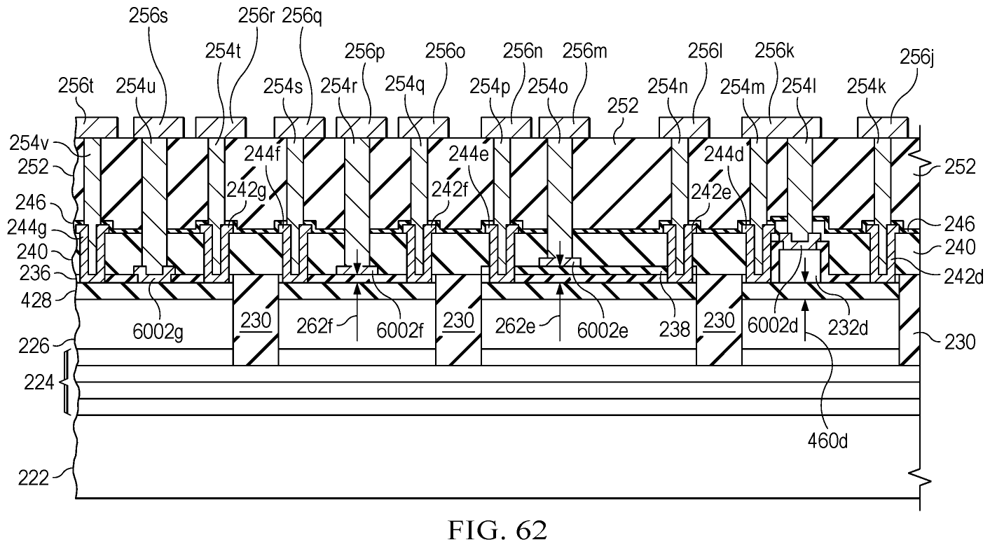

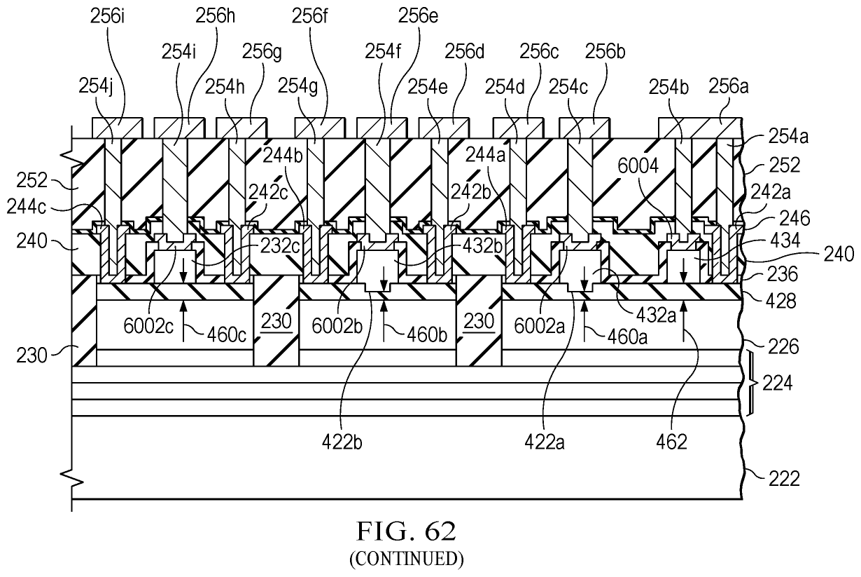

Referring to block 1032 of FIG. 58 and FIG. 62, metal vias 254a-254v and metal lines 256a-256t are formed. The processing for block 1032 may be as described previously. Via openings for the metal vias 254b, 254c, 254f, 254i, 2541, 254o, 254r, 254u are formed through the fifth dielectric layer 252 to expose the injection metal contact 6004 and gate metal contacts 6002a, 6002b, 6002c, 6002d, 6002e, 6002f, 6002g, respectively. Hence, the metal vias 254b, 254c, 254f, 254i, 2541, 254o, 254r, 254u electrically couple and contact the injection metal contact 5104 and gate metal contacts 6002a, 6002b, 6002c, 6002d, 6002e, 6002f, 6002g, respectively.

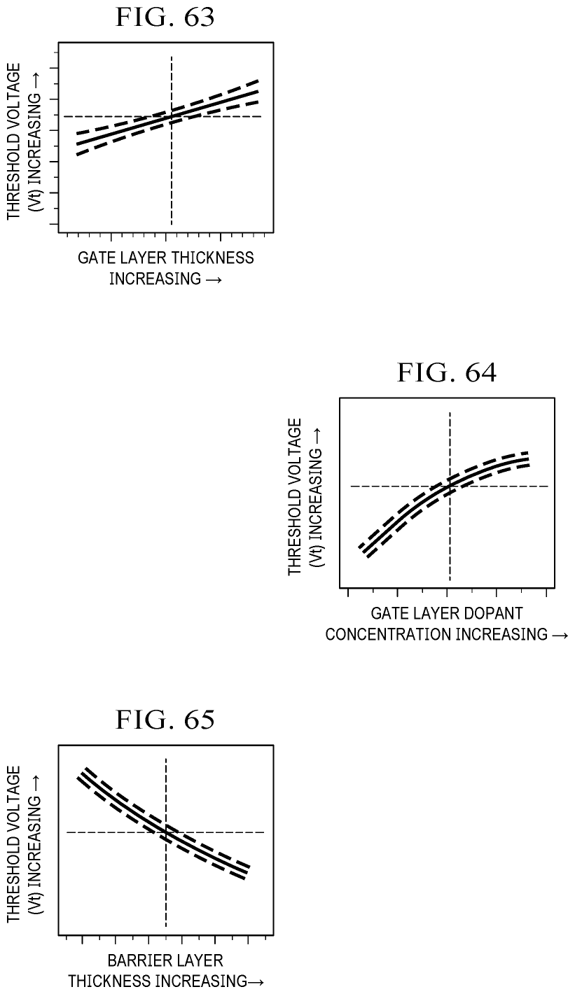

FIG. 63 is a chart illustrating threshold voltage of a semiconductor device (e.g., an Emode HEMT) as a function of gate layer thickness according to some examples. For a given process node for a given semiconductor device, the threshold voltage increases as the thickness of the gate layer increases.

FIG. 64 is a chart illustrating threshold voltage of a semiconductor device (e.g., an Emode HEMT) as a function of gate layer dopant concentration according to some examples. For a given process node for a given semiconductor device, the threshold voltage increases as the dopant concentration (e.g., at the interface between the gate layer and the barrier layer) of the gate layer increases.

FIG. 65 is a chart illustrating threshold voltage of a semiconductor device (e.g., an Emode HEMT) as a function of barrier layer thickness according to some examples. For a given process node for a given semiconductor device, the threshold voltage decreases as the thickness of the barrier layer increases.

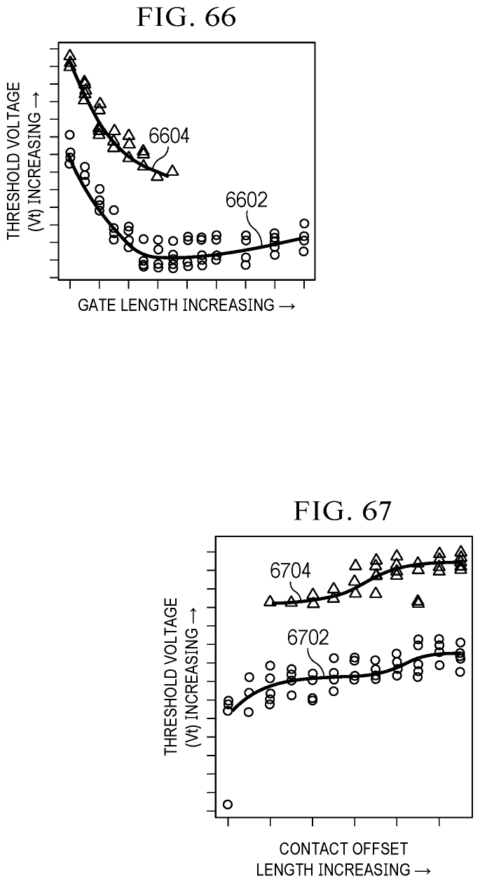

FIG. 66 is a chart illustrating threshold voltage of semiconductor devices (e.g., Emode HEMTs of different designs) as a function of gate length according to some examples. The chart illustrates data points (shown as circles) of a first design of a semiconductor device at varying gate lengths. A trend line 6602 shows that, for the first design, threshold voltage decreases relatively quickly before increasing with increasing gate length. The chart illustrates data points (shown as triangles) of a second design of a semiconductor device at varying gate lengths. A trend line 6604 shows that, for the second design, threshold voltage decreases in a range of increasing gate length.

FIG. 67 is a chart illustrating threshold voltage of semiconductor devices (e.g., Emode HEMTs of different designs) as a function of contact offset length according to some examples. The chart illustrates data points (shown as circles) of a first design of a semiconductor device at varying contact offset lengths. A trend line 6702 shows that, for the first design, threshold voltage increases with increasing contact offset length. The chart illustrates data points (shown as triangles) of a second design of a semiconductor device at varying contact offset lengths. A trend line 6704 shows that, for the second design, threshold voltage increases with increasing contact offset length.

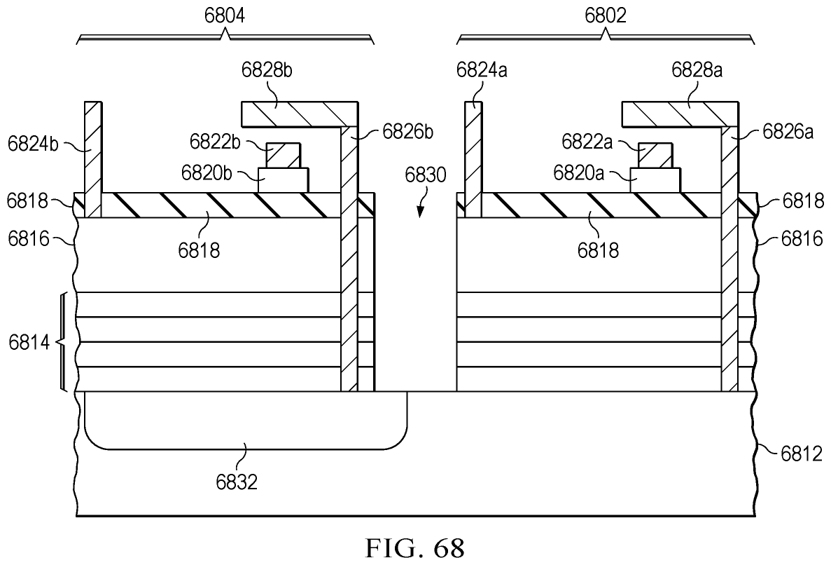

FIGS. 68 through 72 are respective cross-sectional view of semiconductor devices illustrating different isolation techniques according to some examples. Any isolation technique may be implemented for any semiconductor device described above, such as described in U.S. patent application Ser. No. 18/534,056, titled “Integrated devices with conductive barrier structure”, filed Dec. 8, 2023, which is incorporated herein by reference in its entirety. The semiconductor devices in FIGS. 68 through 72 are simplified relative to previously illustrated semiconductor devices to avoid obscuring aspects illustrated in these figures.

FIGS. 68 through 72 include respective first semiconductor devices 6802, 6902, 7002, 7102, 7202 and respective second semiconductor devices 6804, 6904, 7004, 7104, 7204. These semiconductor devices may be or include any of the semiconductor devices described previously, which may include modifications to the semiconductor device(s) in FIGS. 68 through 72.

FIGS. 68 through 72 include a semiconductor substrate 6812, one or more transition layers 6814, a channel layer 6816, and a barrier layer 6818. The semiconductor substrate 6812, transition layer(s) 6814, channel layer 6816, and barrier layer 6818 may have similar structure and/or material(s) as, respectively, the semiconductor substrate 222, transition layer(s) 224, channel layer 226, 726, and barrier layer 228, 428, 528, 728 (or barrier sub-layers 612, 614) previously described and illustrated. The first semiconductor devices 6802, 6902, 7002, 7102, 7202 each includes a gate layer 6820a and a gate metal contact 6822a, which may have similar structure and/or material(s) as any gate layer and any gate metal contact described above, respectively. In each first semiconductor device 6802, 6902, 7002, 7102, 7202, a drain metal contact 6824a extends through the barrier layer 6818 to the channel layer 6816. The drain metal contact 6824a electrically couples the drain terminal of the respective semiconductor device. In other examples, the drain metal contact 6824a contacts, and does not extend through, the barrier layer 6818. In each first semiconductor device 6802, 6902, 7002, a source metal contact 6826a extends through the barrier layer 6818 into the channel layer 6816, and further in the illustrated example, through the transition layer(s) 6814 to the semiconductor substrate 6812. The source metal contact 6826a electrically couples the source terminal of the respective semiconductor device. A source-coupled field plate 6828b is electrically coupled to and extends laterally from the source metal contact 6826a to over the gate layer 6820a.

The second semiconductor devices 6804, 6904, 7004, 7104, 7204 each includes a gate layer 6820b and a gate metal contact 6822b, which may have similar structure and/or material(s) as any gate layer and any gate metal contact described above, respectively. In each second semiconductor device 6804, 6904, 7004, 7104, 7204, a drain metal contact 6824b extends through the barrier layer 6818 to the channel layer 6816. The drain metal contact 6824b electrically couples the drain terminal of the respective semiconductor device. In other examples, the drain metal contact 6824b contacts, and does not extend through, the barrier layer 6818. In each first semiconductor device 6802, 6902, 7002, a source metal contact 6826b extends through the barrier layer 6818 into the channel layer 6816, and further in the illustrated example, through the transition layer(s) 6814 to the semiconductor substrate 6812. The source metal contact 6826b electrically couples the source terminal of the respective semiconductor device. A source-coupled field plate 6828b is electrically coupled to and extends laterally from the source metal contact 6826b to over the gate layer 6820b.

Referring to FIG. 68, a trench 6830 is laterally between the semiconductor devices 6902, 6904 and extends through the barrier layer 6818, channel layer 6816, and transition layer(s) 6814 to an upper surface of the semiconductor substrate 6812. The trench 6830 may be filled with an isolation material (e.g., silicon oxide). A doped well 6832 is in the semiconductor substrate 6812 extending from the upper surface of the semiconductor substrate 6812 into a depth in the semiconductor substrate 6812. The doped well 6832 laterally overlaps the trench 6830. The doped well 6832 underlies the second semiconductor device 6804. The source metal contact 6826b may electrically couple the doped well 6832. The doped well 6832 does not extend to underly the first semiconductor device 6802. In some examples, the semiconductor substrate 6812 is doped with a p-type dopant, and the doped well 6832 is doped with an n-type dopant at a greater concentration than the p-type dopant with which the semiconductor substrate 6812 is doped. The doped well 6832 may be formed by implanting dopants (which may further implement a photolithography process to mask non-implanted areas), such as before forming the transition layer(s) 6814, channel layer 6816, and/or barrier layer 6818. The doped well 6832 may provide lateral junction isolation in the semiconductor substrate 6812.

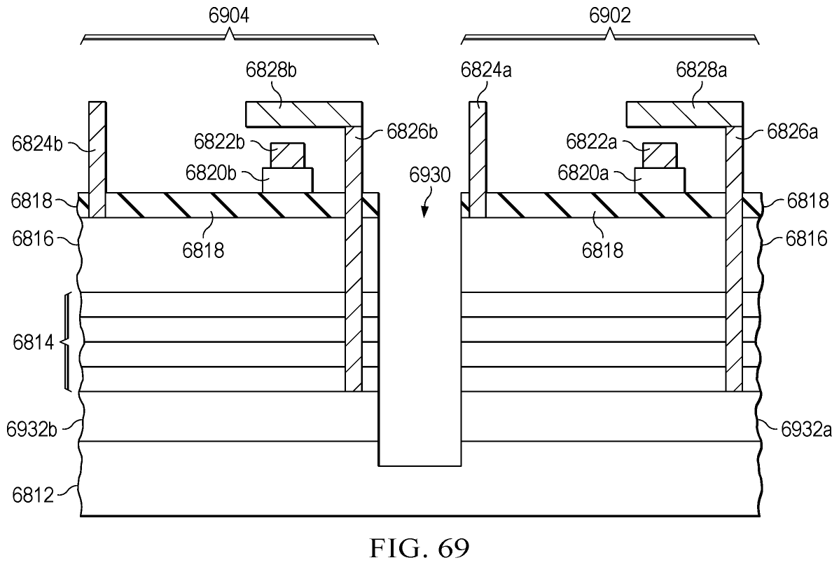

Referring to FIG. 69, a trench 6930 is laterally between the semiconductor devices 6902, 6904 and extends through the barrier layer 6818, channel layer 6816, and transition layer(s) 6814 into the semiconductor substrate 6812. The trench 6930 may be filled with an isolation material (e.g., silicon oxide). Doped wells 6932a, 6932a are in the semiconductor substrate 6812 extending from the upper surface of the semiconductor substrate 6812 into a depth in the semiconductor substrate 6812. The doped well 6932a underlies the first semiconductor device 6902, and the doped well 6932b underlies the second semiconductor device 6904. The source metal contact 6826a may electrically couple the doped well 6932a, and the source metal contact 6826b may electrically couple the doped well 6932b. The trench 6930 extends into the semiconductor substrate 6812 between the doped wells 6932a, 6932b and separates the doped wells 6932a, 6932b. In some examples, the semiconductor substrate 6812 is doped with a p-type dopant, and the doped wells 6932a, 6932b are doped with an n-type dopant at a greater concentration than the p-type dopant with which the semiconductor substrate 6812 is doped. The doped wells 6932a, 6932b may be formed by implanting dopants (which may further implement a photolithography process to mask non-implanted areas), such as before forming the transition layer(s) 6814, channel layer 6816, and/or barrier layer 6818. The doped wells 6932a, 6932b may provide vertical junction isolation in the semiconductor substrate 6812.

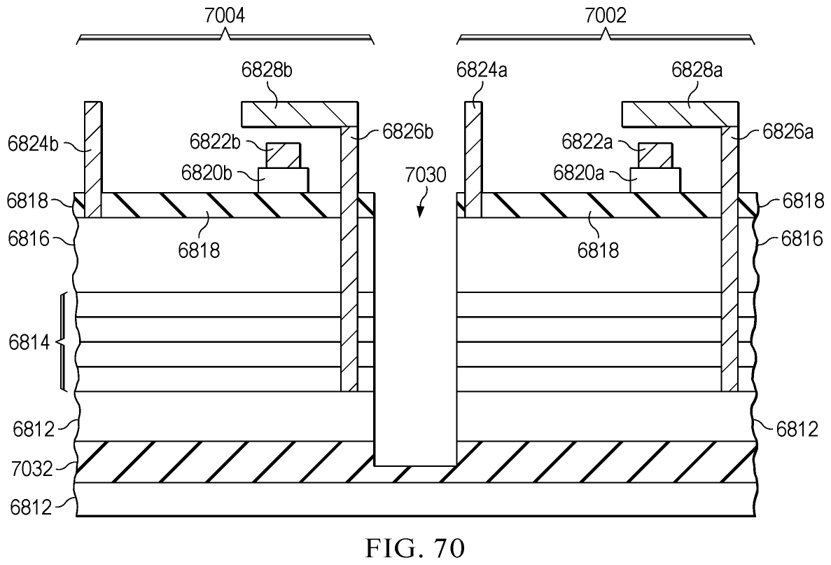

Referring to FIG. 70, a trench 7030 is laterally between the semiconductor devices 7002, 7004 and extends through the barrier layer 6818, channel layer 6816, and transition layer(s) 6814 into the semiconductor substrate 6812. The trench 7030 may be filled with an isolation material (e.g., silicon oxide). The semiconductor substrate 6812 includes an isolation layer 7032, which may result in the semiconductor substrate 6812 to be an SOI substrate. The isolation layer 7032 may be an oxide layer (e.g., a buried oxide (BOX) layer). The trench 7030 further extends into the isolation layer 7032.

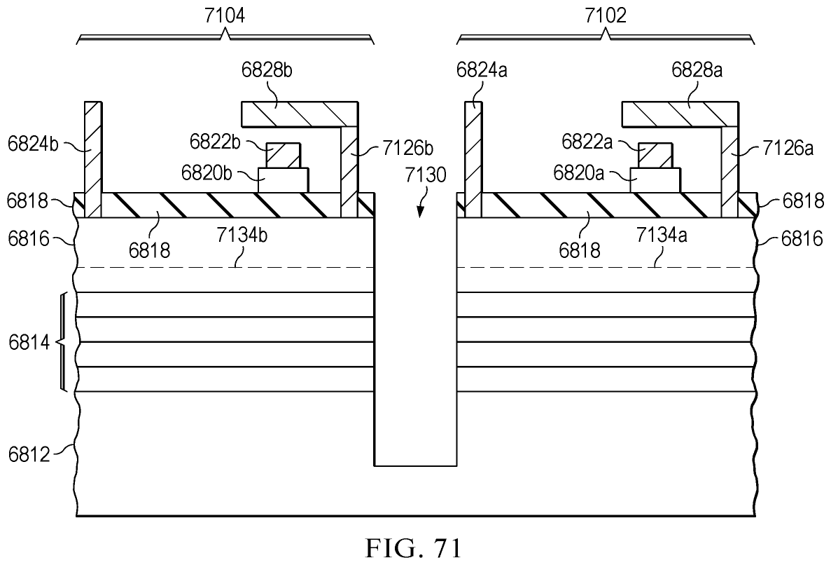

Referring to FIG. 71, a trench 7130 is laterally between the semiconductor devices 7102, 7104 and extends through the barrier layer 6818, channel layer 6816, and transition layer(s) 6814 into the semiconductor substrate 6812. The trench 7130 may be filled with an isolation material (e.g., silicon oxide). The channel layer 6816 of the semiconductor devices 7102, 7104 includes a two-dimensional hole gas (2DHG) 7134a, 7134b. The 2DHG 7134a, 7134b is below a 2DEG in the channel layer 6816. The 2DHG 7134a, 7134b may be formed by band bending the in the channel layer 6816, which may be achieved, for example, by selection of materials of sub-layers of the channel layer 6816. The 2DHG 7134a, 7134b may provide hole injection isolation. In the semiconductor devices 7102, 7104, respective source metal contacts 7126a, 7126b extend through the barrier layer 6818 to the channel layer 6816. The source metal contacts 7126a, 7126b electrically couple the respective source terminals of the respective semiconductor device. Source-coupled field plates 6828a, 6828b are electrically coupled to and extend laterally from the respective source metal contact 7126a, 7126b to over the gate layer 6820a, 6820b.

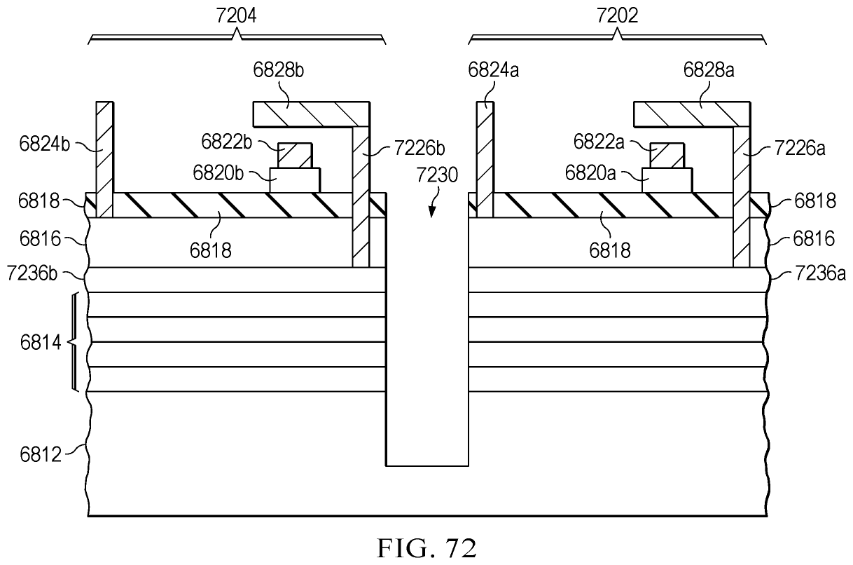

Referring to FIG. 72, a trench 7230 is laterally between the semiconductor devices 7202, 7204 and extends through the barrier layer 6818, channel layer 6816, and transition layer(s) 6814 into the semiconductor substrate 6812. The trench 7230 may be filled with an isolation material (e.g., silicon oxide). The channel layer 6816 of the first semiconductor device 7202 includes a doped region 7236a. The channel layer 6816 of the second semiconductor device 7204 includes a doped region 7236b. The doped regions 7236a, 7236b are below a respective 2DEG in the channel layer 6816. The trench 7230 is laterally between and separates the doped regions 7236a, 7236b. The doped regions 7236a, 7236b may be formed by implanting dopants (which may further implement a photolithography process to mask non-implanted areas), such as before forming the barrier layer 6818. The doped regions 7236a, 7236b may provide a conduction layer in the channel layer 6816 to capture leakage. In the first semiconductor device 7202, a source metal contact 7226a extends through the barrier layer 6818 into the channel layer 6816 to the doped region 7236a. The source metal contact 7226a electrically couples the source terminal of the semiconductor device. In the second semiconductor device 7204, a source metal contact 7226b extends through the barrier layer 6818 into the channel layer 6816 to the doped region 7236b. The source metal contact 7226b electrically couples the source terminal of the semiconductor device and the doped region 7236b. Source-coupled field plates 6828a, 6828b are electrically coupled to and extend laterally from the respective source metal contact 7226a, 7226b to over the gate layer 6820a, 6820b.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or IC package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

Although various examples have been described in detail, it should be understood that various changes, substitutions, and alterations can be made therein without departing from the scope defined by the appended claims.

What is claimed is:

1. An integrated circuit (IC) comprising:
a semiconductor substrate;
a channel layer on the semiconductor substrate, the channel layer including a gallium nitride (GaN) material;
a barrier layer on the channel layer;
a first semiconductor device on the semiconductor substrate, the first semiconductor device including a first terminal over the barrier layer, and the first semiconductor device having a first threshold voltage; and
a second semiconductor device on the semiconductor substrate, the second semiconductor device including a second terminal over the barrier layer, and the second semiconductor device having a second threshold voltage different from the first threshold voltage, in which the first and second threshold voltages are both positive or negative voltages.

2. The IC of claim 1, wherein the first terminal includes a first semiconductor layer, and the second terminal includes a second semiconductor layer.

3. The IC of claim 2, wherein each of the first and second semiconductor layers includes a p-type doped GaN layer.

4. The IC of claim 2, wherein the first semiconductor device is a first enhancement mode high electron mobility transistor (HEMT), the first terminal is a first gate of the first enhancement mode HEMT, and the first enhancement mode HEMT includes a first drain and a first source; and
wherein the second semiconductor device is a second enhancement mode HEMT, the second terminal is a second gate of the second enhancement mode HEMT, and the second enhancement mode HEMT includes a second drain and a second source.

5. The IC of claim 4, wherein the first enhancement mode HEMT includes a first metal contact on the first semiconductor layer, the first metal contact forming a junction with the first semiconductor layer, the junction being a Schottky junction or an ohmic junction; and
wherein the first enhancement mode HEMT includes a first diode terminal electrically coupled to the first source and to the first metal contact, and a second diode terminal electrically coupled to the first drain.

6. The IC of claim 2, wherein the first semiconductor device includes a first metal contact on the first semiconductor layer, the first terminal being configured as a first diode terminal, the first metal contact forming an ohmic junction with the first semiconductor layer, and the first semiconductor device includes a third terminal configured as a second diode terminal.

7. The IC of claim 1, wherein the first semiconductor device is a first depletion mode HEMT, the first terminal being a first gate of the first depletion mode HEMT, the first terminal being on a first dielectric layer; and
wherein the second semiconductor device is a second depletion mode HEMT, the second terminal being a second gate of the second depletion mode HEMT, the second gate being on a second dielectric layer.

8. The IC of claim 1, wherein the first terminal includes a first semiconductor layer over a surface of the barrier layer, the first semiconductor layer having a first thickness over the surface of the barrier layer; and
wherein the second terminal includes a second semiconductor layer over the surface of the barrier layer, the second semiconductor layer having a second thickness over the surface of the barrier layer, the second thickness being different from the first thickness.

9. The IC of claim 1, wherein the first terminal is on the barrier layer, and the second terminal extends into the barrier layer.

10. The IC of claim 1, wherein:
the first semiconductor device is a HEMT, the first terminal is a gate, and the first semiconductor device includes:
a drain;
a source;
a semiconductor layer; and
a third metal contact on the semiconductor layer, the third metal contact electrically coupled to the drain.

11. The IC of claim 1, wherein:
the barrier layer includes:
a first barrier sub-layer over the channel layer, the first barrier sub-layer having an opening therethrough; and
a second barrier sub-layer over the first barrier sub-layer and conformally in the opening to form a recess;
the first terminal extends into the recess and on the second barrier sub-layer; and
the second terminal is on the barrier layer.

12. The IC of claim 1, wherein:
the channel layer has a first recess;
the barrier layer is conformally in the first recess forming a second recess;
the first terminal extends into the second recess; and
the second terminal is on the barrier layer and is laterally outside of the second recess.

13. The IC of claim 1, wherein the first terminal is a first gate having a first gate length, and the second terminal is a second gate having a second gate length different from the first gate length.

14. The IC of claim 1, wherein the first semiconductor device includes a first metal contact on the first terminal, the first metal contact has a same lateral footprint as the first terminal; and
wherein the second semiconductor device includes a second metal contact on the second terminal, the second metal contact has a different lateral footprint from the second terminal.

15. The IC of claim 1, wherein the first and second terminals have different compositions.

16. The IC of claim 15, wherein the first terminal includes a first semiconductor layer, the second terminal includes a second semiconductor layer, and the first and second semiconductor layers have different dopant concentrations.

17. The IC of claim 1, wherein the first terminal is on a first dielectric layer, the second terminal is on a second dielectric layer, and the first and second dielectric layers have different dielectric constants.

18. The IC of claim 1, wherein the semiconductor substrate includes an isolation structure between the first and second semiconductor devices.

19. The IC of claim 1, wherein both the first and second semiconductor devices have, respectively, positive first and second threshold voltages, and the IC further comprises a third semiconductor device on the semiconductor substrate, the third semiconductor device having a negative third threshold voltage.

20. The IC of claim 1, wherein both the first and second semiconductor devices have, respectively, negative first and second threshold voltages, and the IC further comprises a third semiconductor device on the semiconductor substrate, the third semiconductor device having a positive third threshold voltage.

21. The IC of claim 1, wherein the first semiconductor device is a first depletion mode HEMT, and the second semiconductor device is a second depletion mode HEMT.

22. The IC of claim 21, wherein the first depletion mode HEMT has a first gate on a first dielectric layer, the second depletion mode HEMT has a second gate on a second dielectric layer, and the first and second dielectric layers have at least one of: different thicknesses or different dielectric constants.

23. An IC including:
a semiconductor substrate;
a first HEMT on the semiconductor substrate, the first HEMT coupled between a power terminal and a switching terminal;
a second HEMT on the semiconductor substrate, the second HEMT coupled between the switching terminal and a ground terminal; and
a diode on the semiconductor substrate, the diode coupled between the switching terminal and the ground terminal, the diode having a different threshold voltage from at least one of the first HEMT and the second HEMT.

24. The IC of claim 23, wherein the diode is a diode-connected HEMT.

25. An IC including:
a semiconductor substrate;
a first depletion mode HEMT on the semiconductor substrate, the first depletion mode HEMT coupled between a power terminal and a clamp terminal, the first depletion mode HEMT having a first threshold voltage;
an enhancement mode HEMT on the semiconductor substrate, the enhancement mode HEMT coupled between the clamp terminal and a ground terminal, the enhancement mode HEMT having a gate terminal; and
a comparator having a first comparator input, a second comparator input, and a comparator output, the first comparator input electrically coupled to the clamp terminal, the second comparator input electrically coupled to a reference terminal, and the comparator output electrically coupled to the gate terminal, the comparator including a second depletion mode HEMT on the semiconductor substrate, the second depletion mode HEMT having a second threshold voltage different from the first threshold voltage.
